(19) United States
(12) Patent Application Publication
(10) Pub. No.: US 2026/0173477 A1
(43) Pub. Date: Jun. 18, 2026

(54) SEMICONDUCTOR DEVICES FOR REAL NUMBER COMPUTATION USING COMPUTER INTEGRATED CIRCUITS IMPLEMENTING MATTER AMPLIFICATION BY STIMULATED EMISSION COMPUTATION(S) (MASEC)

(71) Applicant: ANALOG COMPUTATION ENTERPRISE INC., Billings, MT (US)

(72) Inventors: Laurence F. Wood, Hamilton, MT (US); Lisa S. WOOD, Hamilton, MT (US); Vassil DIMITROV, CALGARY (CA)

(73) Assignee: ANALOG COMPUTATION ENTERPRISE INC., Billings, MT (US)

(21) Appl. No.: 18/707,388

(22) PCT Filed: Nov. 3, 2022
(86) PCT No.: PCT/US2022/048879

§ 371 Date: May 3, 2024

Related U.S. Application Data
(60) Provisional application No. 63/275,245, filed on Nov. 3, 2021.

(51) Int. Cl. H10D 62/85; G06N 10/60; H10D 8/00

(52) U.S. Cl. CPC H10D 62/85; G06N 10/60; H10D 8/00

(57) ABSTRACT

A processing system, or component thereof, and methods of making and using thereof, the system or component comprising at least one semiconductor device for real number computation using real machine computer integrated circuits implementing matter amplification by stimulated emission computation(s) (MASEC).

### TECHNICAL FIELD

The present disclosure relates to a processing system, or component thereof, and methods of making and using thereof, the system or component comprising at least one semiconductor device for real number computation using real machine computer integrated circuits implementing matter amplification by stimulated emission computation(s) (MASEC).

### BACKGROUND

There is a need to provide improved semiconductor devices for data processing and analysis to improve the performance and speed of real number computations and/or to provide improved computer processing units (CPUs).

The principles of “matter amplification by stimulated emission of radiation” (MASER) were first discovered by Charles H. Townes, Nikolay Basov, and Alexander Prokhorov between 1947 through 1950. Townes, Basov, and Prokhorov shared the 1964 Nobel Prize in Physics for their quantum electronic discoveries leading to the maser. The first maser was built and demonstrated by Charles H. Townes, James P. Gordon, and Herbert J. Zeiger at Columbia University in 1953. Stimulated emission is the process by which an incoming photon of a specific frequency can interact with an excited atomic electron (or other excited molecular state), causing it to drop to a lower energy level. The liberated energy transfers to the electromagnetic field, creating a new photon with frequency, polarization, and direction of travel identical to the photons of the incident wave. The maser is a device that produces coherent electromagnetic waves through amplification by stimulated emission. The maser is the basis for the laser, which is a device that works by this principle, but produces higher frequency coherent radiation at visible wavelengths.

### SUMMARY

According to various aspects hereof, the acronym MASEC stands for “Matter Amplification by Stimulated Emission Computation” device. A MASEC according to the present invention described herein is based on a new adaptation of maser/laser principles, but instead of generating light using a MASER, the MASEC is emission resonance tuned to emit real number computations. Such MASEC real machines can be designed and provided in certain implementations as III-V Monolithic Microwave Integrated Circuits (MMICs).

MASEC devices, computers, and/or circuits according to various aspects of the present invention can be provided as a new semiconductor device used to implement real number and other number computations, where MASEC devices, computers, and/or circuits are the fundamental building blocks of new real machine computer integrated circuits. MASEC devices, computers, and/or circuits according to the invention have the potential to make transistors and quantum computing obsolete. MASEC real machines according to the invention can operate on both high precision complex numbers and real numbers, whereas digital and quantum computers are limited to computable rational numbers. MASEC real machines of the invention enable a novel differentiable model of real number computations, which are not computable by PSPACE reducible digital or quantum machines. In computational complexity theory, PSPACE is the set of all decision problems that are solvable by a Turing machine using a polynomial amount of space. Consequently, new MASEC real machines according to the invention are expected to exceed Turing machine computation. MASEC circuits of the invention can optionally include tiny 50 micron die size and operate at up to several terahertz frequencies. MASEC devices, computers, and/or circuits of the invention function for computation analogous to a laser as used in MASERs. A laser is a device that emits light through a process of optical amplification based on the stimulated emission of electromagnetic radiation. MASEC devices, computers, and/or circuits are similar in this principle to the laser, but instead of emitting light, MASEC devices, computers, and/or circuits emit real number computations. Analogous to a laser in MASERs, MASEC devices, computers, and/or circuits can optionally require direct/zero band-gap semiconductor materials.

A MASEC example computation is a substantially instantaneous O(1) time calculation of the discrete logarithm. In mathematics, for given real numbers a and b, the logarithm log b a is a number x such that bx=a. Analogously, in any group G, powers bk can be defined for all integers k, and the discrete logarithm log b a is an integer k such that bk=a.1 No efficient method is known for computing
them in general. Several important algorithms in public-key cryptography base their security on the assumption that the discrete logarithm problem over carefully chosen groups has no efficient solution. This includes the Monero cryptocurrency privacy token, preferred for illegal activities.

MASEC devices, computers, and/or circuits of the invention can harness the quantum mechanical nature of bulk matter directly for computation and are not restricted to semiconductor solid-state materials. MA SEC devices, computers, and/or circuits can be a replacement for transistors and/or quantum qubits, and can be used to implement all forms of electronics, computer memories, EEPROMs, processors, and devices currently implemented using transistors or quantum qubits.

### BRIEF DESCRIPTION OF THE DRAWINGS

The disclosure of various aspects and optional aspects of the present invention will be understood more fully from the detailed description given below and from the accompanying drawings/figures of various optional embodiments of the disclosure. The drawings, however, should not be taken to limit the disclosure to the specific embodiments, but are for explanation and understanding only as optional aspects and embodiments of the invention, any of which embodiments or aspects can be modified, changed, combined, or integrated according to the description provided herein.

FIG. 1 illustrates the overlap of different number types used in calculations and corresponding types of computer processors that can perform calculations for the different number types.

FIG. 2 illustrates a graphical representation of the correlation between discrete logarithmic current (e.g., mA) is correlated with discrete logarithmic time input voltage (V) according to one or more embodiments of the present disclosure.

FIG. 3 illustrates a discrete logarithm MASEC that is fabricated from InGaP. When the MASEC temperature is changed by 1000 centigrade, the base of the discrete logarithm is shifted, e.g., using temperature, and appropriately tuned material composition, the MASEC discrete logarithm device converts logarithm bases according to one or more embodiments of the present disclosure.

FIGS. 4-10B (with FIG. 9B showing prior art CMOS chip configuration), show circuit and other diagrams representing one or more MASEC discrete logarithm devices that can optionally incorporate or comprise an indium gallium phosphide (InGaP) diode. MMIC planar circuitry provides high impedance isolation and signal amplification for the MASEC devices, computers, and/or circuits. In such an example, MASEC devices, computers, and/or circuits of the invention can create high resolution real number discrete logarithms at frequencies up to 3 THz in O(1) time. Without impedance shielding and planar circuitry the MASEC device, computer, and/or circuit is not functional, as diode electrical loads corrupt the MASEC's stimulated emission signaling integrity according to one or more embodiments of the present disclosure. As shown in FIGS. 10A-10B, a MASEC device, computer, and/or circuit of the present invention can be optionally implemented using one or more of two or more diode types, such as, but not limited to, a semi-conductor diode MASEC; or a semiconductor HBT-diode MASEC, e.g., as a diode connected transistor, such as, but not limited to an HBT diode, which can have one or more of: a higher signal noise, lower real number resolution, less efficient MASEC operation and/or reduced operational frequencies.

FIG. 11 illustrates a general flowchart of the MASEC Real Machine NP-complete solution circuit algorithm, wherein the steps can include one, two, three, and/or four of more of: (1) Convert boolean formula to polynomial; (2) Select bit to be determined (e.g., i-th bit); (3) Evaluate the integrals as provided above; (4) Repeat the process for all remaining bits of the original Boolean formula; and/or (5) Based on the outcome of the previous calculation(s), choose/select/incorporate the i-th bit, according to one or more embodiments of the present disclosure.

FIG. 12 illustrates a graphical representation of a linear-time conversion algorithm from ANY boolean satisfiability formula to a 3SAT formula, according to one or more embodiments of the present disclosure.

FIG. 13 illustrates a diagrammatic representation of a machine in the example form of a computer system 1200 within which a set of instructions, for causing the machine to perform any one or more of the methodologies discussed herein, may be executed.

FIG. 14 illustrates diagrammatic representation of a network provided based on creating a command and control broadcast network with 100 nodes and 1000 links (edges) connections. There is one HACM ONS (Octopus Neural System) at each node, with each ONS having the same number of tentacles as the number of connections that the node supports plus command and control tentacles.

FIGS. 15A-15I illustrate graphical representations of non-limiting examples of MASEC implementation of Artificial Neural Network (ANN) activation (also called squashing) functions. In ANNs, each neuron forms a weighted sum of its inputs and passes the resulting scalar value through its activation function. ANN activation (squashing) function diverse examples are shown in FIGS. 15A-15I (as: ReLU FIG. 15A; Leaky ReLU FIG. 15B; Tanh FIG. 15C; Binary Step Function FIG. 15D; Linear FIG. 15E; SELU FIG. 15F; ELU FIG. 15G; Sigmoid/Logistic FIG. 15H; and/or Parametric ReLU FIG. 15I).

FIGS. 16-17 illustrate graphical representations showing that direct band gap semiconductors can be more optimal or preferred than indirect band gap semiconductors, where indirect band gap semiconductors may be less optimal for use in MASEC devices, computers, or circuits, where indirect band gap semiconductors require phonon assisted transition to move energy from the valence band to the conduction band, whereas direct band gap materials do not, so direct band gap semiconductors will have faster and/or more accurate data and signal processing than indirect band gap semiconductors. In physics, a phonon is a collective excitation in a periodic, elastic arrangement of atoms or molecules in condensed matter. Phonons are a type of quasiparticle. Quasiparticles are closely related, coupled, emergent phenomena arising when a microscopically complex system of fermion (matter) particles interact as a quantum mechanically loosely coupled unified cluster within a solid (and some superfluid's, e.g., but not limited to Helium 3). Phonon interactions that mediate indirect band gap energy transitions are sensitive to thermal noise and can further act as a dampening effect on MASEC resolution.

FIGS. 18A-18B illustrate graphical representations where MASEM memory elements can be integral to MASEC HACM neuron centric machine learning device disclosed herein. Specifically, the HACM neuron implemented using one MASEM per neuron provides extremely high operational frequencies extending up and beyond 3000 Gigahertz (e.g., but not limited to, 100-500, 500-1000, 740-1250, 1500-2500, 1000-3000, 1500-4000, 3000-5000, 4000-6000, 5000-7000, 6000-8000, 7000-9000, 8000-10,000 Gigahertz, or any range, combination, or value therein) using InGaAs process MASEM devices. The Smith charts as FIG. 18A-B validate the HACM neuron characterized frequencies. This ultraperformance and the total lack of arithmetic operations show the HACM AN is a synthetic neuron. INSERT

FIG. 19 provides a miner block diagram illustrating the dataflow is shown in FIG. 19 (SAT MINER). In the MASEC SAT Bitcoin miner approach of the invention, solving for the nonce is through a Boolean SAT equation, which has a solution. This is in stark contrast to the current brute force approach, which is energy wasteful guessing. The resulting MASEC SAT miner would solve for the nonce more rapidly and require a fraction of the electrical power of current Bitcoin miners. Referring to the block diagram FIG. 19, in the MASEC SAT approach, SHA256 is converted to Conjunctive Normal Form (CNF) before presentation to the MASEC SAT solver. In Boolean logic, a formula is in CNF (or clausal normal form) if it is a conjunction of one or more clauses, where a clause is a disjunction of literals; otherwise put, it is a product of sums or an AND of ORs suitable for input for the MASEC 3SAT algorithm described in the main section of this document. More generally, as a canonical normal form, this is useful in automated theorem proving and specifically digital circuit verification. Once SHA256 is converted to CNF the MASEC SAT solver in the miner block diagram FIG. 19 makes a guess for a particular input bit of the SHA256 input value. The remaining bits can be shuffled by making use of the multidimensional integration outlined in the main section of this disclosure. Since the bit guessed can be 0 and 1, then by comparing ONLY THE LINEAR components of the functions H0(ε) and H1(ε) the miner can select the value of the bits based on this comparison: the one that corresponds to the higher slope offers the miner a faster option to solve the cryptographic puzzle, therefore, leading to a high probability of winning the Bitcoin mining race.

FIG. 20 illustrates a visual representation where MASEC memories can always store real number values including single bits of data, so are far denser than any form of transistor memory. MASEC memories are fabricated using two terminal diode like structures with a cathode and anode. MASEC memories are arranged in arrays as shown in the image provided in FIG. 20. MASEC memories arranged as arrays are much simpler than transistor-based memory and have storage cycle times up to 3000 Gigahertz frequency. There is no MASEC feature size as with transistor-based memory since the spherical MASEC structure extends into the Z depth plane. Reducing MASEC physical size is through reducing the MASEC memory cathode/anode diameter. This leads to better MASEC scaling than with quantum limited transistor memories.

### DETAILED DESCRIPTION

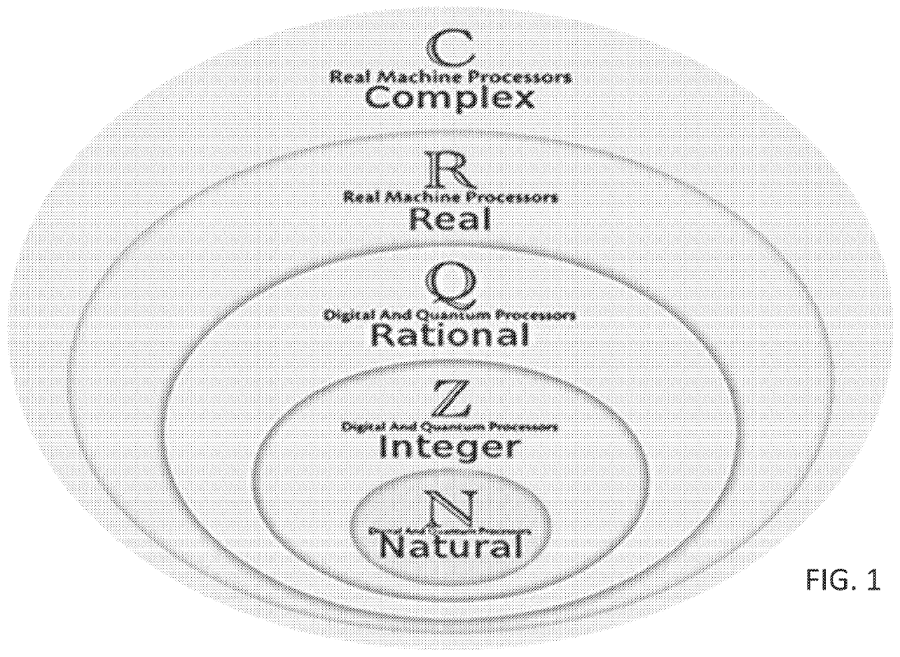

According to various aspects of the present invention, a MASEC device, computer, and/or circuit has been developed that is analogous to using maser/laser principles for light, but instead of generating light using a MASER, the MASEC device, computer, and/or circuit is emission resonance tuned to emit real number computations. MASEC real machines of the invention can be designed as III-V Monolithic Microwave Integrated Circuits (MMICs). A MASEC device, computer, and/or circuit is a new semiconductor device according to the invention that can be used to implement real number computations. MASEC devices, computers, and/or circuits are the fundamental building blocks of new real machine computer integrated circuits of the invention. MASEC devices, computers, and/or circuits can make obsolete transistors and/or quantum computing. MASEC real machines of the invention can operate on both high precision complex and real numbers, whereas digital and quantum computers are limited to computable rational numbers FIG. 1. MASEC real machines of the invention enable a novel differentiable model of real number computation, which is not computable by PSPACE reducible digital or quantum machines. In computational complexity theory, PSPACE is the set of all decision problems that are solvable by a Turing machine using a polynomial amount of space. Consequently, new MASEC real machines of the invention can exceed Turing machine computation. MASEC circuits can optionally include 50 micron die size and operate at up to several terahertz frequencies. MASEC devices, computers, and/or circuits of the invention can function for computations in an analogous way to lasers used in MASERS.

MASEC devices, computers, and/or circuits harness the quantum mechanical nature of bulk matter directly for computation and are not restricted to semiconductor solid-state materials. MASEC devices, computers, and/or circuits are a replacement for transistors and/or quantum qubits, and are used to implement all forms of electronics, computer memories, EEPROMs, processors, and/or devices currently implemented using transistors or quantum qubits. A laser is a device that emits light through a process of optical amplification based on the stimulated emission of electromagnetic radiation. MASEC devices, computers, and/or circuits are similar in this principle to the laser, but instead of emitting light, MASEC devices, computers, and/or circuits emit real number computations. Analogous to a laser in MASERs, MASEC devices, computers, and/or circuits can optionally require direct/zero band-gap semiconductor materials.

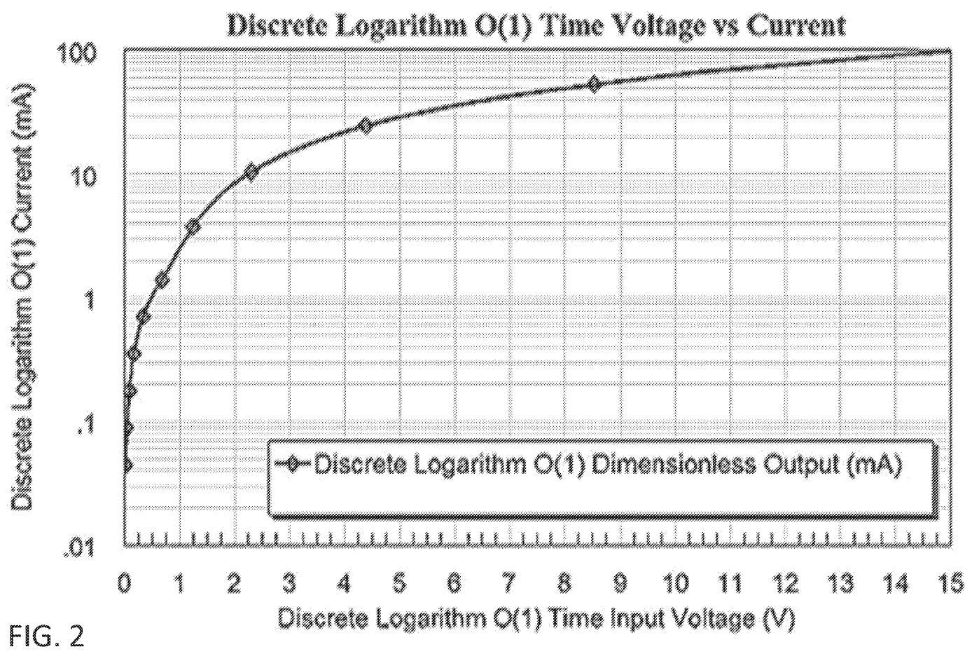

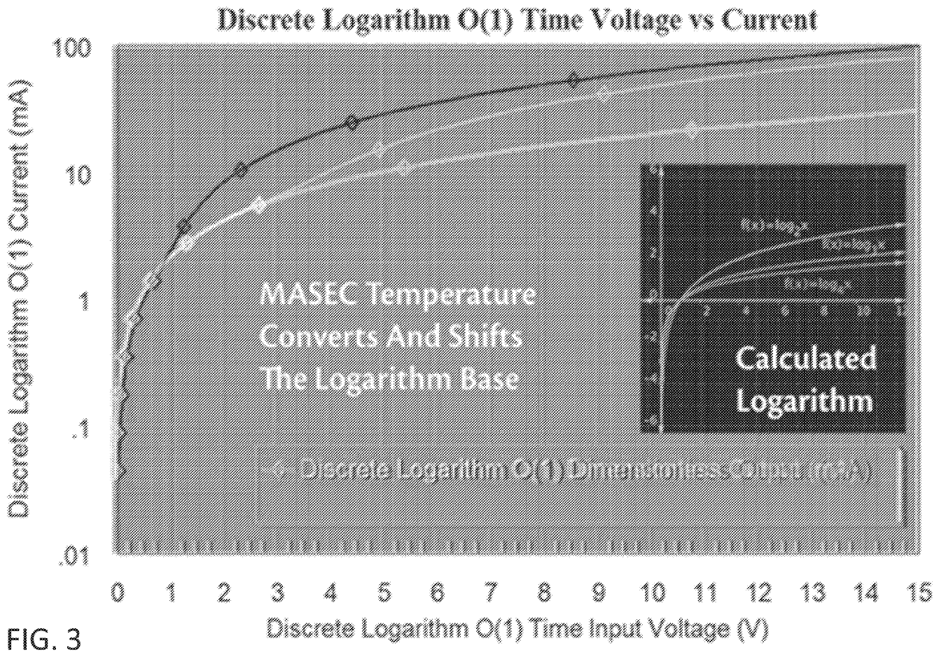

According to optional aspects of the present invention, MASEC physical properties, including but not limited to one or more of, or at least one of: temperature, pressure, voltage, current, and/or material composition, are used to change MASEC computational output. An example of the correlation between discrete logarithmic current (e.g., mA) is correlated with discrete logarithmic time input voltage (V) as shown in FIG. 2. As a non-limiting example, a discrete logarithm MASEC device, computer, and/or circuit is fabricated from InGaP. When the MASEC device, computer, and/or circuit temperature is changed by 1000 centigrade, the base of the discrete logarithm is shifted, e.g., using temperature, and appropriately tuned material composition, the MASEC discrete logarithm device converts logarithm bases, as shown in FIG. 3.

As shown in FIG. 3, an aspect of MASEC device technology of the present invention is where its physical properties and its interactions with the environment can be modified to change the computations, which take place in O(1) constant time, no matter the computation. MASEC computation of the invention is virtually or substantially instantaneous and is based upon manipulating matter as one or more components of the device for computational purposes. Current and future digital and quantum computers manipulate bits of information. MASEC real machines of the invention can generate solutions to computational problems by direct emission stimulation. This may be viewed analogously to how the focal length of an optical system converges or diverges light. According to the invention, with the MASEC device, computer, and/or circuit, such adjustments of properties result in a different computational output. In this way MASEC devices of the invention may be constructed to implement a plurality of computational solutions. Essentially, MASEC quantum electrodynamic, thermodynamic, and/or material compositions for computations of the invention result in a coherent computational output from MACEC comprising integrated circuits for a very wide range of applications, e.g., but not limited to, from heart pacemakers to rocket guidance systems, and in between, as well as machine learning systems able to predict and modulate magnetic flux fusion containment systems in real-time. MASEC devices, computers, and/or circuits of the invention can optionally include use or incorporation in diodes in the design environment.

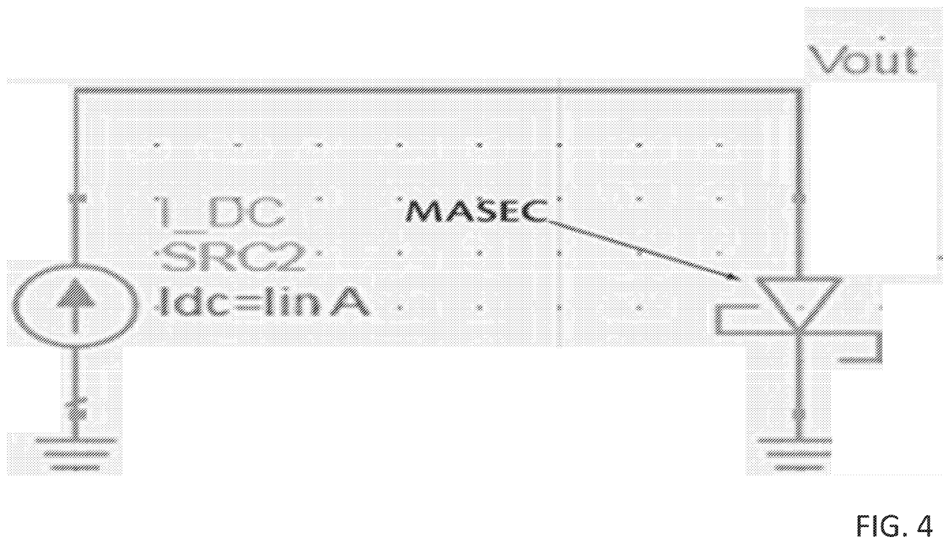

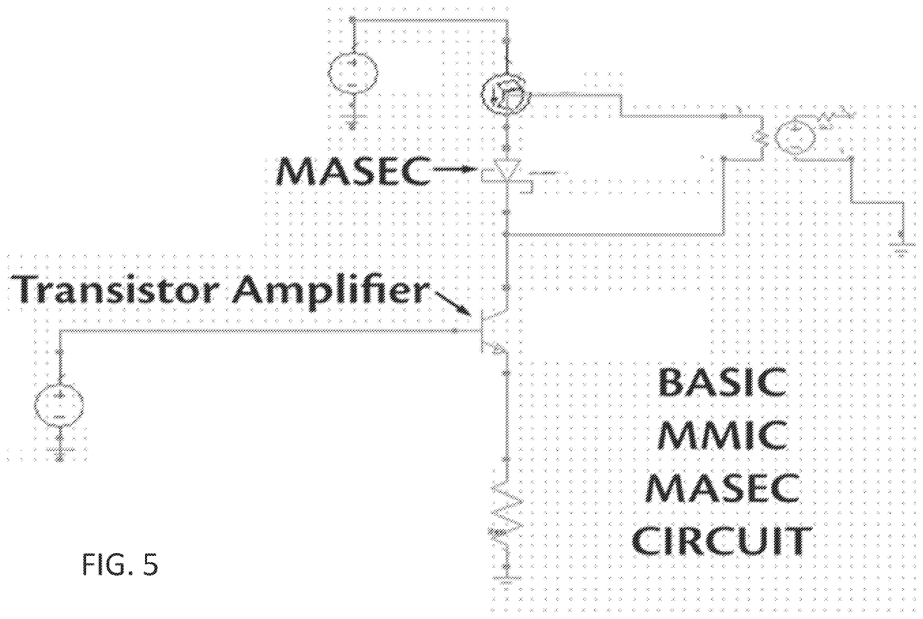

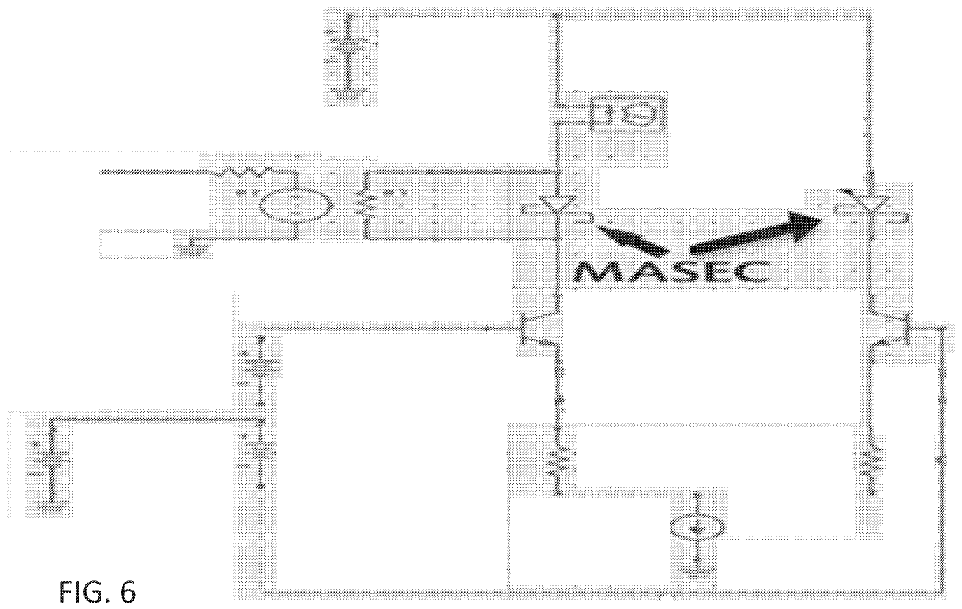

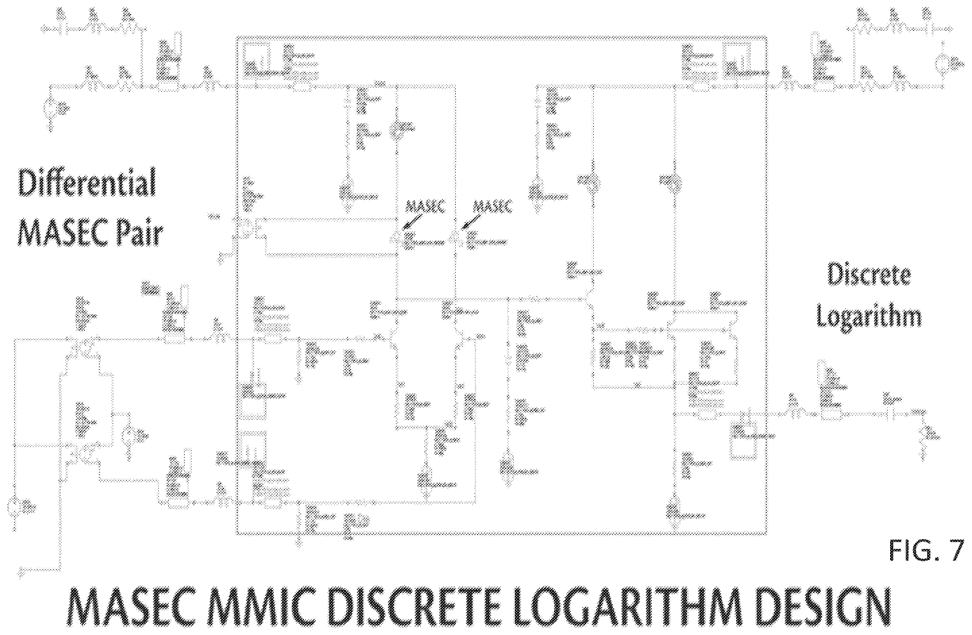

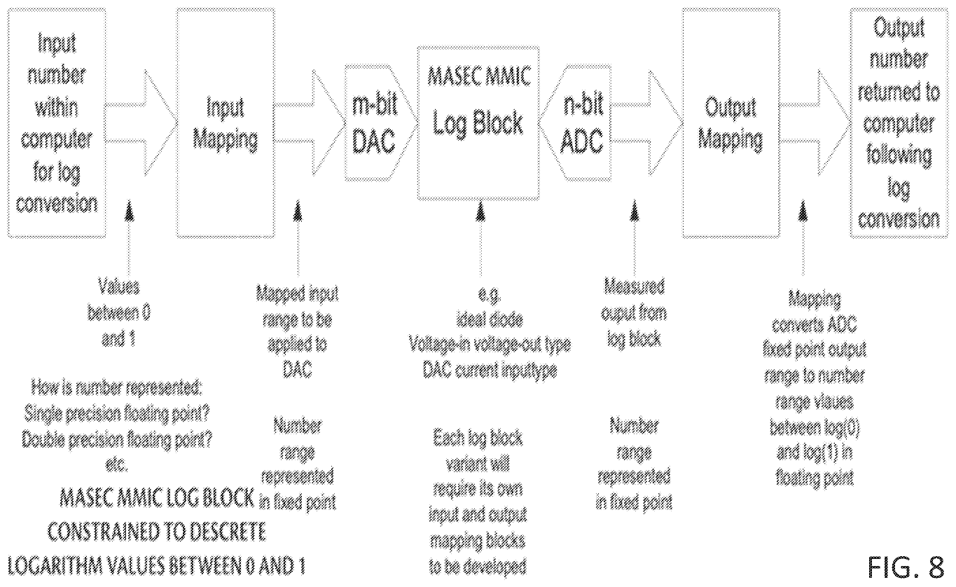

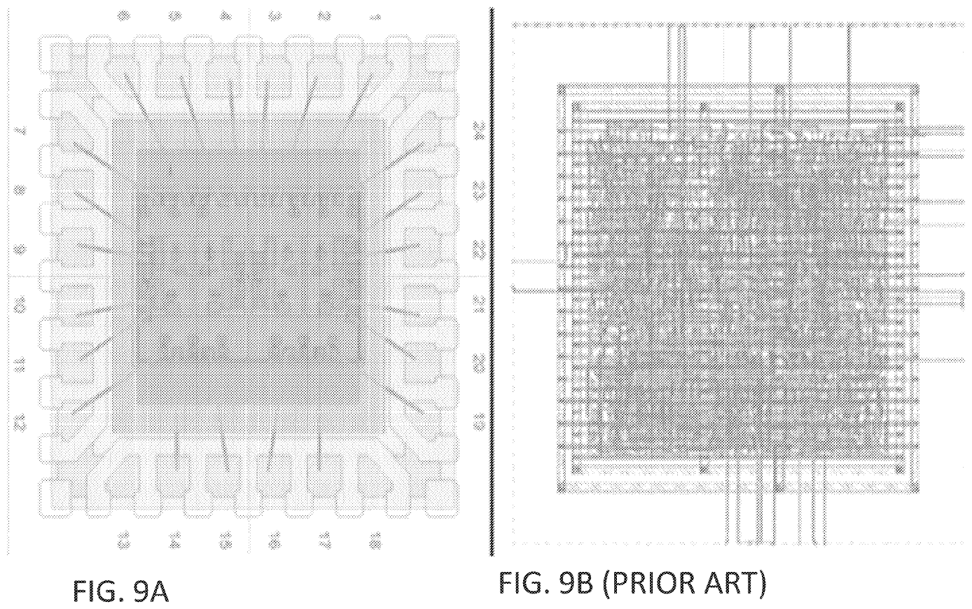

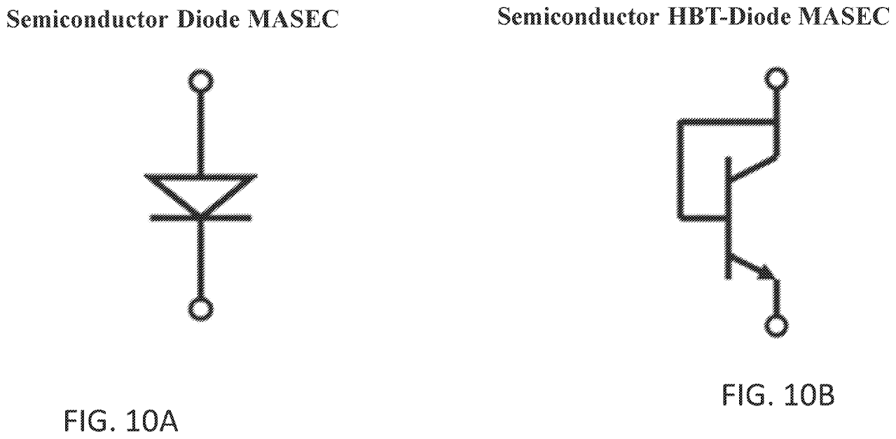

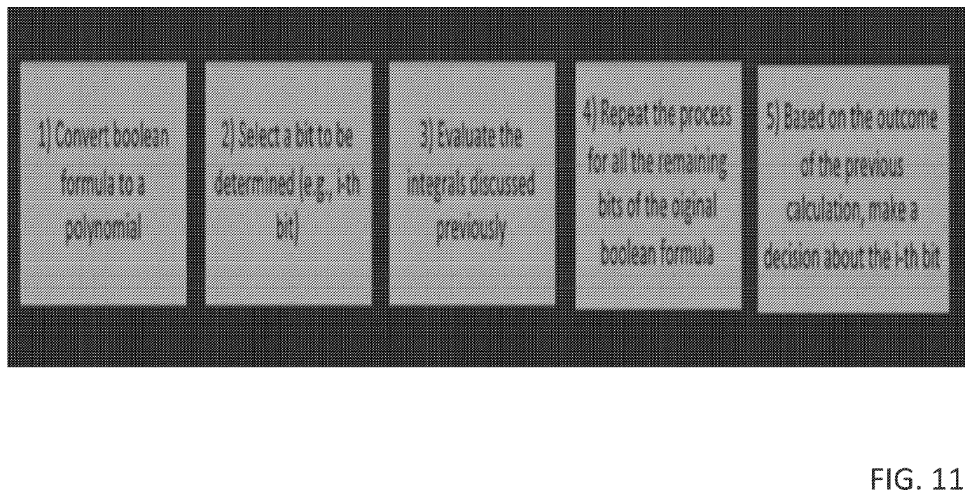

As a non-limiting example, as shown in FIGS. 4-9B (with FIG. 9B showing prior art CMOS chip configuration), one or more MASEC discrete logarithm devices can incorporate or comprise an indium gallium phosphide (InGaP) diode. MMIC planar circuitry provides high impedance isolation and signal amplification for the MASEC device, computer, and/or circuit. In such an example, a MASEC device, computer, and/or circuit of the invention can create high resolution real number discrete logarithms at frequencies up to 3 THz in O(1) time. Without impedance shielding and planar circuitry the MASEC device, computer, and/or circuit can potentially be not completely functional, as diode electrical loads can potentially corrupt one or more aspects of the MASEC's stimulated emission signaling integrity. As shown in FIG. 10A-10B, MASEC's of the present invention can be optionally implemented using one or more of two or more diode types, such as, but not limited to, a semi-conductor diode MASEC; or a semiconductor HBT-diode MASEC, e.g., as a diode connected transistor, such as, but not limited to an HBT diode, which can have one or more of: a higher signal noise, lower real number resolution, less efficient MASEC operation and/or reduced operational frequencies.

As a non-limiting example, an adjacency matrix can be provided for one or more of the examples or embodiments of the invention provided herein, e.g., for each node what other node is connected to it. This can be one of the bases for a HACM ONS (Octopus Neural System) node learning to determine how to get one or more messages through a network to all nodes with the minimum delay. A zero means no connection to the associated (matrix form) node and a one indicates a connection to a node in the network matrix.

{{0, 0, 1, 0, 0, 1, 0, 0, 1, 0, 0, 0, 0, 1, 0, 0, 0, 1, 0, 0, 0,
0, 1, 1, 0, 0, 0, 0, 1, 0, 0, 1, 0, 1, 0, 0, 1, 0, 0, 0, 1, 1, 0,
0, 0, 1, 0, 1, 1, 1, 0, 0, 0, 1, 0, 0, 0, 1, 0, 1, 1, 1, 0, 1, 0, 0, 1, 0,
1, 0, 1, 1, 0, 1, 1, 1, 0, 0, 0, 0, 1, 0, 0, 1, 0, 1, 1, 1, 1, 0,
1, 1, 0, 0, 0, 1, 0, 1, 0, 0}, {0, 0, 1, 0, 0, 1, 1, 0, 0, 0, 1, 1,
0, 0, 0, 0, 0, 1, 1, 0, 0, 1, 0, 1, 0, 1, 0, 0, 1, 0, 0, 0, 0, 0, 1,
0, 0, 1, 0, 0, 0, 1, 1, 0, 0, 0, 0, 0, 1, 1, 1, 0, 1, 0, 1, 1, 0,
0, 0, 1, 1, 0, 1, 0, 1, 1, 1, 0, 1, 1, 0, 1, 1, 0, 1, 0, 0, 1, 0, 0,
0, 0, 0, 1, 0, 1, 0, 1, 1, 0, 0, 1, 0, 0, 1, 1, 0, 0, 0, 1}, {1, 1,
0, 1, 1, 1, 0, 1, 0, 1, 1, 1, 0, 1, 0, 0, 0, 0, 0, 1, 1, 1, 1, 1,
1, 0, 0, 0, 0, 0, 0, 0, 1, 0, 0, 0, 0, 0, 1, 1, 0, 0, 0, 1, 1, 0, 0,
0, 1, 0, 0, 1, 1, 0, 0, 0, 0, 0, 0, 1, 0, 1, 1, 1, 0, 0, 0, 1, 0,
1, 1, 0, 1, 1, 0, 0, 0, 1, 0, 0, 0, 0, 1, 1, 1, 0, 1, 0, 1, 0, 0, 0,
0, 1, 1, 0, 0, 0, 0, 0}, {0, 0, 1, 0, 0, 0, 1, 0, 0, 0, 1, 0, 0, 1,
0, 0, 0, 0, 0, 0, 0, 0, 0, 1, 0, 0, 0, 0, 0, 1, 1, 0, 0, 0, 1, 0,
0, 0, 0, 0, 0, 0, 0, 0, 0, 1, 0, 1, 0, 1, 0, 1, 0, 0, 0, 0, 0, 1, 0,
1, 1, 0, 0, 0, 1, 1, 1, 0, 0, 1, 0, 1, 0, 1, 1, 0, 1, 0, 1, 0, 0,
1, 1, 1, 1, 0, 0, 0, 0, 0, 0, 0, 0, 1, 1, 1, 0, 1, 0, 0}, {0, 0, 1,
0, 0, 0, 1, 0, 0, 1, 0, 0, 1, 0, 0, 0, 1, 0, 1, 1, 1, 0, 0, 1, 0, 0,
1, 0, 1, 1, 0, 0, 1, 1, 0, 0, 0, 1, 1, 0, 1, 1, 0, 0, 0, 0, 0, 1,
1, 1, 0, 0, 1, 0, 0, 0, 1, 1, 0, 0, 1, 0, 1, 1, 0, 0, 1, 1, 0, 1, 1,
0, 1, 0, 0, 0, 1, 0, 0, 1, 0, 1, 1, 0, 0, 1, 1, 0, 0, 1, 1, 0, 0,
1, 0, 1, 0, 1, 0, 1}, {1, 1, 1, 0, 0, 0, 1, 1, 1, 0, 0, 0, 0, 0, 0,
1, 0, 0, 0, 0, 1, 0, 1, 0, 0, 0, 1, 1, 0, 0, 0, 1, 1, 0, 1, 0, 1, 0,
1, 1, 0, 0, 0, 0, 1, 1, 0, 1, 0, 0, 0, 1, 0, 1, 0, 1, 0, 1, 0, 0,
0, 1, 1, 0, 0, 1, 0, 0, 0, 0, 0, 1, 0, 0, 0, 0, 1, 0, 0, 0, 0, 1, 1,
1, 1, 0, 0, 1, 1, 0, 0, 0, 0, 0, 0, 1, 0, 0, 0, 0}, {0, 1, 0, 1, 1,
1, 0, 0, 0, 1, 1, 1, 0, 0, 1, 1, 0, 0, 0, 0, 1, 1, 0, 0, 0, 1, 1,
0, 0, 0, 1, 1, 1, 1, 1, 0, 1, 1, 0, 0, 0, 1, 1, 1, 0, 0, 0, 0, 0, 0,
0, 0, 0, 0, 0, 1, 0, 1, 0, 0, 1, 0, 0, 0, 0, 0, 0, 1, 0, 0, 0, 1,
1, 1, 1, 0, 1, 0, 0, 0, 0, 0, 0, 0, 0, 1, 0, 0, 1, 1, 1, 1, 0, 1, 0,
0, 0, 0, 0, 0}, {0, 0, 1, 0, 0, 1, 0, 0, 1, 0, 0, 1, 1, 1, 1, 1, 0,
0, 0, 1, 0, 1, 0, 0, 0, 0, 0, 1, 0, 0, 0, 0, 0, 1, 1, 0, 1, 1, 1,
0, 1, 0, 1, 0, 0, 1, 0, 1, 0, 0, 0, 0, 1, 0, 1, 0, 1, 0, 0, 0, 0, 0,
0, 1, 0, 0, 0, 0, 0, 0, 1, 1, 1, 1, 0, 1, 0, 0, 1, 0, 0, 0, 0, 0,
1, 0, 0, 1, 1, 0, 0, 1, 0, 1, 0, 0, 0, 0, 0, 1}, {1, 0, 0, 0, 0, 1,
0, 1, 0, 1, 0, 0, 0, 1, 1, 1, 1, 0, 0, 1, 0, 0, 0, 0, 1, 1, 1, 1, 0,
1, 0, 0, 0, 0, 0, 0, 0, 0, 0, 0, 0, 0, 0, 0, 0, 0, 0, 0, 1, 0, 1,
0, 0, 0, 0, 1, 0, 1, 1, 0, 0, 0, 0, 1, 0, 0, 0, 1, 0, 1, 0, 1, 0, 1,
0, 0, 0, 1, 0, 0, 0, 1, 0, 0, 1, 0, 0, 1, 1, 1, 1, 1, 0, 1, 1, 1,
1, 1, 0, 1}, {0, 0, 1, 0, 1, 0, 1, 0, 1, 0, 1, 0, 1, 1, 0, 1, 0, 0,
0, 1, 1, 1, 1, 0, 0, 1, 0, 1, 0, 1, 0, 0, 1, 1, 1, 0, 0, 0, 1, 1, 0,
0, 1, 0, 1, 0, 1, 0, 1, 1, 1, 0, 0, 1, 0, 1, 1, 0, 0, 1, 0, 0, 1,
1, 1, 0, 0, 0, 0, 1, 1, 0, 1, 1, 1, 0, 0, 0, 0, 1, 1, 0, 0, 0, 0, 1,
0, 1, 0, 1, 0, 1, 0, 1, 0, 0, 1, 0, 0, 0}, {0, 1, 1, 1, 0, 0, 1, 0,
0, 1, 0, 1, 0, 1, 1, 0, 1, 1, 1, 0, 1, 1, 0, 0, 0, 1, 0, 0, 1, 1,
0, 0, 1, 1, 0, 0, 1, 1, 1, 0, 0, 1, 0, 0, 0, 0, 1, 0, 1, 1, 0, 1, 1,
1, 0, 0, 0, 0, 1, 0, 1, 0, 0, 0, 1, 0, 0, 0, 0, 1, 1, 1, 0, 1, 1,
0, 1, 0, 0, 1, 1, 1, 1, 0, 0, 1, 1, 1, 0, 1, 0, 0, 1, 0, 0, 0, 0, 0,
1, 1}, {0, 1, 1, 0, 0, 0, 1, 1, 0, 0, 1, 0, 0, 0, 0, 0, 1, 0, 1, 1,
0, 1, 1, 0, 1, 0, 0, 0, 0, 0, 0, 0, 0, 0, 1, 1, 0, 0, 1, 1, 0, 1,
0, 1, 1, 0, 1, 1, 0, 1, 0, 1, 1, 1, 1, 1, 0, 0, 1, 1, 1, 0, 0, 0, 0,
0, 0, 0, 0, 0, 0, 1, 1, 0, 1, 1, 1, 0, 1, 0, 0, 1, 1, 1, 1, 0, 1,
1, 0, 0, 0, 0, 1, 0, 0, 1, 0, 0, 0, 0}, {0, 0, 0, 0, 1, 0, 0, 1, 0,
1, 0, 0, 0, 0, 1, 1, 0, 0, 1, 0, 0, 1, 1, 0, 0, 0, 0, 1, 0, 1, 0, 1,
1, 0, 0, 0, 0, 0, 0, 1, 1, 1, 1, 1, 0, 1, 1, 0, 1, 0, 0, 0, 0, 1,
0, 1, 0, 0, 1, 0, 1, 0, 1, 0, 0, 0, 0, 0, 1, 1, 1, 0, 0, 0, 1, 1, 0,
1, 0, 1, 0, 0, 0, 0, 0, 1, 1, 0, 0, 0, 0, 0, 0, 1, 1, 0, 1, 1, 0,
0}, {1, 0, 1, 1, 0, 0, 0, 1, 1, 1, 1, 0, 0, 0, 1, 0, 0, 0, 0, 0, 0,
1, 0, 1, 1, 1, 1, 0, 0, 0, 1, 1, 0, 0, 0, 1, 1, 1, 0, 0, 0, 0, 1, 1,
0, 0, 1, 0, 0, 0, 1, 1, 0, 1, 1, 0, 0, 0, 1, 0, 1, 1, 1, 0, 0, 0,
0, 0, 0, 0, 0, 0, 0, 0, 0, 1, 0, 0, 1, 0, 0, 0, 0, 0, 1, 0, 1, 0, 1,
0, 1, 1, 0, 0, 1, 0, 0, 0, 0, 1}, {0, 0, 0, 0, 0, 0, 1, 1, 1, 0, 1,
0, 1, 1, 0, 0, 0, 0, 0, 0, 0, 0, 1, 1, 0, 0, 1, 0, 1, 0, 0, 0, 0,
0, 1, 1, 0, 0, 1, 0, 1, 1, 0, 0, 0, 0, 0, 0, 1, 0, 1, 0, 0, 0, 1, 0,
0, 1, 0, 1, 1, 1, 0, 1, 0, 0, 1, 1, 1, 0, 0, 0, 0, 0, 1, 0, 0, 1,
0, 0, 1, 0, 0, 0, 0, 1, 1, 0, 1, 1, 0, 0, 1, 1, 1, 1, 0, 1, 0,
0}, {0, 0, 0, 0, 0, 1, 1, 1, 1, 1, 0, 0, 1, 0, 0, 0, 0, 1, 0, 1, 0,
0, 0, 1, 0, 0, 1, 0, 1, 0, 1, 0, 0, 0, 1, 1, 1, 0, 1, 0, 1, 0, 0, 1,
0, 1, 0, 1, 1, 0, 0, 1, 0, 0, 1, 1, 0, 0, 0, 0, 0, 1, 0, 1, 1, 0,
0, 0, 0, 1, 0, 0, 1, 0, 0, 1, 0, 1, 0, 1, 0, 0, 1, 0, 0, 0, 0, 1, 0,
0, 1, 1, 1, 1, 0, 1, 0, 0, 0, 0}, {0, 0, 0, 0, 1, 0, 0, 0, 1, 0, 1,
1, 0, 0, 0, 0, 0, 0, 0, 1, 1, 1, 0, 0, 0, 0, 0, 0, 0, 0, 0, 1, 0,
0, 1, 1, 0, 0, 1, 0, 0, 1, 0, 1, 0, 1, 0, 0, 1, 0, 0, 1, 0, 0, 0, 0,
0, 0, 0, 0, 1, 0, 0, 1, 0, 0, 1, 0, 1, 0, 0, 0, 1, 1, 1, 0, 0, 0,
0, 1, 0, 0, 0, 0, 1, 1, 0, 0, 0, 0, 0, 0, 0, 0, 1, 1, 0, 1, 0,
1}, {1, 1, 0, 0, 0, 0, 0, 0, 0, 0, 1, 0, 0, 0, 0, 1, 0, 0, 0, 0, 0,
1, 0, 1, 0, 0, 1, 1, 0, 0, 1, 0, 0, 0, 0, 1, 0, 1, 1, 0, 0, 0, 1, 0,
1, 0, 1, 1, 0, 0, 0, 0, 1, 1, 0, 0, 1, 0, 0, 0, 0, 0, 1, 0, 1, 0,
0, 1, 0, 1, 0, 0, 0, 0, 0, 0, 1, 0, 1, 0, 1, 1, 0, 1, 0, 1, 1, 1, 0,
0, 0, 0, 0, 1, 1, 0, 0, 0, 0, 1}, {0, 1, 0, 0, 1, 0, 0, 0, 0, 0, 1,
1, 1, 0, 0, 0, 0, 0, 0, 0, 1, 0, 1, 1, 1, 0, 1, 1, 0, 0, 1, 1, 1,
0, 1, 1, 0, 1, 1, 1, 0, 0, 0, 0, 0, 1, 0, 0, 1, 0, 1, 1, 0, 1, 1, 1,
1, 0, 1, 1, 0, 0, 0, 0, 1, 0, 1, 0, 1, 1, 1, 0, 0, 1, 0, 1, 0, 1,
0, 0, 0, 1, 0, 1, 1, 0, 0, 0, 0, 0, 0, 0, 0, 1, 1, 0, 0, 1, 0,
0}, {0, 0, 1, 0, 1, 0, 0, 1, 1, 1, 0, 1, 0, 0, 0, 1, 1, 0, 0, 0, 0,
0, 1, 1, 1, 0, 0, 1, 0, 0, 1, 0, 0, 0, 0, 1, 1, 0, 0, 1, 0, 0, 0, 1,
1, 1, 0, 1, 0, 1, 1, 0, 1, 0, 0, 0, 0, 0, 1, 1, 1, 0, 0, 1, 0, 0,
1, 0, 0, 0, 0, 0, 0, 0, 0, 1, 0, 0, 0, 0, 1, 0, 0, 0, 1, 0, 0, 1, 0,
0, 0, 0, 1, 1, 1, 1, 0, 1, 0, 1}, {0, 0, 1, 0, 1, 1, 1, 0, 0, 1, 1,
0, 0, 0, 0, 0, 1, 0, 1, 0, 0, 0, 0, 1, 0, 0, 0, 1, 0, 0, 1, 1, 0,
1, 1, 0, 1, 1, 0, 1, 1, 0, 0, 0, 0, 0, 0, 1, 1, 0, 0, 1, 0, 1, 0, 0,
0, 1, 1, 0, 0, 0, 0, 0, 1, 0, 0, 1, 0, 0, 0, 0, 1, 0, 1, 0, 0, 1,
1, 1, 0, 0, 0, 1, 0, 1, 0, 0, 0, 0, 0, 0, 0, 0, 1, 0, 0, 0, 1,
1}, {0, 1, 1, 0, 0, 0, 1, 1, 0, 1, 1, 1, 1, 1, 0, 0, 1, 1, 0, 0, 0,
0, 0, 0, 0, 0, 1, 1, 0, 1, 0, 1, 1, 1, 0, 1, 1, 0, 1, 1, 0, 0, 0, 1,
0, 0, 0, 0, 1, 0, 0, 0, 1, 0, 0, 1, 0, 0, 0, 1, 1, 1, 1, 1, 0, 0,
0, 0, 0, 0, 0, 0, 1, 0, 0, 1, 0, 0, 0, 0, 0, 0, 0, 0, 0, 1, 0, 0, 1,
0, 0, 1, 0, 1, 0, 1, 1, 1, 0, 0}, {1, 0, 1, 0, 0, 1, 0, 0, 0, 1, 0,
1, 1, 0, 1, 0, 0, 0, 1, 1, 0, 0, 0, 1, 0, 1, 0, 0, 1, 1, 0, 0, 0,
0, 1, 1, 0, 0, 0, 0, 0, 0, 0, 0, 0, 0, 1, 0, 0, 0, 0, 0, 0, 0, 1, 0,
1, 0, 1, 1, 0, 1, 0, 0, 1, 1, 1, 1, 0, 0, 0, 0, 1, 1, 0, 0, 0, 1,
1, 0, 0, 0, 1, 0, 0, 1, 1, 0, 1, 0, 0, 0, 0, 0, 1, 0, 0, 1, 0,
1}, {1, 1, 1, 1, 1, 0, 0, 0, 0, 0, 0, 0, 0, 1, 1, 1, 0, 1, 1, 1, 1,
0, 1, 0, 0, 1, 1, 0, 0, 0, 1, 0, 1, 1, 1, 1, 0, 0, 1, 1, 1, 0, 0, 0,
0, 1, 0, 1, 1, 0, 0, 0, 0, 0, 1, 0, 0, 0, 0, 1, 0, 1, 0, 0, 0, 1,
0, 0, 0, 0, 1, 0, 1, 0, 0, 0, 1, 0, 0, 1, 1, 0, 0, 0, 0, 1, 1, 0, 1,
1, 0, 1, 1, 1, 1, 0, 1, 0, 0, 1}, {0, 0, 1, 0, 0, 0, 0, 0, 1, 0, 0,
1, 0, 1, 0, 0, 0, 0, 1, 1, 0, 0, 0, 0, 0, 0, 0, 0, 0, 0, 0, 1, 1,
1, 0, 0, 1, 0, 1, 1, 1, 0, 1, 0, 0, 1, 0, 1, 1, 0, 0, 0, 1, 0, 0, 1,
0, 0, 1, 0, 0, 0, 1, 0, 0, 1, 1, 1, 0, 1, 0, 0, 1, 1, 0, 0, 0, 0,
0, 0, 1, 0, 0, 0, 1, 1, 0, 0, 0, 1, 1, 0, 0, 0, 0, 0, 1, 1, 0,
0}, {0, 1, 0, 0, 0, 0, 1, 0, 1, 1, 1, 0, 0, 1, 0, 0, 0, 0, 0, 0, 0,
0, 1, 1, 0, 0, 0, 0, 0, 0, 1, 0, 0, 0, 0, 0, 1, 0, 1, 1, 0, 1, 0, 1,
1, 0, 0, 1, 1, 0, 0, 0, 0, 0, 0, 0, 0, 1, 0, 0, 1, 0, 1, 0, 1, 0,
1, 0, 0, 1, 1, 0, 0, 0, 0, 0, 0, 0, 1, 1, 0, 1, 0, 1, 1, 1, 1, 1, 1,
0, 0, 1, 1, 0, 1, 1, 1, 1, 0, 1}, {0, 0, 0, 0, 1, 1, 1, 0, 1, 0, 0,
0, 0, 1, 1, 1, 0, 1, 1, 0, 0, 1, 0, 1, 0, 0, 0, 1, 0, 1, 0, 0, 1,
0, 0, 1, 1, 1, 1, 1, 1, 0, 0, 0, 1, 1, 1, 0, 1, 1, 0, 0, 1, 0, 0, 1,
0, 1, 1, 1, 0, 0, 0, 0, 1, 0, 0, 1, 0, 1, 1, 1, 0, 0, 0, 1, 0, 0,
1, 0, 1, 0, 1, 0, 1, 1, 0, 0, 0, 0, 0, 0, 0, 1, 0, 1, 1, 1, 1,
0}, {0, 0, 0, 0, 0, 1, 0, 1, 1, 1, 0, 0, 1, 0, 0, 0, 0, 1, 1, 1, 1,
1, 0, 0, 0, 0, 1, 0, 1, 0, 1, 0, 1, 0, 0, 1, 1, 0, 1, 1, 1, 1, 1, 1,
0, 0, 0, 1, 1, 0, 0, 0, 0, 0, 1, 0, 1, 0, 0, 0, 0, 1, 0, 1, 0, 0,
0, 0, 0, 0, 1, 0, 0, 1, 0, 0, 1, 1, 0, 0, 1, 0, 0, 1, 1, 1, 1, 0, 0,
1, 1, 1, 1, 0, 0, 1, 1, 0, 1, 0}, {1, 1, 0, 0, 1, 0, 0, 0, 0, 0, 1,
0, 0, 0, 1, 1, 0, 0, 0, 0, 0, 0, 1, 0, 0, 0, 0, 1, 0, 0, 0, 0, 1,
0, 0, 1, 1, 0, 1, 0, 1, 1, 1, 1, 0, 1, 0, 1, 1, 0, 0, 1, 0, 1, 0, 1,
0, 0, 1, 1, 1, 0, 0, 0, 0, 1, 0, 1, 0, 0, 1, 1, 0, 1, 0, 1, 0, 1,
0, 0, 0, 0, 0, 0, 0, 0, 0, 1, 0, 1, 0, 0, 1, 0, 0, 0, 0, 1, 1,
1}, {0, 0, 0, 1, 1, 0, 0, 0, 1, 1, 1, 0, 1, 0, 0, 0, 0, 0, 0, 0, 0,
1, 1, 0, 0, 0, 1, 0, 0, 0, 0, 1, 0, 1, 0, 0, 0, 0, 0, 0, 1, 0, 0, 0,
1, 1, 1, 0, 1, 1, 0, 0, 0, 0, 1, 0, 1, 0, 1, 0, 0, 1, 0, 0, 0, 0,
1, 0, 0, 1, 0, 0, 0, 1, 1, 0, 1, 1, 0, 1, 1, 0, 1, 0, 0, 1, 0, 1, 0,
1, 0, 1, 1, 1, 0, 0, 1, 0, 1, 0}, {0, 0, 0, 1, 0, 0, 1, 0, 0, 0, 0,
0, 0, 1, 0, 1, 0, 1, 1, 1, 1, 0, 0, 1, 0, 1, 0, 1, 0, 0, 0, 0, 0,
1, 0, 1, 1, 1, 0, 0, 1, 0, 1, 1, 0, 1, 1, 1, 0, 1, 0, 0, 1, 0, 0, 1,
0, 0, 0, 1, 1, 0, 1, 0, 1, 0, 0, 0, 1, 0, 0, 1, 0, 0, 0, 1, 1, 1,
0, 0, 0, 0, 0, 0, 1, 0, 1, 1, 0, 1, 1, 0, 0, 1, 1, 1, 0, 0, 0,
1}, {1, 0, 0, 0, 0, 1, 1, 0, 0, 0, 0, 0, 1, 1, 0, 0, 1, 0, 1, 0, 1,
1, 0, 0, 1, 0, 0, 0, 0, 1, 0, 0, 0, 1, 0, 1, 0, 0, 0, 0, 1, 0, 0, 0,
0, 1, 0, 1, 0, 1, 1, 1, 1, 1, 0, 0, 0, 0, 0, 0, 0, 0, 0, 1, 0, 0,
1, 1, 0, 0, 1, 0, 1, 0, 0, 1, 0, 0, 0, 0, 0, 0, 0, 0, 1, 0, 1, 0, 1,
0, 0, 1, 0, 0, 0, 0, 1, 0, 1, 1}, {0, 0, 1, 0, 1, 1, 1, 0, 0, 1, 1,
0, 1, 0, 0, 0, 0, 0, 1, 0, 0, 1, 0, 1, 1, 0, 1, 1, 1, 0, 0, 0, 0,
0, 1, 0, 1, 1, 0, 1, 0, 1, 0, 0, 0, 0, 0, 1, 0, 1, 1, 0, 0, 1, 1, 0,
0, 0, 1, 0, 1, 0, 0, 0, 0, 1, 0, 0, 0, 0, 1, 1, 0, 0, 1, 0, 1, 0,
1, 0, 0, 0, 1, 1, 0, 0, 1, 0, 0, 0, 0, 1, 1, 1, 0, 0, 1, 0, 0,
1}, {1, 0, 0, 0, 1, 0, 1, 1, 0, 1, 1, 0, 0, 0, 0, 0, 0, 0, 0, 0, 1,
1, 0, 1, 1, 0, 0, 0, 0, 1, 1, 1, 0, 0, 0, 0, 0, 1, 0, 1, 0, 1, 1, 0,
0, 0, 1, 1, 1, 0, 0, 1, 0, 0, 0, 0, 1, 0, 0, 0, 1, 0, 0, 1, 0, 1,
0, 0, 1, 0, 0, 0, 0, 0, 1, 1, 1, 1, 1, 0, 0, 1, 0, 0, 0, 0, 0, 1, 0,
1, 1, 0, 1, 1, 0, 0, 0, 1, 0, 0}, {0, 1, 0, 1, 0, 1, 1, 1, 0, 1, 0,
1, 0, 0, 1, 1, 1, 0, 1, 0, 1, 0, 1, 1, 0, 0, 0, 0, 0, 0, 0, 0, 1,
0, 0, 1, 0, 0, 1, 0, 0, 1, 0, 1, 0, 0, 1, 0, 0, 1, 1, 0, 1, 0, 0, 0,
0, 1, 1, 0, 0, 0, 0, 1, 1, 0, 1, 1, 1, 1, 1, 0, 1, 0, 0, 0, 1, 1,
0, 1, 1, 0, 1, 1, 0, 0, 1, 0, 1, 0, 0, 0, 0, 0, 0, 1, 0, 0, 0,
1}, {0, 0, 0, 0, 0, 0, 0, 0, 0, 0, 0, 1, 0, 1, 1, 1, 1, 1, 1, 1, 0,
1, 1, 1, 0, 0, 1, 1, 1, 0, 1, 1, 0, 0, 1, 0, 0, 0, 1, 0, 1, 0, 0, 1,
1, 1, 1, 1, 0, 0, 0, 0, 0, 0, 0, 0, 0, 0, 1, 0, 0, 0, 0, 0, 1, 0,
0, 1, 1, 0, 0, 1, 0, 0, 1, 0, 1, 0, 0, 0, 0, 0, 1, 0, 1, 0, 1, 1, 1,
0, 1, 1, 0, 0, 0, 0, 0, 0, 1, 0}, {1, 0, 0, 0, 0, 1, 1, 1, 0, 0, 1,
0, 0, 1, 0, 1, 0, 0, 0, 1, 1, 1, 0, 0, 1, 1, 1, 1, 1, 0, 1, 0, 1,
0, 0, 0, 0, 0, 1, 1, 0, 1, 1, 1, 0, 0, 1, 0, 1, 1, 1, 0, 0, 0, 1, 0,
0, 0, 0, 1, 1, 1, 0, 0, 0, 1, 1, 1, 1, 1, 0, 0, 0, 1, 1, 1, 0, 0,
0, 0, 1, 1, 1, 0, 0, 0, 0, 1, 0, 0, 1, 1, 0, 0, 1, 1, 0, 0, 1,
0}, {0, 1, 0, 0, 1, 0, 1, 1, 0, 0, 1, 0, 0, 1, 0, 0, 0, 1, 1, 0, 1,
0, 0, 0, 0, 0, 1, 0, 0, 0, 1, 0, 1, 1, 0, 0, 0, 0, 0, 1, 0, 1, 0, 0,
0, 1, 0, 1, 1, 0, 0, 0, 0, 1, 1, 1, 0, 0, 1, 1, 0, 1, 1, 1, 0, 1,
0, 0, 0, 0, 0, 0, 1, 1, 1, 1, 1, 1, 0, 0, 0, 1, 0, 1, 0, 0, 1, 0, 0,
0, 1, 1, 0, 1, 0, 0, 0, 0, 0, 1}, {0, 0, 1, 0, 1, 1, 0, 1, 0, 1, 1,
1, 0, 0, 1, 1, 1, 1, 1, 0, 0, 1, 0, 1, 1, 1, 1, 1, 1, 0, 0, 0, 0,
0, 1, 1, 1, 0, 0, 1, 0, 0, 0, 0, 0, 0, 1, 0, 0, 1, 1, 1, 1, 0, 0, 1,
1, 0, 0, 1, 1, 0, 1, 0, 0, 1, 0, 0, 1, 1, 1, 1, 1, 0, 0, 1, 0, 0,
0, 0, 1, 1, 0, 0, 0, 1, 0, 0, 0, 1, 1, 1, 0, 1, 0, 1, 0, 0, 0,
1}, {0, 0, 1, 0, 0, 1, 0, 0, 0, 1, 0, 1, 1, 0, 0, 0, 0, 0, 1, 1, 1,
1, 0, 1, 1, 1, 1, 1, 0, 0, 0, 0, 1, 1, 0, 0, 1, 1, 1, 0, 1, 1, 1, 0,
1, 1, 1, 0, 0, 1, 1, 0, 1, 1, 1, 1, 1, 0, 0, 0, 1, 0, 0, 0, 0, 1,
0, 0, 1, 0, 1, 1, 0, 1, 1, 0, 1, 1, 1, 0, 1, 1, 0, 1, 1, 0, 1, 0, 0,
1, 0, 0, 1, 1, 0, 0, 1, 0, 0, 0}, {1, 0, 0, 0, 1, 0, 0, 1, 0, 0, 0,
0, 1, 0, 1, 1, 0, 0, 0, 0, 1, 0, 0, 1, 1, 0, 1, 1, 1, 1, 1, 1, 0,
0, 0, 1, 0, 0, 0, 1, 0, 1, 0, 0, 0, 1, 1, 1, 0, 1, 0, 1, 0, 0, 1, 0,
1, 0, 0, 0, 0, 1, 0, 0, 1, 0, 1, 0, 0, 0, 0, 0, 1, 1, 1, 0, 1, 0,
1, 1, 1, 0, 0, 1, 0, 0, 0, 1, 1, 0, 0, 0, 1, 0, 1, 0, 0, 0, 0,
0}, {1, 1, 0, 0, 1, 0, 1, 0, 0, 0, 1, 1, 1, 0, 1, 0, 1, 0, 0, 0, 0,
0, 0, 0, 0, 1, 0, 1, 1, 0, 0, 0, 1, 1, 1, 0, 1, 1, 0, 1, 1, 0, 1, 0,
1, 1, 0, 1, 0, 0, 1, 0, 0, 1, 0, 0, 0, 1, 0, 0, 1, 1, 1, 0, 0, 1,
0, 1, 1, 1, 1, 0, 0, 1, 0, 1, 0, 1, 0, 1, 0, 0, 0, 1, 1, 0, 1, 1, 0,
0, 1, 0, 1, 0, 1, 1, 1, 1, 1, 0}, {0, 1, 0, 0, 0, 0, 1, 1, 0, 1, 0,
0, 1, 1, 0, 0, 0, 1, 0, 0, 0, 0, 0, 0, 1, 0, 0, 1, 1, 0, 1, 0, 0,
1, 0, 0, 1, 0, 0, 1, 0, 1, 0, 0, 0, 1, 0, 0, 0, 0, 0, 0, 1, 1, 1, 0,
0, 0, 1, 1, 0, 0, 0, 0, 0, 1, 1, 0, 0, 0, 0, 1, 0, 1, 0, 0, 1, 0,
0, 0, 1, 1, 1, 0, 0, 1, 0, 0, 0, 0, 0, 1, 0, 0, 0, 0, 1, 0, 1,
0}, {0, 0, 1, 0, 0, 0, 1, 0, 0, 0, 0, 1, 1, 1, 0, 1, 1, 0, 0, 1, 0,
1, 0, 0, 0, 1, 0, 1, 1, 0, 1, 0, 0, 0, 1, 1, 1, 0, 0, 0, 0, 0, 0, 0,
1, 0, 0, 0, 0, 0, 0, 0, 1, 1, 0, 0, 0, 1, 0, 0, 0, 1, 0, 1, 0, 1,
0, 1, 1, 1, 0, 1, 1, 1, 1, 0, 0, 1, 0, 0, 0, 1, 1, 1, 0, 0, 0, 0, 1,
0, 1, 1, 1, 1, 0, 0, 0, 0, 0, 0}, {0, 0, 1, 0, 0, 1, 0, 0, 0, 1, 0,
1, 0, 0, 0, 0, 0, 1, 0, 1, 0, 0, 0, 0, 0, 1, 1, 0, 0, 1, 0, 0, 0,
0, 0, 1, 0, 0, 0, 1, 0, 1, 0, 1, 0, 1, 0, 0, 1, 1, 1, 0, 0, 1, 0, 0,
1, 0, 0, 0, 0, 0, 0, 1, 0, 0, 0, 0, 0, 1, 0, 1, 1, 0, 0, 0, 0, 0,
0, 1, 0, 1, 1, 0, 1, 0, 0, 0, 1, 0, 1, 0, 0, 0, 1, 0, 1, 1, 1,
0}, {1, 0, 0, 1, 0, 1, 0, 1, 0, 0, 0, 0, 1, 0, 0, 1, 1, 0, 1, 1, 0,
0, 0, 1, 1, 0, 1, 0, 1, 1, 1, 1, 0, 0, 0, 1, 0, 1, 0, 1, 1, 1, 1, 0,
1, 0, 0, 0, 0, 1, 1, 1, 1, 0, 0, 0, 0, 0, 0, 1, 0, 0, 1, 1, 1, 0,
0, 1, 1, 1, 0, 0, 0, 1, 1, 1, 0, 1, 1, 1, 1, 0, 0, 1, 1, 0, 1, 0, 1,
1, 0, 0, 1, 1, 0, 0, 0, 0, 1, 1}, {0, 0, 0, 0, 0, 0, 0, 0, 0, 1, 1,
1, 1, 1, 0, 0, 0, 1, 0, 0, 0, 0, 1, 0, 0, 0, 1, 0, 0, 1, 1, 0, 0,
1, 1, 1, 1, 0, 1, 1, 1, 0, 0, 0, 0, 0, 0, 0, 1, 0, 0, 1, 1, 1, 0, 1,
0, 0, 1, 0, 0, 1, 0, 1, 1, 1, 1, 0, 1, 0, 0, 0, 1, 1, 0, 1, 0, 0,
0, 0, 1, 1, 1, 1, 0, 1, 1, 0, 0, 1, 1, 1, 1, 1, 1, 0, 1, 0, 0,
0}, {1, 0, 0, 1, 1, 1, 0, 1, 0, 0, 0, 1, 0, 0, 0, 1, 0, 1, 0, 1, 1,
0, 0, 1, 1, 1, 0, 1, 1, 0, 1, 1, 1, 1, 0, 1, 0, 1, 0, 0, 1, 1, 0, 0,
0, 0, 0, 0, 1, 0, 0, 1, 1, 0, 0, 1, 0, 0, 0, 1, 1, 0, 0, 1, 1, 1,
1, 1, 0, 0, 0, 0, 1, 1, 1, 1, 0, 1, 0, 1, 0, 1, 0, 0, 0, 1, 1, 1, 0,
0, 0, 1, 1, 0, 1, 0, 1, 0, 0, 1}, {1, 1, 1, 0, 1, 0, 0, 0, 1, 1, 1,
0, 1, 0, 1, 1, 1, 0, 1, 0, 1, 1, 0, 1, 1, 1, 1, 1, 1, 1, 0, 0, 0,
1, 0, 0, 1, 1, 0, 0, 0, 0, 0, 0, 1, 0, 1, 1, 0, 0, 1, 1, 1, 0, 0, 0,
0, 0, 1, 0, 1, 0, 0, 0, 0, 0, 0, 0, 0, 1, 1, 1, 0, 1, 0, 0, 0, 0,
0, 1, 0, 0, 0, 1, 0, 0, 0, 1, 1, 0, 1, 1, 1, 0, 1, 1, 0, 1, 0,
1}, {1, 1, 0, 1, 1, 0, 0, 0, 0, 1, 1, 1, 0, 0, 0, 0, 0, 0, 0, 1, 0,
0, 0, 0, 0, 0, 1, 0, 0, 1, 1, 1, 1, 0, 1, 0, 1, 0, 1, 1, 1, 0, 0, 0,
1, 1, 0, 0, 0, 0, 1, 1, 0, 1, 1, 1, 0, 0, 1, 0, 1, 0, 0, 1, 0, 0,
0, 1, 1, 0, 1, 0, 0, 0, 0, 1, 0, 1, 1, 0, 1, 1, 1, 1, 0, 0, 0, 0, 0,
0, 1, 1, 1, 0, 1, 0, 1, 1, 0, 1}, {0, 1, 0, 0, 0, 0, 0, 0, 1, 1, 0,
0, 0, 1, 1, 0, 0, 0, 1, 1, 0, 0, 0, 0, 0, 0, 0, 0, 0, 0, 0, 1, 1,
0, 1, 0, 1, 0, 1, 1, 0, 1, 0, 0, 1, 1, 0, 0, 1, 1, 0, 0, 0, 0, 0, 0,
1, 0, 1, 1, 0, 0, 0, 0, 0, 0, 0, 1, 0, 0, 1, 1, 1, 1, 0, 1, 1, 1,
1, 0, 1, 0, 0, 0, 1, 0, 0, 0, 1, 0, 1, 1, 0, 0, 0, 1, 0, 1, 1,
0}, {0, 0, 1, 1, 0, 1, 0, 0, 0, 0, 1, 1, 0, 1, 0, 1, 1, 0, 1, 0, 1,
0, 0, 0, 0, 0, 0, 0, 1, 0, 0, 1, 0, 1, 0, 0, 0, 0, 1, 0, 1, 0, 0, 0,
0, 1, 1, 1, 1, 1, 0, 0, 0, 1, 1, 1, 1, 1, 0, 0, 0, 1, 0, 1, 0, 0,
1, 1, 0, 1, 1, 1, 0, 0, 0, 1, 0, 0, 1, 1, 0, 0, 1, 1, 1, 1, 1, 0, 1,
0, 0, 0, 1, 0, 0, 0, 0, 0, 1, 0}, {0, 1, 1, 0, 1, 0, 0, 1, 0, 0, 1,
1, 0, 0, 0, 0, 0, 1, 0, 1, 0, 1, 0, 0, 1, 0, 1, 0, 0, 0, 1, 1, 0,
0, 1, 0, 0, 0, 1, 1, 0, 0, 1, 1, 0, 1, 1, 1, 1, 0, 0, 0, 0, 0, 0, 0,
0, 0, 0, 0, 1, 0, 0, 1, 0, 0, 1, 1, 1, 1, 0, 1, 0, 0, 0, 1, 0, 1,
0, 1, 0, 0, 1, 0, 1, 1, 0, 0, 0, 0, 0, 1, 0, 1, 0, 0, 0, 1, 1,
1}, {1, 0, 0, 0, 0, 1, 0, 0, 0, 1, 1, 1, 1, 1, 0, 0, 0, 1, 1, 0, 1,
0, 0, 0, 0, 0, 0, 0, 1, 0, 0, 1, 1, 0, 0, 0, 0, 1, 0, 1, 0, 1, 1, 1,
1, 0, 1, 0, 0, 1, 0, 1, 0, 0, 0, 1, 1, 1, 0, 0, 1, 0, 0, 0, 0, 0,
1, 1, 1, 1, 0, 1, 0, 0, 0, 0, 1, 1, 0, 0, 1, 1, 0, 0, 0, 0, 1, 0, 0,
0, 0, 0, 1, 1, 0, 0, 1, 1, 1, 1}, {0, 1, 0, 0, 0, 0, 0, 1, 0, 0, 0,
1, 0, 1, 1, 1, 0, 0, 1, 0, 0, 0, 1, 1, 0, 0, 0, 1, 0, 1, 0, 0, 1,
0, 0, 0, 1, 1, 0, 1, 1, 0, 1, 0, 0, 0, 0, 0, 0, 1, 0, 1, 0, 0, 0, 0,
1, 1, 1, 1, 0, 1, 1, 1, 1, 0, 1, 0, 1, 1, 0, 1, 0, 0, 0, 1, 0, 1,
1, 1, 0, 1, 0, 1, 0, 1, 0, 0, 0, 0, 0, 1, 1, 1, 0, 0, 1, 0, 1,
0}, {0, 1, 0, 0, 0, 1, 1, 0, 1, 1, 0, 1, 1, 0, 0, 1, 0, 0, 1, 0, 0,
1, 0, 0, 1, 0, 1, 0, 1, 0, 1, 0, 0, 0, 0, 0, 0, 1, 1, 1, 0, 0, 0, 0,
0, 0, 1, 1, 0, 1, 0, 1, 0, 1, 0, 0, 0, 1, 1, 0, 0, 0, 0, 0, 1, 0,
0, 0, 1, 1, 1, 0, 0, 1, 0, 1, 0, 1, 1, 1, 1, 0, 1, 0, 0, 1, 0, 0, 1,
1, 0, 0, 0, 0, 0, 1, 1, 0, 1, 0}, {0, 0, 0, 0, 1, 0, 0, 1, 0, 1, 0,
0, 0, 0, 0, 0, 0, 1, 1, 0, 0, 0, 1, 0, 0, 0, 0, 1, 0, 1, 0, 0, 0,
1, 0, 0, 0, 0, 1, 1, 1, 0, 0, 0, 1, 0, 0, 0, 0, 0, 1, 1, 0, 1, 1, 0,
0, 0, 0, 0, 0, 0, 1, 1, 1, 0, 0, 0, 1, 1, 0, 0, 1, 0, 0, 0, 1, 0,
1, 0, 0, 0, 0, 1, 0, 0, 1, 0, 1, 0, 1, 0, 0, 1, 1, 0, 0, 1, 1,
0}, {1, 0, 0, 1, 1, 1, 1, 0, 1, 0, 0, 0, 0, 0, 1, 0, 0, 0, 0, 0, 1,
0, 0, 0, 0, 1, 1, 0, 0, 0, 0, 0, 0, 0, 1, 0, 0, 0, 0, 0, 0, 1, 0, 1,
0, 0, 0, 0, 0, 0, 0, 1, 0, 1, 1, 1, 0, 0, 0, 0, 0, 0, 0, 1, 1, 1,
0, 0, 0, 0, 1, 1, 0, 0, 1, 0, 1, 1, 0, 0, 1, 1, 1, 1, 0, 1, 1, 0, 0,
1, 1, 0, 1, 1, 0, 0, 0, 1, 0, 0}, {0, 0, 0, 0, 0, 0, 0, 0, 1, 0, 1,
1, 1, 1, 0, 0, 0, 0, 1, 1, 1, 0, 1, 0, 1, 0, 1, 0, 1, 1, 0, 0, 1,
0, 1, 1, 0, 1, 0, 0, 0, 0, 1, 0, 0, 0, 1, 0, 1, 1, 1, 0, 0, 0, 1, 1,
0, 0, 0, 1, 1, 0, 0, 1, 0, 1, 0, 0, 0, 0, 0, 0, 1, 1, 1, 1, 0, 0,
0, 1, 1, 0, 1, 1, 1, 0, 1, 0, 0, 0, 1, 0, 0, 0, 1, 1, 1, 0, 0,
1 }, {1, 1, 1, 1, 0, 0, 0, 0, 0, 1, 0, 1, 0, 0, 1, 0, 0, 0, 1, 1, 0,
1, 1, 1, 0, 0, 1, 0, 1, 0, 1, 0, 0, 0, 0, 0, 1, 1, 1, 0, 0, 0, 1, 0,
0, 1, 0, 1, 0, 0, 1, 0, 0, 0, 1, 0, 0, 0, 1, 0, 1, 0, 1, 0, 1, 0,
0, 0, 0, 0, 1, 0, 0, 1, 0, 1, 0, 1, 1, 0, 0, 1, 0, 0, 0, 0, 0, 1, 1,
1, 0, 1, 0, 0, 0, 0, 0, 0, 1, 0}, {1, 1, 0, 1, 1, 0, 1, 0, 0, 0, 1,
1, 1, 1, 1, 0, 1, 0, 0, 1, 0, 1, 0, 0, 0, 1, 0, 0, 1, 0, 1, 0, 1,
1, 0, 0, 1, 0, 1, 1, 0, 1, 0, 0, 0, 0, 0, 1, 1, 1, 0, 0, 1, 1, 0, 0,
0, 0, 1, 1, 0, 0, 0, 0, 0, 0, 0, 0, 1, 1, 1, 1, 0, 0, 0, 1, 0, 0,
0, 1, 1, 1, 1, 0, 0, 1, 0, 0, 0, 1, 0, 1, 0, 0, 0, 0, 1, 0, 0,
0}, {1, 0, 1, 0, 0, 1, 0, 0, 0, 0, 0, 0, 0, 1, 1, 1, 0, 0, 0, 0, 0,
1, 1, 1, 0, 0, 0, 1, 0, 1, 0, 0, 0, 0, 0, 0, 1, 1, 0, 0, 1, 1, 0, 1,
0, 0, 1, 0, 0, 0, 0, 1, 0, 0, 1, 0, 0, 0, 0, 0, 0, 0, 0, 0, 0, 0,
1, 0, 0, 0, 0, 0, 0, 1, 0, 1, 1, 0, 1, 1, 0, 0, 0, 0, 1, 0, 0, 0, 0,
1, 0, 1, 0, 0, 1, 0, 0, 1, 0, 1}, {0, 1, 1, 0, 1, 1, 0, 0, 0, 1, 0,
0, 1, 1, 0, 0, 0, 1, 0, 0, 0, 1, 0, 0, 1, 1, 0, 0, 0, 0, 1, 0, 0,
0, 0, 0, 0, 1, 1, 0, 0, 1, 0, 0, 0, 1, 0, 0, 0, 0, 0, 0, 0, 0, 1, 0,
1, 0, 0, 1, 0, 0, 0, 0, 1, 0, 0, 0, 0, 1, 0, 1, 0, 0, 0, 0, 1, 1,
0, 0, 1, 0, 0, 1, 0, 1, 1, 0, 0, 1, 1, 0, 1, 0, 1, 0, 1, 0, 1,
0}, {1, 0, 1, 0, 1, 0, 0, 1, 1, 1, 0, 0, 0, 0, 1, 1, 1, 0, 0, 1, 0,
1, 0, 0, 0, 0, 0, 1, 0, 0, 0, 1, 0, 1, 1, 0, 0, 1, 0, 0, 0, 0, 0, 1,
1, 1, 1, 1, 0, 1, 0, 1, 1, 0, 1, 0, 1, 1, 1, 0, 0, 0, 0, 0, 0, 0,
0, 0, 0, 0, 0, 0, 0, 1, 0, 1, 0, 0, 0, 0, 1, 1, 0, 0, 0, 1, 0, 0, 0,
0, 0, 0, 0, 0, 0, 1, 0, 0, 0, 1}, {0, 1, 0, 1, 0, 0, 0, 0, 0, 1, 1,
0, 0, 0, 0, 1, 0, 1, 1, 0, 1, 0, 1, 0, 0, 1, 1, 0, 0, 0, 1, 0, 0,
0, 1, 1, 0, 0, 0, 0, 1, 0, 0, 0, 0, 1, 1, 1, 0, 0, 0, 0, 0, 0, 1, 1,
1, 1, 0, 1, 0, 0, 1, 0, 0, 1, 0, 0, 1, 0, 0, 1, 0, 0, 0, 1, 0, 0,
0, 1, 0, 0, 0, 1, 0, 0, 1, 1, 1, 1, 0, 1, 0, 1, 0, 0, 1, 1, 1,
0}, {0, 1, 0, 1, 0, 1, 0, 0, 0, 0, 0, 0, 0, 0, 0, 0, 0, 0, 0, 0, 0,
0, 1, 1, 1, 0, 0, 0, 1, 0, 0, 0, 1, 1, 0, 0, 1, 1, 1, 1, 0, 1, 1, 1,
0, 0, 1, 1, 0, 0, 0, 0, 0, 0, 0, 0, 0, 1, 1, 0, 0, 0, 0, 0, 1, 0,
1, 0, 1, 0, 0, 0, 1, 1, 0, 1, 0, 0, 1, 0, 0, 1, 0, 1, 0, 0, 1, 1, 0,
0, 1, 0, 1, 0, 0, 1, 1, 1, 0, 0}, {1, 1, 0, 1, 1, 0, 0, 0, 0, 0, 0,
0, 0, 0, 1, 0, 1, 0, 1, 1, 0, 0, 1, 0, 1, 1, 0, 0, 0, 1, 0, 1, 0,
0, 1, 0, 1, 0, 0, 0, 1, 0, 1, 0, 0, 0, 1, 1, 0, 0, 0, 1, 1, 1, 1, 0,
0, 0, 0, 0, 0, 1, 0, 0, 0, 1, 0, 0, 0, 0, 0, 0, 1, 0, 1, 0, 1, 1,
0, 1, 1, 0, 0, 0, 0, 0, 0, 1, 0, 1, 0, 1, 0, 0, 1, 1, 0, 0, 0,
0}, {0, 0, 1, 0, 1, 0, 1, 0, 1, 0, 0, 0, 0, 0, 1, 0, 0, 1, 0, 0, 1,
0, 1, 0, 1, 0, 1, 0, 1, 0, 0, 1, 0, 0, 1, 1, 1, 0, 0, 0, 0, 1, 0, 1,
0, 1, 0, 1, 0, 1, 1, 1, 1, 1, 0, 0, 0, 0, 0, 0, 0, 0, 0, 0, 0, 0,
0, 0, 0, 0, 1, 0, 0, 0, 0, 0, 0, 0, 0, 1, 1, 0, 0, 0, 0, 0, 0, 0, 0,
0, 0, 1, 0, 0, 1, 0, 1, 0, 1, 1}, {1, 1, 0, 0, 0, 0, 0, 0, 0, 0, 0,
0, 1, 0, 1, 0, 1, 0, 1, 0, 0, 0, 0, 0, 0, 0, 0, 0, 0, 0, 1, 0, 0,
1, 1, 1, 1, 0, 1, 1, 0, 1, 0, 1, 0, 1, 1, 0, 0, 1, 0, 0, 1, 1, 1, 1,
1, 0, 0, 0, 1, 0, 0, 0, 1, 1, 0, 0, 0, 0, 1, 1, 1, 0, 0, 1, 0, 0,
1, 0, 0, 0, 1, 1, 0, 0, 0, 0, 0, 0, 0, 1, 1, 0, 0, 1, 0, 1, 0,
0}, {0, 1, 1, 1, 1, 0, 0, 0, 1, 1, 1, 0, 1, 0, 0, 1, 0, 1, 1, 0, 0,
0, 0, 0, 1, 1, 1, 0, 0, 1, 0, 0, 0, 0, 1, 0, 1, 0, 1, 0, 0, 1, 0, 1,
1, 1, 0, 0, 1, 0, 0, 1, 1, 1, 1, 1, 1, 0, 0, 0, 1, 0, 1, 0, 0, 0,
0, 0, 0, 0, 1, 0, 1, 0, 1, 1, 0, 0, 0, 1, 0, 0, 0, 1, 1, 1, 1, 1, 1,
0, 1, 1, 0, 1, 1, 0, 1, 0, 0, 0}, {1, 0, 1, 0, 1, 0, 0, 1, 0, 1, 1,
0, 1, 0, 0, 0, 0, 0, 1, 0, 0, 0, 0, 1, 0, 1, 1, 1, 1, 0, 0, 1, 1,
0, 1, 0, 0, 0, 1, 1, 0, 1, 0, 0, 0, 0, 0, 0, 1, 1, 1, 1, 0, 0, 0, 1,
0, 1, 0, 1, 1, 0, 0, 0, 0, 0, 0, 1, 1, 1, 0, 1, 0, 0, 0, 1, 1, 0,
1, 1, 0, 0, 0, 0, 0, 0, 1, 0, 0, 1, 0, 0, 1, 1, 1, 0, 0, 0, 0,
1}, {1, 1, 0, 1, 0, 1, 1, 1, 1, 0, 1, 1, 0, 0, 0, 0, 0, 0, 0, 0, 0,
0, 0, 0, 0, 0, 1, 0, 1, 0, 1, 0, 1, 0, 0, 1, 0, 0, 1, 1, 0, 0, 1, 1,
1, 0, 0, 0, 1, 0, 1, 1, 1, 1, 1, 0, 0, 1, 0, 0, 1, 0, 1, 0, 1, 0,
0, 0, 1, 0, 1, 0, 0, 1, 1, 1, 0, 0, 1, 0, 1, 0, 0, 0, 0, 0, 0, 0, 0,
1, 0, 0, 1, 1, 1, 0, 1, 1, 0, 0}, {0, 1, 1, 0, 1, 0, 1, 1, 0, 1, 0,
1, 0, 0, 0, 1, 1, 0, 0, 0, 1, 1, 1, 1, 1, 0, 0, 0, 0, 0, 0, 1, 0,
0, 1, 0, 0, 1, 1, 0, 1, 0, 0, 1, 1, 0, 1, 1, 0, 0, 1, 0, 0, 0, 0, 0,
1, 0, 1, 0, 0, 0, 0, 0, 0, 1, 1, 0, 1, 1, 0, 0, 0, 1, 0, 1, 1, 1,
1, 0, 0, 0, 0, 0, 0, 1, 1, 0, 0, 0, 1, 0, 0, 1, 0, 1, 0, 0, 0,
1}, {1, 0, 1, 1, 0, 0, 1, 1, 1, 1, 1, 0, 0, 0, 0, 0, 1, 0, 1, 0, 0,
0, 1, 0, 1, 0, 0, 1, 1, 1, 0, 0, 0, 0, 0, 0, 1, 1, 0, 1, 1, 1, 1, 1,
0, 1, 1, 1, 1, 0, 1, 0, 0, 0, 0, 1, 0, 0, 1, 1, 0, 1, 0, 1, 0, 1,
0, 0, 0, 0, 0, 1, 1, 0, 0, 0, 0, 1, 1, 0, 0, 0, 0, 1, 1, 0, 0, 0, 1,
1, 1, 0, 1, 1, 0, 0, 0, 0, 0, 0}, {1, 1, 0, 1, 0, 0, 1, 0, 0, 1, 1,
1, 1, 0, 1, 0, 1, 0, 0, 0, 1, 0, 0, 0, 0, 0, 0, 0, 0, 1, 0, 0, 1,
1, 0, 1, 1, 1, 0, 1, 1, 0, 0, 1, 0, 1, 0, 1, 0, 0, 0, 0, 0, 0, 0, 0,
0, 1, 1, 0, 0, 0, 0, 0, 0, 0, 1, 0, 0, 1, 0, 1, 0, 0, 0, 0, 0, 1,
0, 1, 0, 0, 0, 0, 0, 1, 0, 1, 0, 1, 1, 0, 0, 0, 0, 0, 0, 1, 1,
1}, {1, 0, 0, 0, 0, 0, 0, 1, 0, 0, 0, 1, 1, 1, 0, 1, 0, 0, 1, 1, 0,
1, 0, 0, 0, 0, 1, 0, 1, 0, 1, 1, 0, 1, 0, 0, 1, 1, 1, 0, 0, 1, 0, 0,
0, 1, 1, 1, 0, 1, 1, 1, 1, 0, 1, 1, 0, 0, 1, 1, 1, 1, 0, 1, 1, 1,
0, 0, 1, 1, 1, 1, 1, 0, 0, 0, 0, 1, 0, 0, 0, 0, 0, 0, 0, 1, 0, 0, 0,
1, 1, 1, 0, 1, 1, 0, 0, 0, 0, 0}, {0, 0, 0, 1, 1, 1, 1, 0, 0, 0, 1,
1, 0, 0, 0, 0, 0, 1, 0, 0, 0, 0, 0, 1, 0, 0, 0, 1, 0, 1, 1, 0, 1,
1, 1, 1, 0, 1, 0, 1, 1, 0, 1, 0, 0, 0, 0, 0, 0, 0, 1, 0, 0, 1, 0, 0,
1, 1, 0, 0, 0, 1, 1, 0, 0, 0, 1, 0, 0, 0, 1, 0, 1, 0, 0, 0, 0, 1,
0, 1, 0, 0, 1, 0, 0, 1, 0, 1, 0, 1, 1, 0, 0, 0, 1, 0, 0, 1, 0,
1}, {0, 1, 1, 0, 0, 0, 0, 0, 1, 0, 0, 0, 1, 0, 1, 1, 0, 0, 1, 0, 1,
0, 1, 0, 0, 0, 0, 1, 1, 1, 1, 0, 0, 1, 1, 0, 0, 1, 0, 1, 0, 1, 0, 1,
0, 1, 0, 1, 0, 1, 1, 0, 1, 1, 1, 1, 0, 1, 0, 1, 0, 0, 1, 0, 0, 0,
1, 0, 0, 0, 0, 0, 1, 1, 1, 1, 1, 0, 0, 0, 0, 1, 0, 1, 0, 0, 1, 0, 1,
1, 0, 0, 1, 1, 0, 1, 1, 0, 1, 0}, {0, 0, 0, 1, 0, 0, 0, 1, 0, 0, 0,
1, 0, 1, 0, 0, 0, 1, 0, 0, 1, 0, 1, 0, 0, 1, 1, 0, 0, 0, 0, 0, 1,
1, 0, 0, 0, 0, 0, 1, 1, 0, 0, 0, 0, 1, 0, 0, 0, 1, 1, 1, 0, 0, 1, 1,
1, 0, 0, 1, 0, 1, 0, 0, 0, 1, 0, 0, 1, 0, 1, 1, 1, 1, 0, 0, 0, 0,
0, 0, 0, 0, 0, 0, 1, 0, 1, 0, 0, 0, 0, 1, 0, 1, 1, 1, 0, 0, 1,
0}, {0, 0, 0, 0, 1, 0, 0, 0, 0, 1, 1, 0, 1, 0, 0, 1, 1, 0, 0, 0, 1,
0, 0, 1, 0, 1, 0, 0, 0, 1, 0, 0, 0, 0, 1, 0, 0, 0, 0, 0, 1, 1, 0, 0,
1, 1, 0, 1, 1, 0, 0, 1, 1, 0, 1, 1, 0, 0, 1, 0, 1, 1, 0, 0, 1, 0,
1, 1, 0, 1, 1, 0, 0, 0, 1, 0, 1, 0, 0, 0, 0, 0, 0, 0, 1, 0, 1, 0, 1,
0, 1, 0, 0, 1, 1, 0, 0, 1, 0, 0}, {1, 0, 0, 0, 0, 0, 0, 0, 0, 1, 1,
0, 0, 0, 1, 0, 0, 1, 0, 1, 0, 0, 0, 1, 1, 0, 1, 1, 0, 1, 0, 0, 0,
0, 1, 0, 1, 0, 1, 1, 1, 0, 1, 0, 0, 1, 1, 0, 0, 1, 1, 0, 0, 1, 0, 1,
0, 1, 1, 0, 1, 0, 1, 1, 0, 0, 1, 1, 0, 0, 0, 1, 0, 0, 0, 0, 0, 0,
0, 0, 0, 1, 0, 0, 1, 0, 1, 0, 1, 0, 0, 0, 0, 0, 1, 1, 1, 0, 0,
1}, {0, 0, 0, 1, 1, 1, 0, 0, 1, 0, 1, 1, 0, 0, 0, 0, 0, 1, 1, 0, 0,
0, 0, 0, 0, 1, 0, 0, 0, 0, 0, 0, 0, 1, 0, 0, 1, 1, 1, 1, 0, 0, 1, 1,
1, 0, 1, 1, 0, 1, 0, 0, 0, 1, 1, 0, 0, 1, 0, 1, 1, 0, 0, 1, 0, 1,
0, 0, 0, 0, 0, 0, 0, 0, 0, 0, 0, 1, 0, 0, 1, 0, 1, 1, 1, 0, 0, 0, 1,
0, 0, 0, 0, 1, 0, 0, 0, 0, 0, 0}, {0, 0, 1, 1, 1, 1, 0, 0, 0, 0, 1,
1, 0, 0, 0, 1, 0, 0, 0, 0, 0, 0, 1, 0, 0, 0, 1, 0, 0, 1, 0, 0, 1,
0, 1, 1, 1, 0, 0, 0, 0, 0, 1, 1, 1, 0, 1, 0, 0, 1, 0, 1, 1, 0, 0, 1,
0, 1, 1, 0, 1, 0, 0, 0, 0, 0, 0, 0, 1, 0, 0, 0, 0, 0, 0, 0, 1, 0,
0, 0, 0, 1, 0, 1, 0, 0, 0, 1, 0, 0, 1, 0, 1, 0, 0, 0, 0, 0, 1,
0}, {1, 1, 1, 1, 0, 1, 0, 0, 0, 0, 0, 1, 0, 0, 0, 0, 0, 1, 1, 0, 1,
0, 0, 0, 0, 1, 0, 1, 0, 0, 0, 0, 1, 0, 1, 0, 0, 1, 0, 1, 1, 1, 0, 1,
0, 1, 1, 0, 1, 1, 0, 1, 0, 0, 1, 0, 1, 1, 1, 0, 0, 0, 1, 0, 1, 1,
0, 0, 1, 1, 0, 0, 0, 1, 0, 0, 0, 1, 0, 0, 0, 1, 1, 0, 1, 1, 0, 1, 0,
1, 0, 1, 0, 1, 0, 1, 1, 0, 1, 1}, {0, 0, 1, 1, 0, 1, 0, 1, 1, 0, 0,
1, 0, 1, 0, 0, 1, 0, 1, 1, 0, 0, 0, 0, 1, 1, 1, 1, 0, 0, 1, 1, 0,
0, 0, 1, 0, 0, 0, 1, 0, 1, 0, 0, 1, 1, 0, 0, 0, 0, 1, 1, 1, 0, 0, 0,
0, 0, 1, 0, 0, 1, 0, 0, 0, 0, 0, 0, 0, 1, 0, 0, 0, 1, 0, 0, 0, 0,
1, 1, 1, 1, 0, 1, 0, 0, 1, 1, 1, 1, 0, 1, 0, 1, 1, 0, 0, 1, 1,
1}, {1, 1, 0, 0, 1, 0, 1, 0, 0, 1, 1, 0, 1, 0, 1, 0, 1, 1, 0, 0, 1,
1, 1, 1, 1, 1, 1, 1, 0, 1, 0, 0, 0, 0, 0, 0, 0, 0, 1, 0, 0, 0, 1, 0,
0, 0, 1, 1, 0, 0, 0, 1, 1, 0, 1, 1, 0, 1, 0, 0, 1, 0, 1, 1, 0, 0,
0, 0, 0, 1, 0, 0, 1, 0, 1, 1, 1, 0, 0, 0, 0, 0, 0, 1, 0, 0, 0, 1, 0,
1, 0, 1, 1, 1, 0, 0, 1, 1, 0, 0}, {1, 0, 1, 0, 1, 0, 0, 0, 0, 0, 1,
1, 1, 1, 1, 0, 0, 1, 0, 0, 0, 0, 1, 1, 0, 1, 0, 1, 0, 0, 1, 1, 1,
0, 1, 1, 0, 1, 0, 1, 0, 1, 0, 0, 0, 1, 1, 1, 0, 0, 0, 1, 0, 1, 0, 0,
1, 1, 1, 0, 0, 0, 1, 0, 1, 1, 0, 0, 0, 1, 1, 0, 1, 0, 0, 0, 0, 1,
1, 1, 1, 0, 0, 0, 1, 0, 0, 0, 0, 0, 0, 0, 0, 0, 0, 1, 0, 0, 0,
0}, {1, 1, 0, 0, 0, 1, 0, 1, 1, 1, 1, 1, 0, 0, 0, 1, 0, 1, 0, 1, 0,
0, 0, 0, 0, 1, 0, 0, 1, 1, 1, 0, 0, 1, 0, 1, 1, 0, 0, 0, 1, 1, 0, 0,
0, 0, 0, 1, 1, 0, 0, 0, 0, 0, 0, 0, 0, 0, 0, 1, 0, 0, 0, 0, 1, 1,
1, 0, 0, 1, 0, 0, 0, 0, 1, 0, 1, 0, 0, 0, 0, 0, 1, 1, 1, 1, 0, 0, 1,
0, 0, 0, 1, 0, 1, 0, 0, 1, 1, 0}, {1, 1, 1, 0, 0, 1, 1, 1, 1, 0, 0,
0, 0, 1, 1, 0, 0, 0, 0, 0, 0, 1, 1, 1, 0, 1, 0, 0, 0, 0, 0, 1, 0,
0, 1, 1, 0, 0, 0, 0, 1, 0, 0, 1, 1, 1, 0, 0, 1, 0, 1, 1, 0, 0, 0, 1,
1, 0, 0, 1, 0, 0, 0, 0, 1, 0, 0, 0, 0, 1, 0, 0, 0, 1, 0, 0, 0, 1,
0, 1, 1, 1, 0, 0, 1, 0, 0, 1, 0, 0, 0, 1, 1, 1, 1, 0, 0, 0, 1,
0}, {0, 0, 0, 0, 1, 0, 1, 0, 1, 1, 1, 0, 0, 0, 1, 0, 0, 0, 0, 0, 0,
0, 0, 1, 1, 0, 0, 1, 1, 1, 1, 0, 0, 1, 0, 0, 0, 0, 1, 1, 0, 0, 0, 0,
0, 1, 1, 0, 0, 0, 0, 0, 0, 0, 0, 1, 0, 1, 0, 1, 1, 1, 1, 0, 1, 0,
1, 0, 0, 0, 1, 1, 0, 1, 1, 1, 1, 1, 0, 0, 0, 0, 0, 1, 1, 1, 0, 0, 0,
0, 1, 1, 0, 0, 0, 0, 0, 0, 0, 0}, {1, 0, 0, 0, 1, 0, 1, 0, 1, 0, 0,
0, 0, 1, 0, 1, 0, 0, 0, 0, 0, 0, 0, 0, 1, 0, 0, 1, 0, 0, 1, 0, 0,
1, 0, 1, 1, 1, 1, 0, 0, 1, 0, 1, 1, 0, 1, 0, 1, 1, 1, 0, 0, 0, 0, 0,
1, 1, 1, 0, 0, 0, 1, 0, 0, 1, 0, 0, 0, 1, 0, 0, 1, 1, 1, 1, 1, 0,
0, 1, 0, 0, 1, 0, 0, 0, 0, 0, 0, 1, 0, 0, 0, 0, 1, 1, 0, 0, 0,
0}, {1, 1, 0, 0, 0, 0, 1, 1, 1, 1, 0, 0, 0, 1, 0, 1, 0, 0, 0, 0, 0,
1, 0, 1, 0, 1, 0, 1, 0, 1, 0, 1, 1, 0, 0, 1, 1, 1, 1, 0, 0, 0, 1, 1,
0, 0, 1, 1, 1, 1, 1, 0, 1, 0, 1, 0, 0, 0, 0, 1, 1, 1, 0, 0, 1, 0,
1, 1, 1, 1, 0, 0, 0, 0, 0, 1, 0, 0, 1, 0, 0, 0, 0, 1, 1, 1, 0, 0, 1,
1, 0, 0, 0, 0, 0, 0, 0, 1, 1, 0}, {0, 0, 0, 0, 0, 0, 0, 0, 0, 0, 1,
1, 0, 0, 1, 1, 0, 0, 0, 1, 0, 0, 0, 1, 0, 1, 0, 1, 1, 1, 0, 0, 1,
1, 0, 0, 0, 0, 0, 1, 1, 1, 0, 1, 0, 1, 1, 1, 1, 1, 0, 1, 0, 1, 1, 0,
0, 1, 0, 0, 0, 0, 1, 0, 0, 1, 0, 0, 1, 0, 1, 1, 0, 1, 0, 0, 0, 1,
0, 0, 0, 0, 1, 0, 0, 1, 0, 1, 1, 0, 0, 0, 0, 0, 0, 0, 1, 0, 0,
1}, {0, 0, 1, 1, 1, 0, 1, 1, 1, 1, 0, 0, 1, 0, 1, 1, 0, 1, 1, 1, 0,
1, 0, 1, 0, 0, 1, 0, 0, 1, 1, 0, 1, 1, 0, 0, 0, 1, 1, 1, 0, 0, 0, 1,
0, 1, 1, 0, 0, 0, 0, 0, 1, 1, 1, 0, 1, 1, 0, 0, 0, 0, 0, 0, 1, 0,
0, 0, 0, 1, 1, 1, 1, 1, 0, 1, 0, 1, 1, 1, 0, 1, 0, 1, 1, 1, 0, 0, 1,
0, 0, 0, 0, 0, 0, 1, 0, 0, 0, 0}, {0, 1, 1, 1, 0, 0, 0, 0, 1, 0, 0,
0, 1, 1, 1, 0, 1, 1, 1, 1, 1, 0, 1, 1, 0, 1, 0, 0, 0, 0, 1, 0, 0,
0, 0, 0, 1, 0, 0, 0, 1, 1, 0, 0, 1, 0, 1, 1, 1, 1, 0, 0, 0, 0, 0, 0,
1, 0, 1, 0, 0, 1, 1, 0, 0, 0, 1, 1, 0, 1, 1, 1, 0, 0, 0, 1, 1, 0,
1, 1, 1, 0, 0, 0, 1, 0, 0, 1, 1, 0, 1, 0, 0, 0, 0, 0, 1, 1, 0,
1}, {1, 1, 0, 1, 1, 1, 0, 0, 1, 0, 0, 1, 0, 0, 1, 1, 1, 0, 0, 1, 0,
1, 0, 0, 0, 1, 1, 1, 0, 0, 1, 0, 0, 0, 1, 0, 1, 0, 1, 0, 0, 1, 0, 0,
0, 0, 0, 0, 1, 0, 1, 0, 0, 0, 0, 1, 0, 0, 1, 0, 0, 0, 0, 1, 0, 1,
1, 0, 1, 0, 0, 0, 1, 0, 0, 0, 0, 1, 1, 0, 1, 0, 0, 1, 0, 0, 1, 0, 0,
0, 1, 0, 0, 1, 0, 0, 0, 1, 0, 1}, {0, 0, 0, 0, 0, 0, 0, 0, 1, 1, 0,
0, 1, 0, 0, 0, 0, 0, 0, 0, 0, 1, 0, 1, 1, 1, 1, 1, 0, 1, 0, 1, 1,
0, 0, 0, 0, 0, 0, 1, 0, 1, 1, 0, 1, 0, 1, 1, 0, 1, 0, 0, 0, 1, 1, 1,
0, 0, 1, 0, 1, 0, 1, 0, 1, 1, 0, 1, 0, 1, 0, 1, 0, 0, 0, 0, 0, 1,
0, 0, 1, 0, 0, 1, 0, 1, 0, 0, 0, 0, 0, 0, 1, 0, 1, 0, 0, 0, 1,
0}, {1, 0, 0, 1, 1, 0, 0, 0, 1, 0, 0, 0, 1, 0, 1, 0, 1, 0, 1, 1, 0,
1, 1, 0, 1, 1, 1, 0, 1, 0, 0, 0, 0, 1, 0, 0, 0, 0, 0, 0, 0, 1, 0, 0,
1, 0, 0, 0, 1, 1, 1, 0, 1, 1, 0, 0, 1, 1, 0, 0, 0, 1, 0, 0, 1, 1,
0, 0, 1, 0, 0, 1, 0, 0, 1, 0, 1, 0, 0, 1, 0, 0, 0, 0, 1, 1, 0, 1, 0,
0, 0, 1, 0, 0, 1, 1, 0, 0, 0, 1}, {0, 0, 0, 0, 0, 0, 0, 0, 0, 0, 1,
0, 0, 0, 0, 0, 0, 0, 0, 0, 1, 0, 0, 0, 0, 0, 1, 1, 1, 1, 0, 1, 0,
0, 0, 1, 1, 0, 0, 0, 0, 1, 1, 0, 1, 1, 0, 0, 0, 0, 1, 1, 1, 1, 1, 1,
1, 0, 0, 1, 0, 0, 1, 0, 1, 0, 0, 1, 0, 0, 0, 0, 0, 0, 1, 0, 0, 1,
1, 0, 0, 0, 1, 1, 1, 0, 0, 1, 1, 0, 0, 1, 0, 0, 0, 0, 1, 0, 0,
0}, {0, 1, 0, 0, 1, 0, 0, 1, 1, 0, 1, 0, 0, 1, 0, 0, 1, 1, 0, 1, 1,
0, 1, 1, 0, 1, 0, 0, 1, 0, 1, 1, 1, 0, 1, 0, 0, 1, 1, 0, 0, 0, 0, 0,
0, 1, 0, 1, 1, 1, 0, 0, 1, 1, 0, 0, 0, 0, 1, 0, 0, 1, 0, 1, 0, 0,
0, 1, 0, 0, 1, 0, 1, 0, 1, 0, 1, 0, 0, 0, 1, 0, 0, 1, 1, 0, 0, 0, 0,
0, 0, 0, 1, 0, 1, 1, 0, 1, 0, 0} }

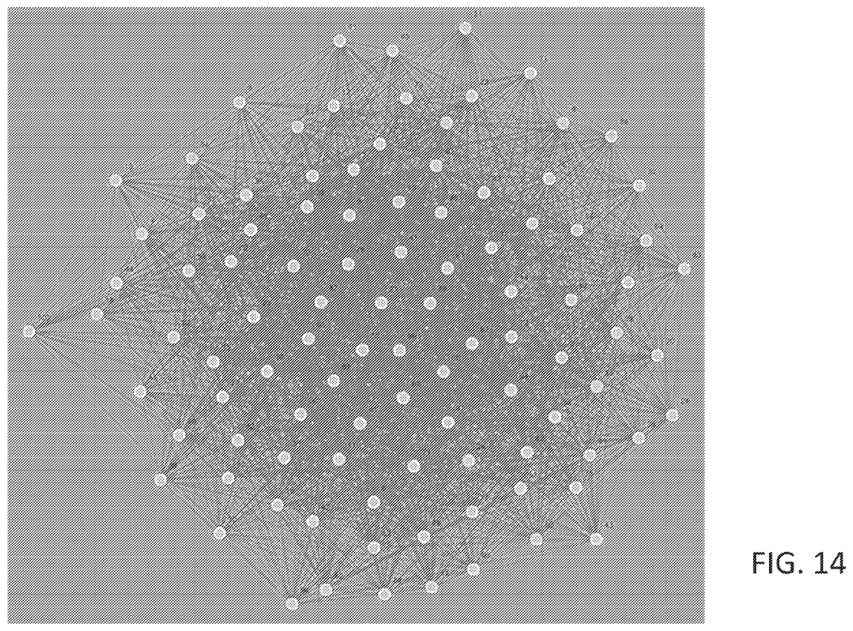

As one example of this non-limiting example, as shown in FIG. 14, a network provided based on creating a command and control broadcast network with 100 nodes and 1000 links (edges) connections. There is one HACM ONS (Octopus Neural System) at each node, with each ONS having the same number of tentacles as the number of connections that the node supports plus command and control tentacles. When a emergency action message (EAM) is sent into the network, the job of the broadcast ONS controlled nodes is to find optimal paths to distribute the message to all of the nodes and respond with their pre-programmed operations as specified by a single integrated operational plan (SIOP). The networks are completely random as shown in images.

For example, a network is provided based on creating a thermonuclear event survival command and control broadcast network with 100 nodes and 1000 links (edges) connections. There is one HACM ONS (Octopus Neural System) at each node, with each ONS having the same number of tentacles as the number of connections that the node supports plus launch control tentacles. When an emergency action message (EAM) is sent into the network, the job of the broadcast ONS controlled nuclear nodes is to find optimal paths to distribute the message to all of the nodes and retaliate with their pre-programmed major attack operations (MAO) as specified by a single integrated operational plan (SIOP). In this way the network command and control structure could survive a full thermonuclear exchange and retaliate with the remaining nodes following the attack. The networks are completely random as shown in images.

As a non-limiting example of the invention, taking a discrete logarithm can be provided according to the invention, wherein MASEC devices, computers, and/or circuits can implement any mathematical function continuous or otherwise. The process of MASEC design is waveform shaping. Waveform shaping in electronics is the modification of the shape of an electronic waveform. In this way MASEC waveforms are synthesized and designed. Waveform shaping is extensively studied in signal processing, the electrical engineering subfield that focuses on analyzing, modifying, and synthesizing signals such as sound, images, and scientific measurements, and mathematical functions. The difference with MASEC waveform shaping (MASEC design) is that once the MASEC electrical and thermodynamic properties are adjusted to conform to the desired waveform shape, it's voltage and current properties are “locked in”, and the voltage and current are mapped to mathematical functions, sound, images, and scientific measurements desired. The resulting MASEC devices, computers, and/or circuits, (and their pluralities working together), are a direct replacement for computational process currently implemented by discrete computational methods.

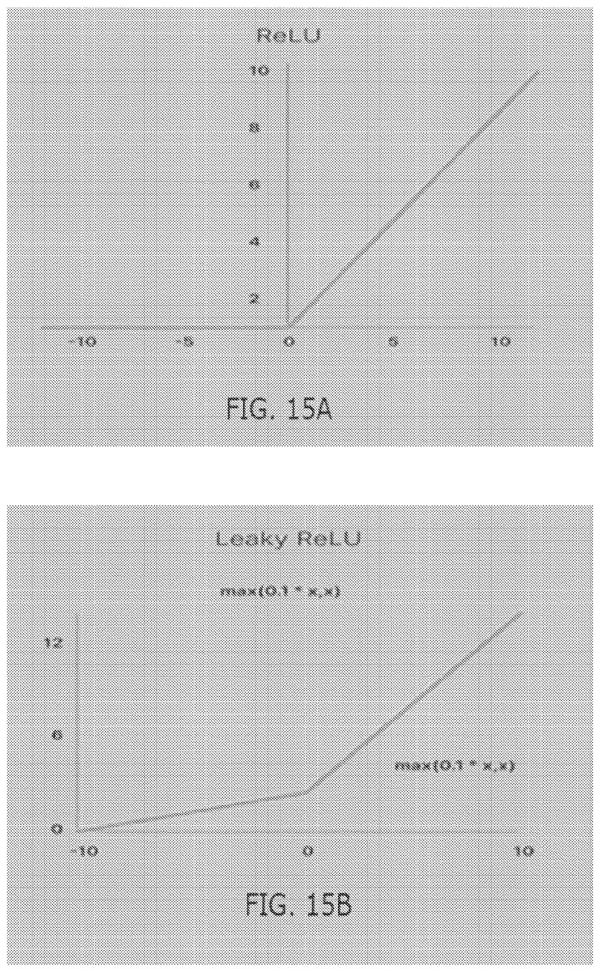

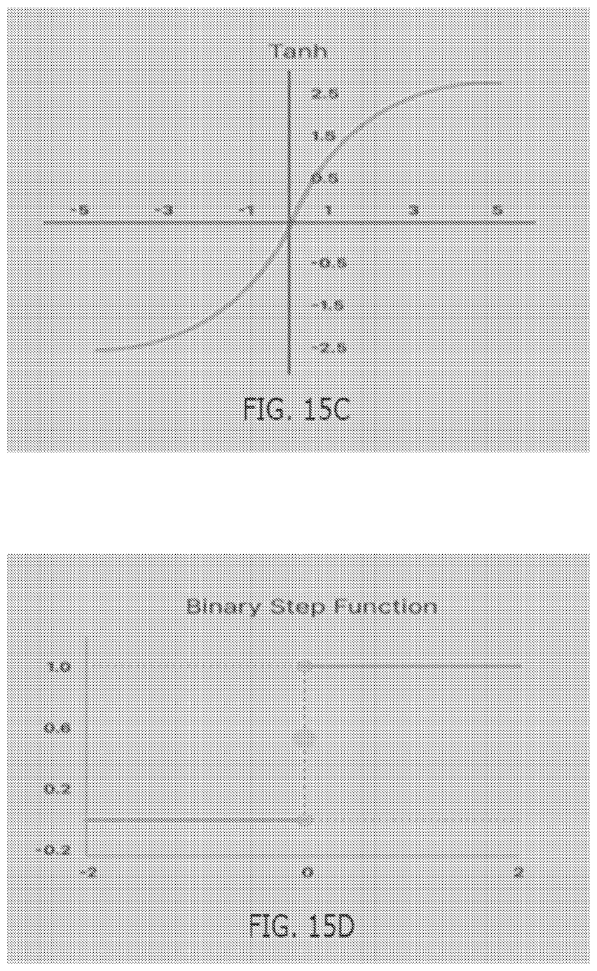

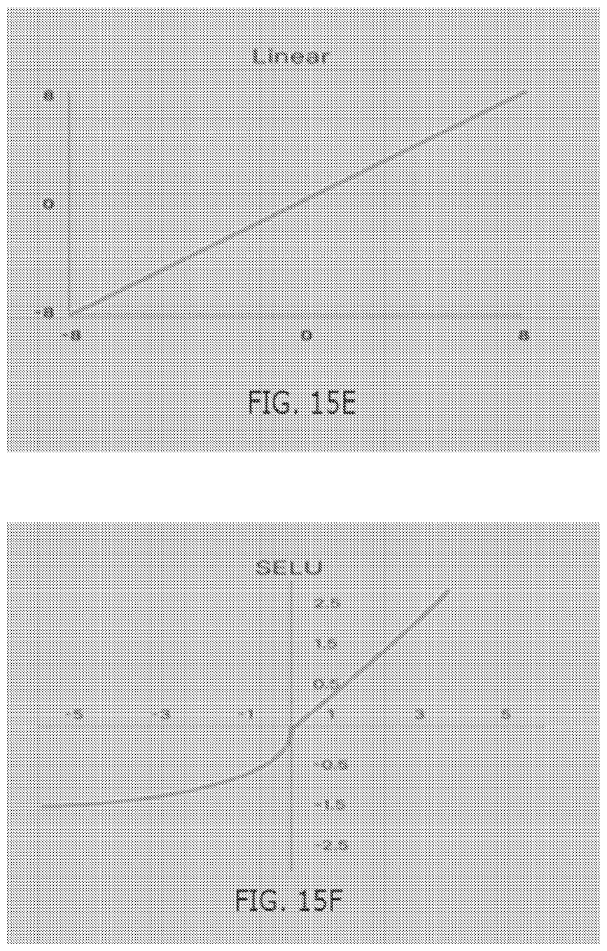

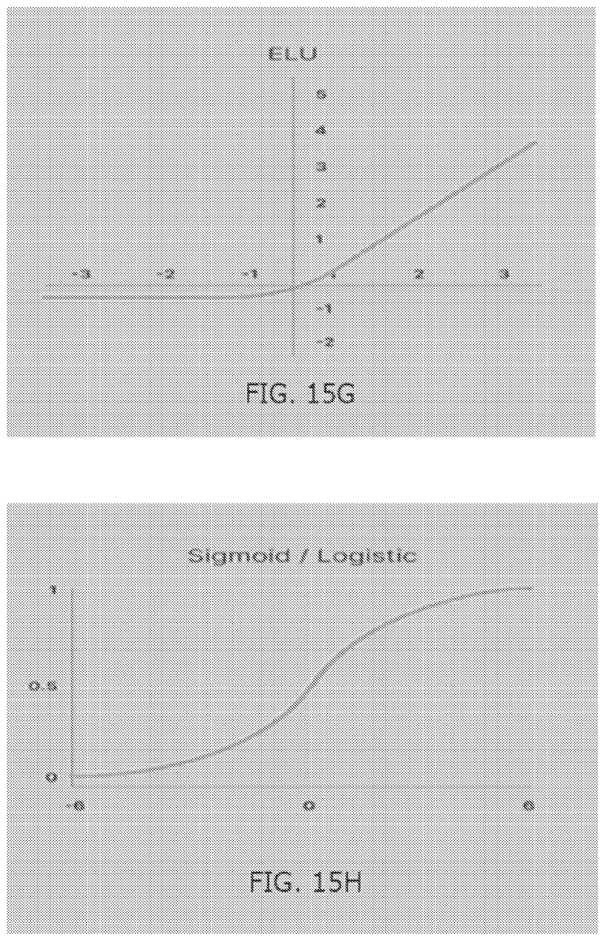

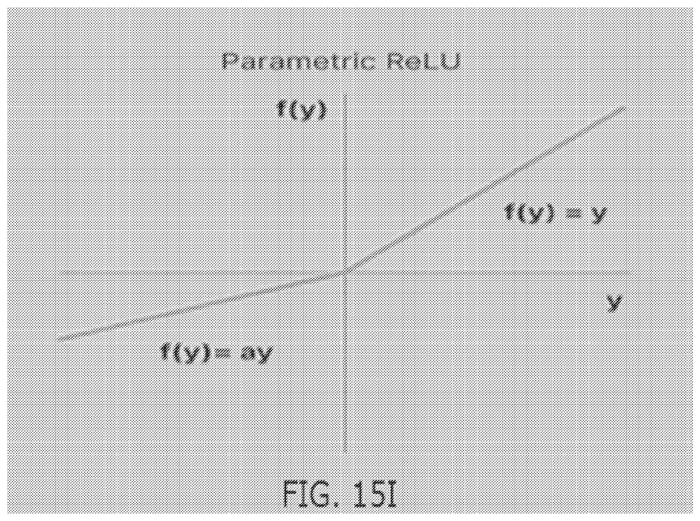

A non-limiting example is MASEC implementation of Artificial Neural Network (ANN) activation (also called squashing) functions. In ANNs, each neuron forms a weighted sum of its inputs and passes the resulting scalar value through its activation function. ANN activation (squashing) function diverse examples are shown in FIGS. 15A-15I (ReLU FIG. 15A; Leaky ReLU FIG. 15B; Tanh FIG. 15C; Binary Step Function FIG. 15D; Linear FIG. 15E; SELU FIG. 15F; ELU FIG. 15G; Sigmoid/Logistic FIG. 15H; and/or Parametric ReLU FIG. 15I).

MASEC devices, computers, and/or circuits of the present invention can be constructed to eliminate several, many, or all, current mathematical operations currently used to implement ANN activation functions. This MASEC ANN activation function replacement results in one or more of greatly reduced die (chip) size, reduced electrical requirements, and greatly reduced operating temperatures. This significantly increases several, many, or all, aspects of ANN performance.

As a non-limiting example of the invention, MASEC devices, computers, or circuits can optionally include: direct band gap semiconductors, such as, but not limited to, current III-V periodic table elements, including, but not limited to, one or more of:

Group IV / carbon family elements carbon (C), silicon (Si), germanium
(Ge), tin (Sn), lead (Pb), and flerovium (FI);
Group III/ boron family elements: boron (B), aluminum (Al), gallium
(Ga), indium (In), thallium (TI), and nihonium (Nh); and/or
Group V / vanadium family elements: vanadium (V), niobium (Nb),
tantalum (Ta) and dubnium (Db).

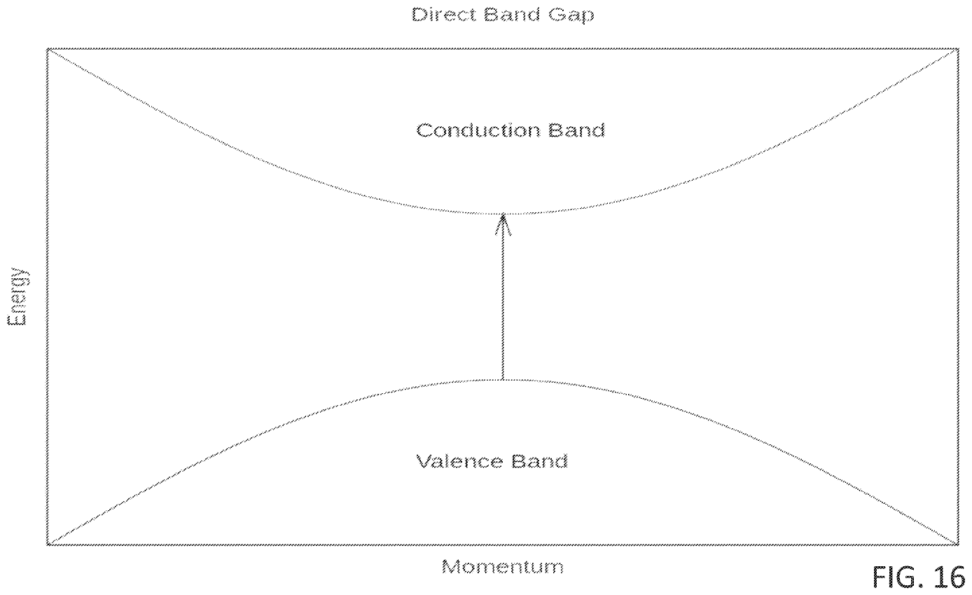

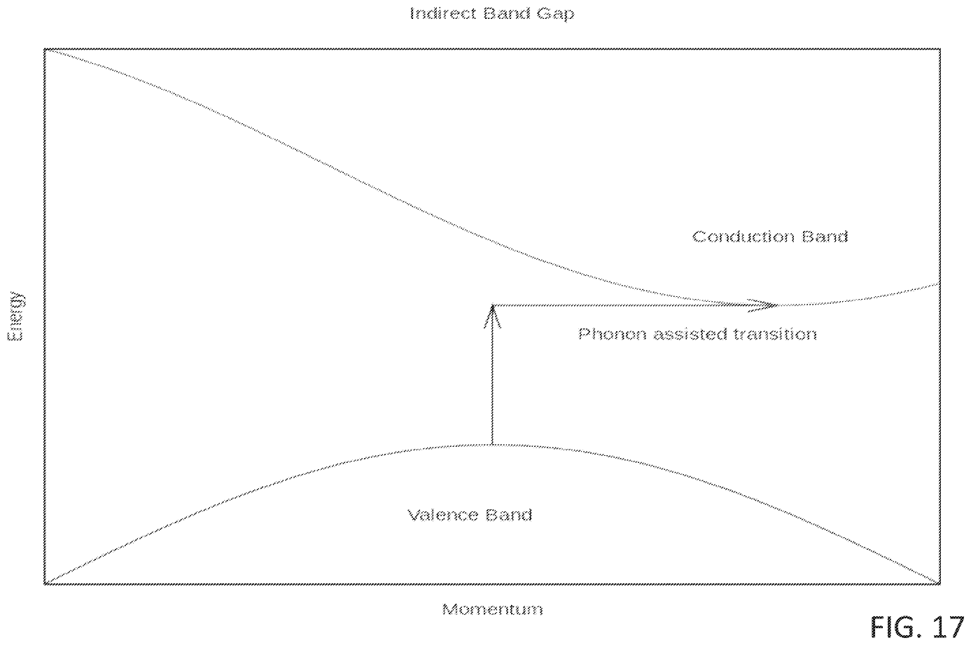

As shown in FIGS. 16-17, direct band gap semiconductors can be more optimal or preferred than indirect band gap semiconductors, where indirect band gap semiconductors may be less optimal for use in MASEC devices, computers, or circuits, where indirect band gap semiconductors require phonon assisted transition to move energy from the valence band to the conduction band, whereas direct band gap materials do not, so direct band gap semiconductors will have faster and/or more accurate data and signal processing than indirect band gap semiconductors. In physics, a phonon is a collective excitation in a periodic, elastic arrangement of atoms or molecules in condensed matter. Phonons are a type of quasiparticle. Quasiparticles are closely related, coupled, emergent phenomena arising when a microscopically complex system of fermion (matter) particles interact as a quantum mechanically loosely coupled unified cluster within a solid (and some superfluid's, e.g., but not limited to Helium 3). Phonon interactions that mediate indirect band gap energy transitions are sensitive to thermal noise and can further act as a dampening effect on MASEC resolution.

MASEC real machines of the invention cam optionally transcend Turing machines with their ability to solve previously exponentially intractable computational challenges in polynomial time. For example, a novel MASEC 3SAT algorithm of the invention can include the use of MASEC complex logarithm computations O(1) applied to translating 3SAT into the continuous domain. A non-limiting example includes a MASEC general algorithm for converting a 3SAT problem into a multi-dimensional integration that can be carried out entirely with MASEC devices of the invention. This MASEC algorithm for a very large number of continuous variables is a new transformation that exponentially reduces the number of computational operations and makes use of properties of polylogarithmic functions implemented using novel MASEC devices alone. The extension of this MASEC algorithm to SHA256 (for example) or any NP-complete problem is possible since all NP-complete computational problems are equivalent according to the invention. The MASEC algorithm, as a non-limiting example is generic and can be used to find solutions for other computationally challenging NP-complete problems. The fundamental MASEC NP-complete solutions begin with the following two integrals.

The NP-complete deterministic polynomial time algorithm is expressed symbolically like this:

$${\sum }_{{i}_{t} = 0}^{1} {\sum }_{{i}_{\text{?}} = 0}^{1} {\sum }_{{i}_{\text{?}} = 0}^{1} ⋯ {\sum }_{{i}_{\text{?}} = 0}^{1} H ( {p}_{o} , , {q}_{k - 1} ) {\to }_{\text{?}} {\int }_{- ε}^{1 + ε} ⋯ {\int }_{- ε}^{1 + ε} HP ( {p}_{0} , {p}_{1} , … , {p}_{i - 1} , 1 , {p}_{i + 1} , … , {p}_{k - 1} , {q}_{0} , … , {q}_{k - 1} ) {dp}_{0} … {dq}_{k - 1} - {\int }_{- ε}^{1 + ε} ⋯ {\int }_{- ε}^{1 + ε} HP ( {p}_{0} , {p}_{1} , … , {p}_{i - 1} , 1 , {p}_{i + 1} , … , {p}_{k - 1} , {q}_{0} , … , {q}_{k - 1} ) {dp}_{0} … {dq}_{k - 1}$$

$${\sum }_{{i}_{t} = 0}^{1} {\sum }_{{i}_{\text{?}} = 0}^{1} {\sum }_{{i}_{\text{?}} = 0}^{1} ⋯ {\sum }_{{i}_{\text{?}} = 0}^{1} H ( {p}_{o} , , {q}_{k - 1} ) {\to }_{\text{?}} {\int }_{- ε}^{1 + ε} ⋯ {\int }_{- ε}^{1 + ε} HP ( {p}_{0} , {p}_{1} , … , {p}_{i - 1} , 0 , {p}_{i + 1} , … , {p}_{k - 1} , {q}_{0} , … , {q}_{k - 1} ) {dp}_{0} … {dq}_{k - 1} - {\int }_{- ε}^{1 + ε} ⋯ {\int }_{- ε}^{1 + ε} HP ( {p}_{0} , {p}_{1} , … , {p}_{i - 1} , 0 , {p}_{i + 1} , … , {p}_{k - 1} , {q}_{0} , … , {q}_{k - 1} ) {dp}_{0} … {dq}_{k - 1}$$

$$\text{?} \text{indicates text missing or illegible when filed}$$

Whilst evaluation of the summations requires exponentially many terms, the evaluation of the integrals on the right-hand side of this relation can be done in succession for each variable by transforming the summation with exponentially many terms into two integral evaluations. By determining which of the two integral evaluations results is larger (as a function of e) value, it is not required to explicitly evaluate the integrals (1) and (2). However, for the sake of completeness and clarity, we can demonstrate the entire evaluation in the case of relatively few variables.

Consider pᵢ and the two possible conjectures for pᵢ and with the below four integrals:

$${I}_{1}^{( + )} = {\int }_{- ε}^{1 + ε} {\int }_{- ε}^{1 + ε} {\int }_{- ε}^{1 + ε} ⋯ {\int }_{- ε}^{1 + ε} HP ( {p}_{0} , {p}_{1} , … , {p}_{i - 1} , 1 , {p}_{i + 1} , … , {p}_{k - 1} , {q}_{0} , {q}_{1} , … , {q}_{k - 1} ) {dp}_{0} … {dq}_{k - 1}$$

$${I}_{1}^{( - )} = {\int }_{ε}^{1 - ε} {\int }_{ε}^{1 - ε} {\int }_{ε}^{1 - ε} ⋯ {\int }_{ε}^{1 - ε} HP ( {p}_{0} , {p}_{1} , … , {p}_{i - 1} , 1 , {p}_{i + 1} , … , {p}_{k - 1} , {q}_{0} , {q}_{1} , … , {q}_{k - 1} ) {dp}_{0} … {dq}_{k - 1}$$

$${I}_{0}^{( + )} = {\int }_{- ε}^{1 + ε} {\int }_{- ε}^{1 + ε} {\int }_{- ε}^{1 + ε} ⋯ {\int }_{- ε}^{1 + ε} HP ( {p}_{0} , {p}_{1} , … , {p}_{i - 1} , 0 , {p}_{i + 1} , … , {p}_{k - 1} , {q}_{0} , {q}_{1} , … , {q}_{k - 1} ) {dp}_{0} … {dq}_{k - 1}$$

$${I}_{0}^{( - )} = {\int }_{ε}^{1 - ε} {\int }_{ε}^{1 - ε} {\int }_{ε}^{1 - ε} ⋯ {\int }_{ε}^{1 - ε} HP ( {p}_{0} , {p}_{1} , … , {p}_{i - 1} , 0 , {p}_{i + 1} , … , {p}_{k - 1} , {q}_{0} , {q}_{1} , … , {q}_{k - 1} ) {dp}_{0} … {dq}_{k - 1}$$

Compare the two limits:

$${Y}_{1} = {lim}_{ε \to 0} {I}_{1}^{( + )} - {I}_{1}^{( - )}$$

$${Y}_{0} = {lim}_{ε \to 0} {I}_{0}^{( + )} - {I}_{0}^{( - )}$$

If Y₁>Y₀, then the i-th bit of p is conjectured to be ONE, otherwise it is conjectured to be ZERO. In the specific example provided, Y₁=0, whereas Y₀=2(½+ε)ε; The fact that Y₀ is larger indicates that the correct value for pᵢ is expected to be 0 (which is true). Summarizing below: As a function of ε, the formulae for Y₁ and Yₙ are polynomial expressions.
Both polynomials have a constant term 0.
There is no need to compute the entire polynomial expansions.
The first terms in the polynomial expansions of a that differ will determine which one of the two essential values (that is, Y₁ or Y₀) is larger.
The examples above indicate that this is occurring in considering very low degrees of E, therefore, the integration can be pruned in such a way as to indicate only the first (low degree) components of the polynomial expansions.

FIG. 10A-B shows a general flowchart of the MASEC Real Machine NP-complete solution circuit algorithm, wherein the steps can include one, two, three, and/or four of more of: (1) Convert boolean formula to polynomial; (2) Select bit to be determined (e.g., i-th bit); (3) Evaluate the integrals as provided above; (4) Repeat the process for all remaining bits of the original Boolean formula; and/or (5) Based on the outcome of the previous calculation(s), choose/select/incorporate the i-th bit.

Summarizing: Within the NP-complete solution, the original product—if expanded—contains exponentially many terms, whereas the MASEC summation contains only polynomial many terms. When we work within epsilon and 1—epsilon, we ensure the logarithms are computed, and that they are finite and real numbers. We obtain 0-1 values by letting epsilon tend to zero.

MASEC Real Machine example with a 3-SAT problem

The following non-limiting example is aimed at clarifying the behavior of the algorithm outlined above in the case of a simple 3-SAT problem. The application to SHA256 becomes apparent in what follows.

Consider the following 3-SAT illustrative problem:

Given the boolean function: f(b1,b2,b3,b4,b5)=(b1 or b2 or b3) and (not b2 or b3 or b5) and (b1 or not b3 or b4) and (not b1 or b3 or b5).

Problem: Try to find assignments for the five boolean variables so that the value of f will be TRUE.

A direct computation of the values of the function f showcases that it has a true value for 16 of the possible assignments for the boolean variables (b₁, b₂, b₃, b₄, b₅) and for the remaining 16 possible assignments it is false.

Performing the conversion from boolean to algebraic form, we have the following polynomials:

$${f}_{1} ( {b}_{1} , {b}_{2} , {b}_{3} , {b}_{4} , {b}_{5} ) = 1 - ( 1 - {b}_{1} ) ( 1 - {b}_{2} ) ( 1 - {b}_{3} )$$

$${f}_{2} ( {b}_{1} , {b}_{2} , {b}_{3} , {b}_{4} , {b}_{5} ) = 1 - {b}_{2} ( 1 - {b}_{3} ) ( 1 - {b}_{5} )$$

$${f}_{3} ( {b}_{1} , {b}_{2} , {b}_{3} , {b}_{4} , {b}_{5} ) = 1 - ( 1 - {b}_{1} ) {b}_{3} ( 1 - {b}_{4} )$$

$${f}_{4} ( {b}_{1} , {b}_{2} , {b}_{3} , {b}_{4} , {b}_{5} ) = 1 - {b}_{1} ( 1 - {b}_{3} ) {b}_{5}$$

and consequently, the master polynomial (their product):

$$T ( {b}_{1} , {b}_{2} , {b}_{3} , {b}_{4} , {b}_{5} ) = {\prod }_{i = 1}^{4} {f}_{i} ( {b}_{1} , {b}_{2} , {b}_{3} , {b}_{4} , {b}_{5} )$$

Now let us select one of the boolean variables, say, b₃ and try to see if there are assignments for the other four variables such that the value of the boolean function f(b1,b2,b3,b4,b5) will be 1 and, more importantly, how often. Ergo, we create two polynomials based on the two possible values for b₃, then we evaluate:

$${H}_{b 3}^{( 0 )} ( ε ) = {\int }_{- ε}^{1 + ε} {\int }_{- ε}^{1 + ε} {\int }_{- ε}^{+ ε} {\int }_{- ε}^{1 + ε} \{ {\int }_{- ε}^{1 + ε} T ( {b}_{1} , {b}_{2} \} {b}_{3} , {b}_{4} , {b}_{5} ) {db}_{1} d {b}_{2} d {b}_{3} d {b}_{4} d {b}_{5} - {\int }_{ε}^{1 - ε} {\int }_{ε}^{1 - ε} {\int }_{1 - ε}^{1 + ε} {\int }_{ε}^{1 - ε} \{ {\int }_{ε}^{1 - ε} T ( {b}_{1} , {b}_{2} \} , {b}_{3} , {b}_{4} , {b}_{5} ) {db}_{1} d {b}_{2} d {b}_{3} d {b}_{4} d {b}_{5} = \frac{296}{27} {ε}^{2} + \frac{1765}{108} {ε}^{4} - \frac{37561}{540} {ε}^{6} - \frac{271}{15} {ε}^{8} + \frac{791}{27} {ε}^{10} + \frac{2096}{135} {ε}^{12} + \frac{16}{27} {ε}^{14} \\ And \\ {H}_{b 3}^{( 1 )} ( ε ) = {\int }_{- ε}^{1 + ε} {\int }_{- ε}^{1 + ε} {\int }_{- ε}^{+ ε} {\int }_{- ε}^{1 + ε} \{ {\int }_{- ε}^{1 + ε} T ( {b}_{1} , {b}_{2} \} {b}_{3} , {b}_{4} , {b}_{5} ) {db}_{1} d {b}_{2} d {b}_{3} d {b}_{4} d {b}_{5} - {\int }_{ε}^{1 - ε} {\int }_{ε}^{1 - ε} {\int }_{1 - ε}^{1 + ε} {\int }_{ε}^{1 - ε} \{ {\int }_{ε}^{1 - ε} T ( {b}_{1} , {b}_{2} \} , {b}_{3} , {b}_{4} , {b}_{5} ) {db}_{1} d {b}_{2} d {b}_{3} d {b}_{4} d {b}_{5} = 24 {ε}^{2} + \frac{379}{4} {ε}^{4} - \frac{6481}{540} {ε}^{6} - \frac{538}{45} {ε}^{8} - \frac{1}{3} {ε}^{10} + \frac{32}{45} {ε}^{12} + \frac{16}{27} {ε}^{14}$$

The coefficients to the lowest power of e are the only important components. Since in the case of b3=1 the coefficients are equal to 24, whereas if b3=O the coefficient is equal to 296/27, we make a conclusion that it is better to select b3 as 1. This is in excellent agreement with the exhaustive search over the truth table.

To get additional intuition about this MASEC algorithm, we apply the same procedure for b₁:

$${H}_{b 1}^{( 0 )} ( ε ) = {\int }_{- ε}^{+ ε} {\int }_{- ε}^{1 + ε} {\int }_{1 - ε}^{1 + ε} {\int }_{- ε}^{1 + ε} \{ {\int }_{- ε}^{1 + ε} T ( {b}_{1} , {b}_{2} \} {b}_{3} , {b}_{4} , {b}_{5} ) {db}_{1} d {b}_{2} d {b}_{3} d {b}_{4} d {b}_{5} - {\int }_{- ε}^{+ ε} {\int }_{ε}^{1 - ε} {\int }_{ε}^{10 ε} {\int }_{ε}^{1 - ε} \{ {\int }_{ε}^{1 - ε} T ( {b}_{1} , {b}_{2} \} , {b}_{3} , {b}_{4} , {b}_{5} ) {db}_{1} d {b}_{2} d {b}_{3} d {b}_{4} d {b}_{5} = \frac{128}{9} {ε}^{2} + \frac{10199}{270} {ε}^{4} - \frac{8042}{135} {ε}^{6} - \frac{3688}{135} {ε}^{8} + \frac{1808}{27} {ε}^{10} + \frac{46}{27} {ε}^{12} + \frac{128}{45} {ε}^{14} \\ and {H}_{b 1}^{( 1 )} ( ε ) = 1 {\int }_{1 - ε}^{1 + ε} {\int }_{- ε}^{1 + ε} {\int }_{1 - ε}^{+ ε} {\int }_{- ε}^{1 + ε} \{ {\int }_{- ε}^{1 + ε} T ( {b}_{1} , {b}_{2} \} {b}_{3} , {b}_{4} , {b}_{5} ) {db}_{1} d {b}_{2} d {b}_{3} d {b}_{4} d {b}_{5} - {\int }_{1 - ε}^{1 + ε} {\int }_{ε}^{1 - ε} {\int }_{ε}^{1 - ε} {\int }_{ε}^{1 - ε} \{ {\int }_{ε}^{1 - ε} T ( {b}_{1} , {b}_{2} \} , {b}_{3} , {b}_{4} , {b}_{5} ) {db}_{1} d {b}_{2} d {b}_{3} d {b}_{4} d {b}_{5} = \frac{187}{9} {ε}^{2} + \frac{20723}{270} {ε}^{4} - \frac{4349}{135} {ε}^{6} - \frac{2431}{135} {ε}^{8} + \frac{1496}{135} {ε}^{10} + \frac{32}{27} {ε}^{12} - \frac{64}{45} {ε}^{14}$$

This above outcome provides that if one tabulates the truth table of the original boolean function f, one will see that if b₃=1, then the value of f is TRUE in 12 of the 16 possible choices for (b₁,b₂,b₄,b₅) and if b₃=0, then the value of f is FALSE in 4 of the 16 possible choices for (b₁,b₂,b₄,b₅). If b₁=1, then the value of f is TRUE in 9 of the 16 possible choices for (b₂,b₃,b₄,b₅) and if b₁=0, then the value of f is FALSE in 7 of the 16 possible choices for (b₂,3₂,b₄,b₅). Therefore, if one must make a guess about the values of b3 and b1, both should be selected as ‘1’. Selecting b3=1 significantly increases the chance to find a correct assignment for the remaining variables, which is indicated by the following limit:

$${lim}_{ε \to 0} \frac{{H}_{b 3}^{( 1 )} ( ε )}{{H}_{b 3}^{( 0 )} ( ε )} = \frac{81}{37}$$

The same ratio for the variable b1 is:

$${lim}_{ε \to 0} \frac{{H}_{b 3}^{( 1 )} ( ε )}{{H}_{b 3}^{( 0 )} ( ε )} = \frac{187}{128}$$

Several important observations can be made at this point: The first is this: We are trying to find an efficient algorithm for solving the 3SAT problem. This problem is the first one belonging to the class of NP-complete problems. What is achieved:
1. As a function of E, the functions H1(ε) and H0(ε) are polynomial functions without constant and linear terms.
2. Since H1(ε)=c₁ε²+o(ε²) and H0(ε)=C₀ε²+o(ε²), the only essential components to discover are the values of the constants c₁ and c₀. The larger one determines what value of the bit in consideration (in the above example: b₃ and b₁) occurs in larger number of true assignments/values of the function f.
3. The discrete problem (summation) is converted into a continuous MASEC problem. This enables symbolic evaluation of the associated integrals. Since we are dealing with polynomial functions, the integration—in principle—is computed to any desired precision.

Now, what prevents this algorithm from being directly applicable to a large scale 3SAT problem?

Let us look at the actual polynomial expansion of the function f. The use of Wolfram Research Mathematica function “Expand[ ]” allows us to have a look at the full extent of the expression:

```
f(b1,b2,b3,b4,b5) = b1 + b2 − 2 b1 b2 − b2\hat{ }2 + b1 b2\hat{ }2 + b3 − 2 b1 b3 + b1\hat{ }2 b3 − 3 b2 b3 +
  6 b1 b2 b3 − 2 b1\hat{ }2 b2 b3 + 3 b2\hat{ }2 b3 − 4 b1 b2\hat{ }2 b3 + b1\hat{ }2 b2\hat{ }2 b3 − b3\hat{ }2 +
  2 b1 b3\hat{ }2 − b1\hat{ }2 b3\hat{ }2 + 3 b2 b3\hat{ }2 − 6 b1 b2 b3\hat{ }2 + 3 b1\hat{ }2 b2 b3\hat{ }2 −
  3 b2\hat{ }2 b3\hat{ }2 + 5 b1 b2\hat{ }2 b3\hat{ }2 − 2 b1\hat{ }2 b2\hat{ }2 b3\hat{ }2 − b2 b3\hat{ }3 + 2 b1 b2 b3\hat{ }3 −
  b1\hat{ }2 b2 b3\hat{ }3 + b2\hat{ }2 b3\hat{ }3 − 2 b1 b2\hat{ }2 b3\hat{ }3 + b1\hat{ }2 b2\hat{ }2 b3\hat{ }3 + b1 b3 b4 −
  b1\hat{ }2 b3 b4 + b2 b3 b4 − 3 b1 b2 b3 b4 + 2 b1\hat{ }2 b2 b3 b4 − b2\hat{ }2 b3 b4 +
  2 b1 b2\hat{ }2 b3 b4 − b1\hat{ }2 b2\hat{ }2 b3 b4 + b3\hat{ }2 b4 − 2 b1 b3\hat{ }2 b4 + b1\hat{ }2 b3\hat{ }2 b4 −
  2 b2 b3\hat{ }2 b4 + 5 b1 b2 b3\hat{ }2 b4 − 3 b1\hat{ }2 b2 b3\hat{ }2 b4 + 2 b2\hat{ }2 b3\hat{ }2 b4 −
  4 b1 b2\hat{ }2 b3\hat{ }2 b4 + 2 b1\hat{ }2 b2\hat{ }2 b3\hat{ }2 b4 + b2 b3\hat{ }3 b4 − 2 b1 b2 b3\hat{ }3 b4 +
  b1\hat{ }2 b2 b3\hat{ }3 b4 − b2\hat{ }2 b3\hat{ }3 b4 + 2 b1 b2\hat{ }2 b3\hat{ }3 b4 − b1\hat{ }2 b2\hat{ }2 b3\hat{ }3 b4 −
  b1\hat{ }2 b5 + 2 b1\hat{ }2 b2 b5 + b2\hat{ }2 b5 − b1\hat{ }2 b2\hat{ }2 b5 − b1 b3 b5 + 3 b1\hat{ }2 b3 b5 −
  b1\hat{ }3 b3 b5 + b2 b3 b5 + b1 b2 b3 b5 − 7 b1\hat{ }2 b2 b3 b5 + 2 b1\hat{ }3 b2 b3 b5 −
  3 b2\hat{ }2 b3 b5 + 4 b1\hat{ }2 b2\hat{ }2 b3 b5 − b1\hat{ }3 b2\hat{ }2 b3 b5 + 2 b1 b3\hat{ }2 b5 −
  4 b1\hat{ }2 b3\hat{ }2 b5 + 2 b1\hat{ }3 b3\hat{ }2 b5 − 2 b2 b3\hat{ }2 b5 − 2 b1 b2 b3\hat{ }2 b5 +
  10 b1\hat{ }2 b2 b3\hat{ }2 b5 − 5 b1\hat{ }3 b2 b3\hat{ }2 b5 + 3 b2\hat{ }2 b3\hat{ }2 b5 + b1 b2\hat{ }2 b3\hat{ }2 b5 −
  7 b1\hat{ }2 b2\hat{ }2 b3\hat{ }2 b5 + 3 b1\hat{ }3 b2\hat{ }2 b3\hat{ }2 b5 − b1 b3\hat{ }3 b5 + 2 b1\hat{ }2 b3\hat{ }3 b5 −
  b1\hat{ }3 b3\hat{ }3 b5 + b2 b3\hat{ }3 b5 + 2 b1 b2 b3\hat{ }3 b5 − 7 b1\hat{ }2 b2 b3\hat{ }3 b5 +
  4 b1\hat{ }3 b2 b3\hat{ }3 b5 − b2\hat{ }2 b3\hat{ }3 b5 − 2 b1 b2\hat{ }2 b3\hat{ }3 b5 + 6 b1\hat{ }2 b2\hat{ }2 b3\hat{ }3 b5 −
  3 b1\hat{ }3 b2\hat{ }2 b3\hat{ }3 b5 − b1 b2 b3\hat{ }4 b5 + 2 b1\hat{ }2 b2 b3\hat{ }4 b5 − b1\hat{ }3 b2 b3\hat{ }4 b5 +
  b1 b2\hat{ }2 b3\hat{ }4 b5 − 2 b1\hat{ }2 b2\hat{ }2 b3\hat{ }4 b5 + b1\hat{ }3 b2\hat{ }2 b3\hat{ }4 b5 − b1\hat{ }2 b3 b4 b5 +
  b1\hat{ }3 b3 b4 b5 + 2 b1\hat{ }2 b2 b3 b4 b5 − 2 b1\hat{ }3 b2 b3 b4 b5 + b2\hat{ }2 b3 b4 b5 −
  b1 b2\hat{ }2 b3 b4 b5 − b1\hat{ }2 b2\hat{ }2 b3 b4 b5 + b1\hat{ }3 b2\hat{ }2 b3 b4 b5 − b1 b3\hat{ }2 b4 b5 +
  3 b1\hat{ }2 b3\hat{ }2 b4 b5 − 2 b1\hat{ }3 b3\hat{ }2 b4 b5 + b2 b3\hat{ }2 b4 b5 −
  6 b1\hat{ }2 b2 b3\hat{ }2 b4 b5 + 5 b1\hat{ }3 b2 b3\hat{ }2 b4 b5 − 2 b2\hat{ }2 b3\hat{ }2 b4 b5 +
  b1 b2\hat{ }2 b3\hat{ }2 b4 b5 + 4 b1\hat{ }2 b2\hat{ }2 b3\hat{ }2 b4 b5 − 3 b1\hat{ }3 b2\hat{ }2 b3\hat{ }2 b4 b5 +
  b1 b3\hat{ }3 b4 b5 − 2 b1\hat{ }2 b3\hat{ }3 b4 b5 + b1\hat{ }3 b3\hat{ }3 b4 b5 − b2 b3\hat{ }3 b4 b5 −
  b1 b2 b3\hat{ }3 b4 b5 + 6 b1\hat{ }2 b2 b3\hat{ }3 b4 b5 − 4 b1\hat{ }3 b2 b3\hat{ }3 b4 b5 +
  b2\hat{ }2 b3\hat{ }3 b4 b5 + b1 b2\hat{ }2 b3\hat{ }3 b4 b5 − 5 b1\hat{ }2 b2\hat{ }2 b3\hat{ }3 b4 b5 +
  3 b1\hat{ }3 b2\hat{ }2 b3\hat{ }3 b4 b5 + b1 b2 b3\hat{ }4 b4 b5 − 2 b1\hat{ }2 b2 b3\hat{ }4 b4 b5 +
  b1\hat{ }3 b2 b3\hat{ }4 b4 b5 − b1 b2\hat{ }2 b3\hat{ }4 b4 b5 + 2 b1\hat{ }2 b2\hat{ }2 b3\hat{ }4 b4 b5 −
  b1\hat{ }3 b2\hat{ }2 b3\hat{ }4 b4 b5 − b1\hat{ }2 b2 b5\hat{ }2 − b1 b2\hat{ }2 b5\hat{ }2 + b1\hat{ }2 b2\hat{ }2 b5\hat{ }2 −
  b1 b2 b3 b5\hat{ }2 + 4 b1\hat{ }2 b2 b3 b5\hat{ }2 − b1\hat{ }3 b2 b3 b5\hat{ }2 + 4 b1 b2\hat{ }2 b3 b5\hat{ }2 −
  5 b1\hat{ }2 b2\hat{ }2 b3 b5\hat{ }2 + b1\hat{ }3 b2\hat{ }2 b3 b5\hat{ }2 + 3 b1 b2 b3\hat{ }2 b5\hat{ }2 −
  7 b1\hat{ }2 b2 b3\hat{ }2 b5\hat{ }2 + 3 b1\hat{ }3 b2 b3\hat{ }2 b5\hat{ }2 − 6 b1 b2\hat{ }2 b3\hat{ }2 b5\hat{ }2 +
  9 b1\hat{ }2 b2\hat{ }2 b3\hat{ }2 b5\hat{ }2 − 3 b1\hat{ }3 b2\hat{ }2 b3\hat{ }2 b5\hat{ }2 − 3 b1 b2 b3\hat{ }3 b5\hat{ }2 +
  6 b1\hat{ }2 b2 b3\hat{ }3 b5\hat{ }2 − 3 b1\hat{ }3 b2 b3\hat{ }3 b5\hat{ }2 + 4 b1 b2\hat{ }2 b3\hat{ }3 b5\hat{ }2 −
  7 b1\hat{ }2 b2\hat{ }2 b3\hat{ }3 b5\hat{ }2 + 3 b1\hat{ }3 b2\hat{ }2 b3\hat{ }3 b5\hat{ }2 + b1 b2 b3\hat{ }4 b5\hat{ }2 −
  2 b1\hat{ }2 b2 b3\hat{ }4 b5\hat{ }2 + b1\hat{ }3 b2 b3\hat{ }4 b5\hat{ }2 − b1 b2\hat{ }2 b3\hat{ }4 b5\hat{ }2 +
  2 b1\hat{ }2 b2\hat{ }2 b3\hat{ }4 b5\hat{ }2 − b1\hat{ }3 b2\hat{ }2 b3\hat{ }4 b5\hat{ }2 − b1\hat{ }2 b2 b3 b4 b5\hat{ }2 +
  b1\hat{ }3 b2 b3 b4 b5\hat{ }2 − b1 b2\hat{ }2 b3 b4 b5\hat{ }2 + 2 b1\hat{ }2 b2\hat{ }2 b3 b4 b5\hat{ }2 −
  b1\hat{ }3 b2\hat{ }2 b3 b4 b5\hat{ }2 − b1 b2 b3\hat{ }2 b4 b5\hat{ }2 + 4 b1\hat{ }2 b2 b3\hat{ }2 b4 b5\hat{ }2 −
  3 b1\hat{ }3 b2 b3\hat{ }2 b4 b5\hat{ }2 + 3 b1 b2\hat{ }2 b3\hat{ }2 b4 b5\hat{ }2 − 6 b1\hat{ }2 b2\hat{ }2 b3\hat{ }2 b4 b5\hat{ }2 +
  3 b1\hat{ }3 b2\hat{ }2 b3\hat{ }2 b4 b5\hat{ }2 + 2 b1 b2 b3\hat{ }3 b4 b5\hat{ }2 − 5 b1\hat{ }2 b2 b3\hat{ }3 b4 b5\hat{ }2 +
  3 b1\hat{ }3 b2 b3\hat{ }3 b4 b5\hat{ }2 − 3 b1 b2\hat{ }2 b3\hat{ }3 b4 b5\hat{ }2 + 6 b1\hat{ }2 b2\hat{ }2 b3\hat{ }3 b4 b5\hat{ }2 −
  3 b1\hat{ }3 b2\hat{ }2 b3\hat{ }3 b4 b5\hat{ }2 − b1 b2 b3\hat{ }4 b4 b5\hat{ }2 + 2 b1\hat{ }2 b2 b3\hat{ }4 b4 b5\hat{ }2 −
  b1\hat{ }3 b2 b3\hat{ }4 b4 b5\hat{ }2 + b1 b2\hat{ }2 b3\hat{ }4 b4 b5\hat{ }2 − 2 b1\hat{ }2 b2\hat{ }2 b3\hat{ }4 b4 b5\hat{ }2 +
  b1\hat{ }3 b2\hat{ }2 b3\hat{ }4 b4 b5\hat{ }2
```

(2)

The number of terms grows as an exponential function of the number of variables. If one tries to integrate the individual components occurring in the above formula, then one can see that every one of them contains a term of the form cε², so the hope that we can evaluate only a few terms of the expansion and make a correct judgment about the

$${lim}_{ε \to 0} \frac{{H}_{b ( i )}^{( 1 )} ( ε )}{{H}_{b ( i )}^{( 0 )} ( ε )}$$

has to be abandoned. Converting the product into summation avoids this obstacle. Hence, consider the transformation:

$${\sum }_{{i}_{1 = 0}}^{1} {\sum }_{{i}_{2 = 0}}^{1} {\sum }_{{i}_{3 = 0}}^{1} … {\sum }_{{i}_{\text{?} - 1}}^{1} H ( {p}_{0} , … , {q}_{k - 1} ) {\to }_{discrete to continuous} {\int }_{\text{?} / \text{?}}^{1 - \text{?} / \text{?}} … {\int }_{\text{?} / \text{?}}^{1 - \text{?}} Log [ HP ( {p}_{0} \text{?} {p}_{i - 1} , 1 , {p}_{i + 1} \text{?} {p}_{k - 1} , {q}_{0} \text{?} {q}_{k - 1} ) ] {dp}_{0} … {dq}_{k - 1} - {\int }_{\text{?}}^{1 - \text{?}} … {\int }_{\text{?}}^{1 - \text{?}} Log [ HP ( {p}_{0} \text{?} {p}_{i - 1} , 1 , {p}_{i + 1} \text{?} {p}_{k - 1} , {q}_{0} \text{?} {q}_{k - 1} ) ] {dp}_{0} … {dq}_{k - 1} \qquad ( 3 )$$

$$\text{?} \text{indicates text missing or illegible when filed}$$

There are a few essential differences between transformation (3) and transformation (1):
1. The first important difference is the change of the integration bounds of the first integral. It is done in a way that ensures the strict positivity of the function HP.
2. Since now we are taking a MASEC complex logarithm, the product of the arithmetic versions of the elementary boolean functions is converted into summation. This is especially important in the case of the 3SAT problem, since in this case we will have logarithms of product of at most three polynomials of degree three or less, i.e. third order.
3. The computation is now broken down into several completely independent (highly parallel) and easy-to-evaluate numerical integrals.
4. MASEC integration is needed as the new function cannot be integrated analytically. This poses no implementation hurdles as we can use MASEC techniques based on Richardson extrapolation for fast numerical integration to compute the integral to any precision.
5. One can easily generalize the transformation by using many other MASEC arithmetization strategies. The traditional approach to convert a boolean variable into a real one is to use the function f(x)=x for every single variable. The use of other transformations, like f(x)=x², or x³ can improve the accuracy of numerical integration without affecting the performance of the algorithm. Also, one can use these types of modified transformations for the bit-under-investigation. This is critical to ensure that we do not have to use multi-precision arithmetic. By making use of modified polynomial transformations, we select the powers of x to guarantee reliable computations within IEEE-2019 arithmetic standard.

### Example: Real-World 3SAT Problem

There are many SAT hackathons, so one can download a 3SAT testing problem and perform computational experiments aimed at unveiling the deep details about the MASEC real machine algorithm of the invention, finding some extremely fine-tuned modifications and complete the conversion of the algorithm into a working polynomial-time algorithm. We selected the following function of 20 variables, with 56 clauses. The entire set of clauses are provided in the table below:

| | | | |
|---|---|---|---|
| x15 and x7 and x6 | x17 and ¬x6 and x19 | ¬x4 and ¬x10 and ¬x13 | x7 and ¬x4 and x13 |
| ¬x4 and ¬x17 and ¬x8 | x15 and x8 and x20 | x10 and ¬x3 and x6 | x8 and x16 and ¬x15 |
| ¬xl and ¬x16 and ¬x18 | ¬x3 and ¬x2 and x9 | x4 and ¬x13 and ¬x10 | x4 and x2 and x19 |
| x15 and ¬x18 and ¬x6 | x4 and ¬x18 and x10 | x13 and x14 and x10 | ¬x4 and ¬x8 and ¬x1 |
| x9 and ¬x15 and ¬x7 | x19 and ¬x1 and ¬x3 | ¬x12 and x17 and ¬x7 | x5 and ¬x1 and x7 |
| x12 and x13 and ¬x3 | ¬x16 and x20 and ¬x19 | x18 and ¬x4 and ¬x6 | x19 and ¬x1 and ¬x9 |
| x7 and ¬x20 and x19 | x2 and x5 and x12 | ¬x18 and ¬x9 and ¬x2 | x15 and ¬x20 and ¬x17 |
| x10 and ¬x5 and x2 | ¬x5 and x16 and ¬x18 | ¬x2 and ¬x16 and ¬x1 | x19 and ¬x20 and x16 |
| x5 and ¬x11 and x10 | ¬x17 and ¬x9 and x10 | x6 and ¬x19 and x2 | x2 and x17 and ¬x1 |
| ¬x2 and ¬x5 and ¬x19 | ¬x7 and x20 and x6 | x1 and ¬x18 and ¬x13 | ¬x16 and x2 and ¬x4 |
| x3 and x7 and x15 | x3 and x11 and x7 | x16 and x14 and x1 | ¬x5 and ¬x9 and ¬x18 |
| x3 and x14 and x16 | x6 and ¬x12 and ¬x8 | x2 and ¬x17 and ¬x8 | ¬x9 and ¬x14 and x10 |
| ¬x20 and x7 and x8 | x19 and x18 and ¬x17 | ¬x11 and ¬x20 and x6 | x13 and x11 and x1 |
| ¬x2 and ¬x15 and x19 | x16 and ¬x19 and x12 | x1 and ¬x14 and x15 | ¬x7 and x17 and ¬x1 |

Since the number of variables is small, we analyze the 3SAT boolean function in detail. For one, we found that the function has exactly 638 true assignments. For the set of the true assignments, it is possible to determine exactly how often a particular boolean variable must have a true/false value. This statistic is provided in the next truth table. The first component showcases the number of false values for a particular variable and the second one is the number of true values:

| | | | |
|---|---|---|---|
| (404, 234) | (381, 257) | (413, 225) | (600, 38) |
| (426, 212) | (36, 602) | (208, 430) | (423, 215) |
| (325, 313) | (126, 512) | (233, 405) | (202, 436) |
| (517, 121) | (323, 315) | (79, 559) | (62, 576) |
| (203, 435) | (547, 91) | (0, 638) | (311, 327) |

A look at the truth table shows that for x19, there are no false assignments. Ergo, we can determine if this is detectable by using simple Mathematica codes that calculate the integral transformation (3). The range for the variable x19 is between ε/2 and ε (which tests the conjecture x19=0) and between 1−ε and 1−ε/2 (which test the conjecture x19=1). The selected value for ε in this numerical example is 1/100. The algorithm correctly determines that x19 must be selected as true. We executed the algorithm for x4, x6, x15 and x16 and the algorithm correctly shows that in these cases the values of these variables in most cases are (false, true, true, true).

### Important MASEC Discrete Logarithm Algorithmic Aspects of the Logarithmic Transformation

There are two fundamentally different techniques to handle transformation (3). Since this is critical for the accurate/efficient implementation of the MASEC algorithm we analyze separately:

### 1. Approach Based on SYMBOLIC Integration.

There are, e.g., EIGHT types of integrals that will occur after taking a logarithm from the product of three-term polynomial functions that encode in a continuous manner the boolean clauses. The first two types are presented below, where the rest can be calculated in a similar and/or analogous way.

$$F {L}_{a 1 , b 1 , a 2 , b 2 , a 3 , b 3} ( 0 ) = {\int }_{a 1}^{b 1} {\int }_{a 2}^{b 2} {\int }_{a 3}^{b 3} Log [ 1 - x 1 x 2 x 3 ] dx 1 dx 2 dx 3 \\ {FL}_{a 1 , b 1 , a 2 , b 2 , a 3 , b 3} ( 1 ) = {\int }_{a 1}^{b 1} {\int }_{a 2}^{b 2} {\int }_{a 3}^{b 3} Log [ 1 - x 1 x 2 ( 1 - x 3 ) ] dx 1 dx 2 dx 3$$

The remaining six three-dimensional integrals looks like:

$${FL}_{a 1 , b 1 , a 2 , b 2 , a 3 , b 3} ( 2 ) = {\int }_{a 1}^{b 1} {\int }_{a 2}^{b 2} {\int }_{a 3}^{b 3} Log [ 1 - x 1 ( 1 - x 2 ) x 3 ] dx 1 dx 2 dx 3 \\ {FL}_{a 1 , b 1 , a 2 , b 2 , a 3 , b 3} ( 3 ) = {\int }_{a 1}^{b 1} {\int }_{a 2}^{b 2} {\int }_{a 3}^{b 3} Log [ 1 - x 1 ( 1 - x 2 ) ( 1 - x 3 ) ] dx 1 dx 2 dx 3 \\ {FL}_{a 1 , b 1 , a 2 , b 2 , a 3 , b 3} ( 4 ) = {\int }_{a 1}^{b 1} {\int }_{a 2}^{b 2} {\int }_{a 3}^{b 3} Log [ 1 - ( 1 - x 1 ) x 2 x 3 ] dx 1 dx 2 dx 3 \\ {FL}_{a 1 , b 1 , a 2 , b 2 , a 3 , b 3} ( 5 ) = {\int }_{a 1}^{b 1} {\int }_{a 2}^{b 2} {\int }_{a 3}^{b 3} Log [ 1 - ( 1 - x 1 ) x 2 ( 1 - x 3 ) ] dx 1 dx 2 dx 3 \\ {FL}_{a 1 , b 1 , a 2 , b 2 , a 3 , b 3} ( 6 ) = {\int }_{a 1}^{b 1} {\int }_{a 2}^{b 2} {\int }_{a 3}^{b 3} Log [ 1 - ( 1 - x 1 ) ( 1 - x 2 ) x 3 ] dx 1 dx 2 dx 3 \\ {FL}_{a 1 , b 1 , a 2 , b 2 , a 3 , b 3} ( 7 ) = {\int }_{a 1}^{b 1} {\int }_{a 2}^{b 2} {\int }_{a 3}^{b 3} Log [ 1 - ( 1 - x 1 ) ( 1 - x 2 ) ( 1 - x 3 ) ] dx 1 dx 2 dx 3$$

This integral CAN be evaluated analytically with the assistance of the two Polylog functions:

$$PolyLo g [ 2 , x ] = {\sum }_{k = 1}^{∞} \frac{{z}^{k}}{{k}^{2}} \\ and \\ PolyLog [ 3 , x ] = {\sum }_{k = 1}^{∞} \frac{{z}^{k}}{{k}^{3}}$$

The resulting outcome obtained is:

```
  F0[a1_,b1_,a2_,b2_,a3_,b3_]:= 3 a1 a2 a3−3 a2 a3 b1−3 a1 a3 b2+3 a3 b1 b2−3 a1 a2 b3+3 a2
b1 b3+3 a1 b2 b3−3 b1 b2 b3−a1 a2 a3 Log[1−a1 a2 a3]+Log[−1+a1 a2 a3]+Log[a3] (−Log[1−a1 a2
a3]+Log[−1+a1 a2 a3])+Log[a2] Log[a3] (−Log[1−a1 a2 a3]+Log[−1+a1 a2 a3])+a2 a3 b1 Log[1−a2 a3
b1]−Log[−1+a2 a3 b1]−Log[a3] (−Log[1−a2 a3 b1]+Log[−1+a2 a3 b1])−Log[a2] Log[a3] (−Log[1−a2 a3
b1]+Log[−1+a2 a3 b1])+a1 a3 b2 Log[1−a1 a3 b2]−Log[−1+a1 a3 b2]−Log[a3] (−Log[1−a1 a3 b2]+Log[−
1+a1 a3 b2])−Log[a3] Log[b2] (−Log[1−a1 a3 b2]+Log[−1+a1 a3 b2])−a3 b1 b2 Log[1−a3 b1 b2]+Log[−
1+a3 b1 b2]+Log[a3] (−Log[1−a3 b1 b2]+Log[−1+a3 b1 b2])+Log[a3] Log[b2] (−Log[1−a3 b1 b2]+Log[−
1+a3 b1 b2])+a1 a2 b3 Log[1−a1 a2 b3]−Log[−1+a1 a2 b3]−Log[b3] (−Log[1−a1 a2 b3]+Log[−1+a1 a2
b3])−Log[a2] Log[b3] (−Log[1−a1 a2 b3]+Log[−1+a1 a2 b3])−a2 b1 b3 Log[1−a2 b1 b3]+Log[−1+a2 b1
b3]+Log[b3] (−Log[1−a2 b1 b3]+Log[−1+a2 b1 b3])+Log[a2] Log[b3] (−Log[1−a2 b1 b3]+Log[−1+a2 b1
b3])−a1 b2 b3 Log[1−a1 b2 b3]+Log[−1+a1 b2 b3]+Log[b3] (−Log[1−a1 b2 b3]+Log[−1+a1 b2
b3])+Log[b2] Log[b3] (−Log[1−a1 b2 b3]+Log[−1+a1 b2 b3])+b1 b2 b3 Log[1−b1 b2 b3]−Log[−1+b1 b2
b3]−Log[b3] (−Log[1−b1 b2 b3]+Log[−1+b1 b2 b3])−Log[b2] Log[b3] (−Log[1−b1 b2 b3]+Log[−1+b1 b2
b3])−PolyLog[2,a1 a2 a3]+PolyLog[2,a2 a3 b1]+PolyLog[2,a1 a3 b2]−PolyLog[2,a3 b1 b2]+PolyLog[2,a1
a2 b3]−PolyLog[2,a2 b1 b3]−PolyLog[2,a1 b2 b3]+PolyLog[2,b1 b2 b3]−PolyLog[3,a1 a2
a3]+PolyLog[3,a2 a3 b1]+PolyLog[3,a1 a3 b2]−PolyLog[3,a3 b1 b2]+PolyLog[3,a1 a2 b3]−PolyLog[3,a2
b1 b3]−PolyLog[3,a1 b2 b3]+PolyLog[3,b1 b2 b3] ;
  FL1[a1_,b1_,a2_,b2_,a3_,b3_]:= 3 a1 a2 a3−3 a2 a3 b1−3 a1 a3 b2+3 a3 b1 b2−3 a1 a2 b3+3
a2 b1 b3+3 a1 b2 b3−3 b1 b2 b3−Log[1+a1 a2 (−1+a3)]+a1 a2 Log[1+a1 a2 (−1+a3)]−a1 a2 a3 Log[1+a1
a2 (−1+a3)]+Log[1+a2 (−1+a3) b1]−a2 b1 Log[1+a2 (−1+a3) b1]+a2 a3 b1 Log[1+a2 (−1+a3)
b1]+Log[1+a1 (−1+a3) b2]−a1 b2 Log[1+a1 (−1+a3) b2]+a1 a3 b2 Log[1+a1 (−1+a3) b2]−Log[1+(−1+a3)
b1 b2]+b1 b2 Log[1+(−1+a3) b1 b2]−a3 b1 b2 Log[1+(−1+a3) b1 b2]+Log[1+a1 a2 (−1+b3)]−a1 a2
Log[1+a1 a2 (−1+b3)]+a1 a2 b3 Log[1+a1 a2 (−1+b3)]−Log[1+a2 b1 (−1+b3)]+a2 b1 Log[1+a2 b1 (−
1+b3)]−a2 b1 b3 Log[1+a2 b1 (−1+b3)]−Log[1+a1 b2 (−1+b3)]+a1 b2 Log[1+a1 b2 (−1+b3)]−a1 b2 b3
Log[1+a1 b2 (−1+b3)]+Log[1+b1 b2 (−1+b3)]−b1 b2 Log[1+b1 b2 (−1+b3)]+b1 b2 b3 Log[1+b1 b2 (−
1+b3)]+PolyLog[2,−a1 a2 (−1+a3)]−PolyLog[2,−a2 (−1+a3) b1]−PolyLog[2,−a1 (−1+a3) b2]+PolyLog[2,−(−
1+a3) b1 b2]−PolyLog[2,−a1 a2 (−1+b3)]+PolyLog[2,−a2 b1 (−1+b3)]+PolyLog[2,−a1 b2 (−1+b3)]−
PolyLog[2,−b1 b2 (−1+b3)]+PolyLog[3,−a1 a2 (−1+a3)]−PolyLog[3,−a2 (−1+a3) b1]−PolyLog[3,−a1 (−1+a3)
b2]+PolyLog[3,−(−1+a3) b1 b2]−PolyLog[3,−a1 a2 (−1+b3)]+PolyLog[3,−a2 b1 (−1+b3)]+PolyLog[3,−a1 b2
(−1+b3)]−PolyLog[3,−b1 b2 (−1+b3)] ;
```

The polylogarithmic functions needed in the symbolic evaluations of these integrals are computed with different precisions.

The next section outlines the MASEC approach to this task.

### Example: Consider a Single Clause 3SAT Problem, for Example

$$B ( x 1 , x 2 , x 3 ) = ( not x 1 or not x 2 or not x 3 )$$

Let us concentrate on the third variable, x3. If x3 is false, then there are four possible solutions of the boolean equation B(x1,x2,x3)=true, whereas if x3 is true, then there are only three solutions of the same boolean equations. In terms of our MASEC real machine processor computing solutions, this can be discovered by evaluating the integrals:

$${I}_{x 3 = f a l s e} = {\int }_{ε}^{1 - ε} {\int }_{ε}^{1 - ε} {\int }_{ε}^{2 ε} Log [ 1 - x 1 x 2 x 3 ] dx 1 dx 2 dx 3 - {\int }_{2 ε}^{1 - 2 ε} {\int }_{2 ε}^{1 - 2 ε} {\int }_{ε}^{2 ε} L o g [ 1 - x 1 x 2 x 3 ] dx 1 dx 2 dx 3 \\ And \\ {I}_{x 3 = t r u e} = {\int }_{ε}^{1 - ε} {\int }_{ε}^{1 - ε} {\int }_{1 - 2 ε}^{1 - ε} Log [ 1 - x 1 x 2 x 3 ] dx 1 dx 2 dx 3 - {\int }_{2 ε}^{1 - 2 ε} {\int }_{2 ε}^{1 - 2 ε} {\int }_{1 - 2 ε}^{1 - ε} Log [ 1 - x 1 x 2 x 3 ] dx 1 dx 2 dx 3$$

Several important points are observed in this 3SAT example:
1. The limits for variables—lower and upper bounds—are set to positive real values. In this way the MASEC complex logarithmic function can be evaluated with real arithmetic only.
2. The limits for the tested variable (x3 in this case) are set to [ε,2ε] if we test the hypothesis x3=false and [1−2ε,1−ε] if we test the hypothesis x3=true.
3. Since the integrals can be computed with any desired precision, we can select E as small as we desire,
4. Ideally, values for E should not be too small, to make sure that the PolyLog(2,x) and PolyLog(3,x) functions won't require too many iterations to converge to their true values with sufficient precision. In the next page polylogarithms are replaced by zeta constants.
   In the above case we selected ε=0.01. The evaluations of the integrals revealed:
Iₓ₃₌ₜᵢₘₑ=−0.00023619; I_{x3=false}=−0.000000681; the comparison between the two values showcases that x3 must be selected to be FALSE to increase the chance to find a true assignment for this single term 3SAT function. This agrees with the analysis in the beginning of this section.

### Computation of the Polylogarithmic Function Using MASEC Complex Logarithm Transformation

The polynomial integrals outlined previously require accurate (e.g., multi-precision) evaluation of the polylogarithmic function. Here there are several MASEC considerations we consider:
1. We evaluate only two polylogarithmic functions: PolyLog[2,x] and PolyLog[3,x];
2. This is very important—we need to evaluate these two functions for values of x that are very close to zero but positive and very close to one but less than one.
3. The evaluation of the PolyLog[3,x] is more complicated than the evaluation of PolyLog[2,x]. The mathematical identity given below removes all the polylogarithms.
4. The evaluations of these function at points very close to zero is MASEC efficient.
5. MASEC complex logarithms on a branched Riemann surface eliminates possible infinites.

Based on the earlier formulae, there are two MASEC identities for the polylogarithm functions:

$$PolyLog [ 2 , x ] + P o l y L o g [ 2 , 1 - x ] = Zeta [ 2 ] + Ln [ x ] Ln [ 1 - x ] \\ and \\ PolyLog [ 3 , x ] + PolyLog [ 3 , 1 - x ] + PolyLog [ 3 , x / ( 1 - x ) ] = Zeta [ 3 ] - 1 / 2 Ln [ x ] {Ln}^{2} [ 1 - x ] + Zeta [ 2 ] Ln [ 1 - x ] + 1 / 6 {Ln}^{3} [ 1 - x ]$$

One can observe that the MASEC computation of polylogarithmic functions is converted into the evaluations of logarithmic functions and Riemann zeta function. The analytical value of Zeta[2] is

$$\frac{{π}^{2}}{6}$$

and the value of Zeta[3] is known to many millions of bits of precision. Ergo, the computation of the polylogarithmic functions for MASEC real machine algorithms is computationally tractable.

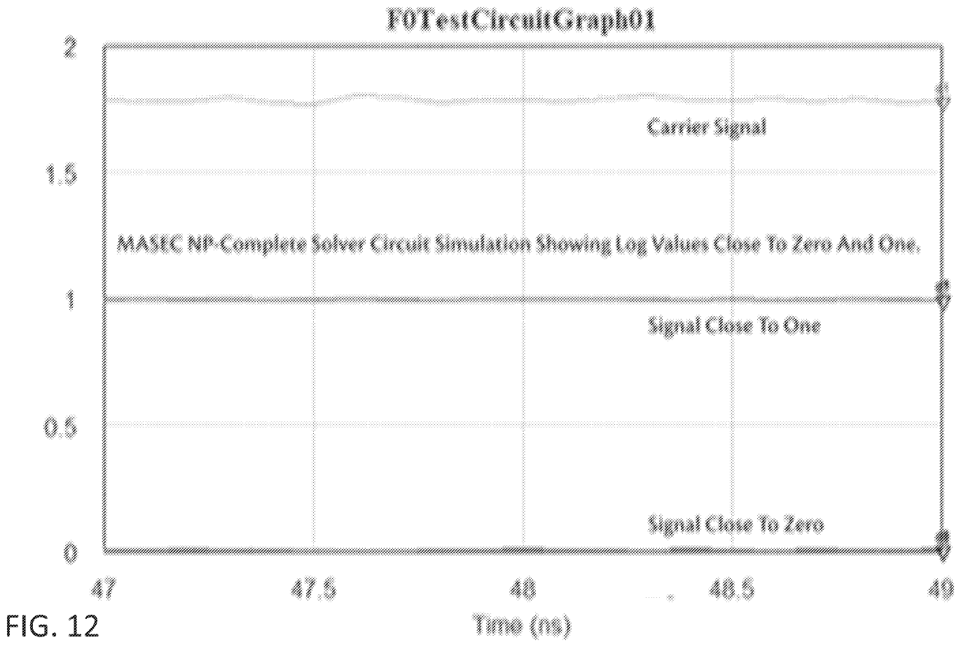

Thus, there is a linear-time conversion algorithm from ANY boolean satisfiability formula to a 3SAT formula, e.g., as shown in FIG. 12. This is the main reason why SAT hackathons are exclusively aimed at the 3SAT problem since an efficient algorithm for 3SAT leads to efficient algorithms for unrestricted SAT problems.

### Example: Integer Factorization And 3SAT Algorithm Preliminaries

The problem of factoring large composite numbers composed of two primes is a cornerstone of modern cryptanalysis and computational number theory. The security of the most widely used public key cryptosystem, RSA, crucially depends on the assumption that there exists no fast algorithm for factoring integers. In fact, many public key cryptosystems rely on the same assumption, such as Rabin's digital signature method and its variants, in the semantically secure public key encryption, the existentially unforgeable signature scheme. For this reason, many resources have been expended on the factorization problem. These efforts are both scientific and popular. In the past RSA Data Security offered several awards for factoring some specifically designed large composite numbers. Some of the most impressive results in factoring have made front page headlines. This makes sense, e.g., where Visa International uses RSA 1408-bit public keys (with expiration date Dec. 31, 2024—the value of the key is provided in hexadecimal format below) and 1536-bit public keys (with expiration date Dec. 31, 2030) to protect electronic payment transactions. Any breakthrough in this field would have tremendous consequences that would at a minimum result in a complete overhaul in cryptography standards and in the worst case could be used as a weapon for information warfare.

### VISA International Public Key (1408-Bit) in Hexadecimal Format:

D9 FD 6E D7 5D 51 D0 E3 06 64 BD 15 70 23 EA A1 FF A8 71 E4 DA 65 67 2B 86 3D 25 5E 81 E1 37 A5 1D E4 F7 2B CC 9E 44 AC E1 21 27 F8 7E 26 3D 3A F9 DD 9C F3 5C A4 A7 B0 1E 90 70 00 BA 85 D2 49 54 C2 FC A3 07 48 25 DD D4 C0 C8 F1 86 CB 02 0F 68 3E 02 F2 DE AD 39 69 13 3F 06 F7 84 51 66 AC EB 57 CA 0F C2 60 34 45 46 98 11 D2 93 BF EF BA FA B5 76 31 B3 DD 91 E7 96 BF 85 0A 2501 2F 1A E3 8F 05 AA 5C 4D 6D 03 B1 DC 2E 56 86 12 78 59 38 BB C9 B3 CD 3A 91 0C 1D A5 5A 5A 92 18 AC E0 F7 A2 12 87 75 26 82 F1 58 32 A6 78 D6 E1 ED 0B
   State of the Art Factoring Algorithms and their Complexities:

There are many classical and quantum algorithms for factoring integers. The Table below provides the main figures of merit; algorithms, their complexity and reference to analysis.

TABLE 1
Algorithms for factoring an integer number N and their complexity measures

| Algorithm for factoring an | | |
|---|---|---|
| integer number N | Complexity | Classical or quantum |
| Trial division [3] | 0(N^{0.5}) | Classical |
| Pollard rho [3] | 0(N^{0.25}) | Classical |
| Lenstra's elliptic curve | 0 (e^{(logN)}^{^{1/2}} ^{((log log N))}^{^{1/2}}) | Classical |
| factoring [4] | | |
| Generalized Number Field | 0 (e^{(1.9+ε)(logN)}^{^{1/3}} ^{((log log N))}^{^{2/3}}) | Classical |
| Sieve [3] | | |
| Shor's algorithm [2] | 0(log² N log log N log log log N) | Quantum |

The first two algorithms (trial division and Pollard rho) have exponential complexity. The thirdand fourth algorithms have sub-exponential complexity (that is, the complexity function grows faster than any polynomial but slower than any exponential). Shor's algorithm is the only one with provable (probabilistic) polynomial time complexity but can be implemented only on a largescale hypothetical quantum computer. It is estimated that approximately 2n-qubits are required to factor an n-bit RSA key.

In the general case, the best strategy is to try first trial division algorithm, then (if it fails in finding non-trivial prime factors) to switch to elliptic curve factorization technique (since its complexity
depends on the second largest prime factor of N) and only after that try the GNFS. For RSA keys, however, one can directly start with the GNFS.

There are various other techniques aimed at solving the same problem. It is possible to treat the problem as an optimization task over multidimensional polynomial functions of degree four. This approach has been used extensively by researchers and engineers at D-Wave Corporation. Whilst in the general form the problem is known to be NP-hard, nothing is known (in terms of their complexity classification) for the specific polynomials that must be optimized for this specific computational problem.

### Summarizing: The State of the Factoring Problem:

Given an integer number, N, that is a product of two primes, p and q, find p and q. We assume p and q to be positive integers and p>q.

### Examples

N=35, solution p=7, q=5;
N=323, solution p=19, q=17;
N=1098413, solution p=1951, q=563;

### N: 1911479277189866096892294666314546498129862462766673548641885036388072607034 3679905877620136513516127813425829612810920004670291298456875280033022177775 2773957404540495707851421041

### P: 4007800823297508779525813391041005725268293178158071765648821789984975727719 50624613470377

### Q: 4769396887386118369955354773570708579399020760277882320319897758246062255957 73435668861833

The number RSA-2048 is the largest number from the list of composites, suggested by RSALaboratories as challenges for factorization algorithms. It has 2048 bits in its binary number system representation and is a product of two unknown 1024-bit prime numbers.

RSA-2048 =
25195908475657893494027183240048398571
42928212620403202777713783604366202070
75955562640185258807844069182906412495
15082189298559149176184502808489120072
84499268739280728777673597141834727026
18963750149718246911650776133798590957
00097330459748808428401797429100642458
69181719511874612151517265463228221686
99875491824224336372590851418654620435
76798423387184774447920739934236584823
82428119816381501067481045166037730605
62016196762561338441436038339044149526
34432190114657544454178424020924616515
72335077870774981712577246796292638635
63732899121548314381678998850404453640
23527381951378636564391212010397122822
120720357

### General Description of the Factoring Algorithm:

1. consider the binary representation of p and q.

$$p = {\sum }_{i = 0}^{k - 1} {p}_{i} {2}^{i} \\ q = {\sum }_{i = 0}^{k - 1} {q}_{i} {2}^{i}$$

2. Break the symmetry by randomly guessing a few bits of p and q

Example: If N=391 (17*23), then we will try to successfully predict the bits of the two factors, p and q, by assuming that their binary representations look like this: p=(1 p3 p2 01)2 and q=(1 q3 q2 1 1)2. The ultimate solution will consist of determining that (p3 p2)=(0,0) and (q3 q2)=(0,1).
3. Consider the Boolean function H(p,q) that relates the bits of p and q with the bits of N. The process of this conversion can be explained as follows. The three major Boolean functions: AND, OR and NOT can be represented as polynomials by using the following substitution rules:

| Variable | Boolean function NOT | Polynomial equivalent |
|---|---|---|
| x | ¬x | f(x) = (1 − x) |

| Variables | Boolean function AND | Polynomial equivalent |
|---|---|---|
| x, y | x ∧ y | f(x, y) = xy |

| Variables | Boolean function OR | Polynomial equivalent |
|---|---|---|
| x, y | x ∨ y | f(x, y) = 1 − (1 − x)(1 − y) |

Example (cont.). Consider the following Boolean function:

$$f ( a , b , c , d ) = NOT [ ( a or b ) and ( not c or d ) ]$$

The function can be expressed by the following truth table: (Table 3)

| a | b | C | d | f(a, b, c, d) |
|---|---|---|---|---|
| 0 | 0 | 0 | 0 | 1 |
| 0 | 0 | 0 | 1 | 1 |
| 0 | 0 | 1 | 0 | 1 |
| 0 | 0 | 1 | 1 | 1 |
| 0 | 1 | 0 | 0 | 0 |
| 0 | 1 | 0 | 1 | 0 |
| 0 | 1 | 1 | 0 | 1 |
| 0 | 1 | 1 | 1 | 0 |
| 1 | 0 | 0 | 0 | 0 |
| 1 | 0 | 0 | 1 | 0 |
| 1 | 0 | 1 | 0 | 1 |
| 1 | 0 | 1 | 1 | 0 |
| 1 | 1 | 0 | 0 | 0 |
| 1 | 1 | 0 | 1 | 0 |
| 1 | 1 | 1 | 0 | 1 |
| 1 | 1 | 1 | 1 | 0 |

Based on the above rules for the conversion of the three basic Boolean functions (AND, OR and NOT), one can obtain the following algebraic equivalent (e.g., polynomial) of the function:

$$F ( a , b , c , d ) = 1 - a - b + a b + ( 1 - d ) ( a c + bc - abc )$$

Small factoring example: 143=11*13 (taken from B. Wang. F. Hu, H. Yao and C. Wang, Prime factorization algorithm based on parameter optimization of Ising model, Nature, 2020).

TABLE 4

| | 2⁷ | 2⁶ | 2⁵ | 2⁴ | 2³ | 2² | 2¹ | 2⁰ |
|---|---|---|---|---|---|---|---|---|
| p | | | | | 1 | p₂ | p₁ | 1 |
| q | | | | | 1 | q₂ | q₁ | 1 |
| | | | | | 1 | p₂ | p₁ | 1 |
| | | | | q₁ | p₂q₁ | p₁q₁ | q₂ | |
| | | | q₂ | p₂q₂ | p₁q₂ | q₂ | | |
| | | 1 | p₂ | p₁ | 1 | | | |
| carries | z₆₇ | z₅₆ | z₄₅ | z₃₄ | z₂₃ | z₁₂ | | |
| | z₅₇ | z₄₆ | z₃₅ | z₂₄ | | | | |
| p*q = 143 | 1 | 0 | 0 | 0 | 1 | 1 | 1 | 1 |

4. Perform arithmetization of the H(p,q) to obtain polynomial version of H(p,q) denote this HP(p,q). The example below showcases how this can be done.

### Example (Transformation of the Boolean Function into a Polynomial)

Consider the following Boolean function of four variables (Table 5):

| p₁ | p₂ | q₁ | q₂ | H(p₁, p₂, q₁, q₂) |
|---|---|---|---|---|
| 0 | 0 | 0 | 0 | 0 |
| 0 | 0 | 0 | 1 | 0 |
| 0 | 0 | 1 | 0 | 0 |
| 0 | 0 | 1 | 1 | 0 |
| 0 | 1 | 0 | 0 | 0 |
| 0 | 1 | 0 | 1 | 0 |
| 0 | 1 | 1 | 0 | 0 |
| 0 | 1 | 1 | 1 | 0 |
| 1 | 0 | 0 | 0 | 0 |
| 1 | 0 | 0 | 1 | 1 |
| 1 | 0 | 1 | 0 | 0 |
| 1 | 0 | 1 | 1 | 0 |
| 1 | 1 | 0 | 0 | 0 |
| 1 | 1 | 0 | 1 | 0 |
| 1 | 1 | 1 | 0 | 0 |
| 1 | 1 | 1 | 1 | 0 |

After the arithmetization of this Boolean function, one obtains the function:

$$HP ( p 1 , p 2 , q 1 , q 2 ) = p 1 ( 1 - p 2 ) ( 1 - q 1 ) q 2$$

There is only one combination of zeros and ones for which the value of this function is one. Now we:

Make an estimate for a particular bit of p (or q). The critical consideration is the following. We make a guess for a random bit (say, pi) of one of the two secret keys (the unknown prime factors). We use randomization to distinguish between the factorization of N as p*q from q*p. For all the remaining unknown bits (2k−1 in total), we apply the following idea: consider four 2 k−1-dimensional integrals defined like this. In the function to be integrated we firstly substitute pi with 1. We compute the two 2 k−1—dimensional integrals for our function; in the first case the limits are between −ε and 1+ε for the first integral and between +ε and 1−ε for the second one. In this way we simulate all passible combinations of the unknown bits. This is expressed symbolically in (1) and (2) at the beginning of the disclosure.

### Example: Real Memory—Matter Amplification for Stimulated Emission Memory (MASEM)

MASEC devices, computers, and/or circuits implement computer memories, which may obsolete transistor memory. Current silicon transistor-based memory is ubiquitous and highly optimized. Transistor-based memory comes in generally of the two forms of Static Random-Access Memory (SRAM), or Dynamic Random-Access Memory (DRAM). Fast and expensive SRAM memory is typically used for computer cache or fast temporary storage. Slower and inexpensive DRAM memory is used for bulk computer memory storage where binary computer software programs reside prior to and during program execution.

SRAM requires 6 transistors per unit cell to represent a single “bit” of computer storage. Since there are eight bits in a byte of storage, one Gigabyte (GB) of SRAM memory has 48 billion transistors, i.e., (6*8). The slower DRAM memory is implemented using a single transistor and a capacitor for a single bit of storage. The capacitor is charged or discharged to represent a 1 or a 0. Consequently, 1 GB of DRAM requires two devices, i.e., 8 billion transistors and 8 billion associated capacitors. Unlike the directly addressable SRAM, DRAM require a memory controller unit to manage access to DRAM computer memory storage. Both SRAM and DRAM typically store single bits of information. Flash memory stores information in an array of memory cells made from floating gate transistors. The resistance of the transistor is sensed to interpret the data stored. In traditional single-level-cell (SLC) devices, each cell stores only one bit whereas multilevel cell (MLC) Flash memory devices, can store more than one bit per cell by choosing between multiple levels of electrical charge to apply to the floating gates of its cells, and so are slower.

In comparison, MASEC memories are much more efficient than any form of transistor memory. MASEC memories always store real number values including single bits of data, so are far denser than any form of transistor memory. MASEC memories are fabricated using two terminal diode like structures with a cathode and anode. MASEC memories are arranged in arrays as shown in the image provided in FIG. 20. MASEC memories arranged as arrays are much simpler than transistor-based memory and have storage cycle times up to 3000 Gigahertz frequency. There is no MASEC feature size as with transistor-based memory since the spherical MASEC structure extends into the Z depth plane. Reducing MASEC physical size is through reducing the MASEC memory cathode/anode diameter. This leads to better MASEC scaling than with quantum limited transistor memories.

### Example: MASEC Prototypes, Applications, Challenges, Competition, And Scalability

A MASEC is a new semiconductor device used to implement real number computation and real number computer memory. Collectively both the MASEC processing element devices and MASEC memories are the fundamental building blocks of new real machine computer integrated circuits. MASEC product die is 10 um\hat{ }2, require 100 mW or less per circuit, and operate up to 3000 GHz.

### MASEC Prototypes

The four MASEC prototypes are scalable designs that characterize and validate four products. These scalable designs can include, but are not limited to, the MASEC 3SAT product, the associated MASEC discrete logarithm (DLOG) product, the HACM (Affective Neuron, or AN) neural network product, and the associated MASEC real memory (MASEM) product. These prototypes are now discussed below:

### MASEC 3SAT

The P versus NP problem is the major unsolved problem in computer science. It asks whether every problem whose solution is quickly verified can also be solved quickly. The informal term quickly, means the existence of an algorithm solving the task that runs in polynomial time, such that the time to complete the task varies as a polynomial function on the size of the input to the algorithm (as opposed to intractable exponential time). The general class of questions for which some algorithm can provide an answer in polynomial time is “P” or “class P”. Aside from being an extremely important problem in computational theory, a solution has profound implications for mathematics, cryptography (obsoleting many encryption algorithms), algorithm R&D, artificial intelligence, game theory, computer processing, life sciences, economics, and many other fields.

Regarding P versus NP, the 3SAT Boolean satisfiability problem is the problem of determining if there exists an interpretation that satisfies a given Boolean formula to be either true or false. 3SAT (SAT) was the first problem that was proven to NP-complete (using the Cook-Levin theorem, also known as Cook's theorem). Whereupon any NP-complete (NPC) problem can be reduced to the 3SAT Boolean satisfiability problem. NPC problem solutions are easily verified yet their solution is intractable as said. Current 3SAT-algorithms are solved using heuristic approximations, with the most challenging NPC algorithms in engineering, aerodynamics, life sciences and other fields remaining intractable. There is no polynomial time 3SAT closed form solution. The MASEC 3SAT algorithm is a scalable 3rd degree polynomial closed form NPC solution. The MASEC 3SAT solution executes in either quadratic or polynomial time irrespective of problem. The MASEC 3SAT polynomial time solution targets the most challenging NPC problems that are either difficult or impossible to solve with current heuristic digital solutions. The MASEC 3SAT solution is not competitive against small NPC problems that highly tuned heuristic solutions target efficiently.

### MASEC 3SAT Applications and Competition

NPC problems are generally optimization problems, and most hard optimization problems are NPC. Consequently, NPC problems are ubiquitous across industry and exist within all fields of study. Current heuristic solvers (generally referred to as SAT solvers) are used to solve NPC problems throughout industry. Heuristic SAT solvers are highly tuned to their respective applications and consequently are application “brittle.” Brittleness refers to the heuristic SAT solver not working well outside of its applications specific task, i.e., if the NPC problem changes the heuristic SAT solver must be re-tuned to provide acceptable results. Moreover, heuristic SAT solvers breakdown when the size of the NPC problem becomes extremely large. Consequently, the ACE 3SAT solution target should be NPC problems that are extremely large in scope. Unlike heuristic SAT solvers, the ACE 3SAT solution does not use heuristics and therefore is not brittle, which translates into broad NPC solutions across industry that perform in (polynomial) real-time.

### MASEC 3SAT Prototype Demonstration and Scalability

The ACE 3SAT MASEC solution scales as a third-degree polynomial, which means that it is a highly scalable and parallel solution. In mathematics, the degree of a polynomial is the highest of the degrees of the polynomial's individual terms within the polynomial, (i.e., the polynomials monomials) with non-zero coefficients. The degree of a term is the sum of the exponents of the variables that appear in it, and thus is a non-negative integer. The MASEC 3SAT prototype is a demonstration of the deterministic (non-heuristic) NPC solution, which validates functionality. The MASEC 3SAT prototype electrical engineering design scales architecturally as a function of the target NPC application. It is either a building block Monolithic Microwave Integrated Circuit (MMIC) functional co-processor component, or the design basis for a complete NPC processor. The MASEC 3SAT prototype device die size is between 10-50 microns in size, implements four NPC parallel processors, and runs at a test frequency of 5 Gigahertz to keep test equipment and packaging costs down. Much higher frequencies up to 3000 Gigahertz are possible, but require optical circuit interfaces, custom packaging, and 1.75-million-dollar specialized test equipment.

No digital to analog or analog to digital interfacing is required for the 3SAT MASEC solution. The circuit interfaces are binary digit values mapped to 3SAT MASEC circuit voltage and current levels,
e.g., a binary digit 1 mapped to a high voltage input or a high current output from the circuit, and a binary digit 0 mapped to a low voltage input or a low current output from circuit, respectively.

### MASEC DLOG and PLOG

The MASEC DLOG prototype is instantaneous O(1) time calculation of the discrete logarithm. In
mathematics, for given real numbers a and b, the logarithm log b a is a number x such that bx=a. Analogously, in any group G, powers bk can be defined for all integers k, and the discrete logarithm log b a is an integer k such that bk=a. No efficient method is known for computing them in general. Several important algorithms in public-key cryptography base their security on the assumption that the discrete logarithm problem over carefully chosen groups has no efficient solution. This includes the Monero cryptocurrency privacy token, preferred for illegal activities.

The MASEC DLOG prototype validates that a single MASEC implements complex mathematical functions that require tens of thousands of transistors using digital transistor methods. MASEC devices, computers, and/or circuits that implement other complex functions include MASEC PLOG, which implements mathematical polylogarithm functions. In mathematics, the polylogarithm (also known as Jonquiere's function) is a special function Lis(z) of order s and argument z. The polylogarithm function is defined by computationally expensive power series in z. The function has diverse application in quantum statistics, where the polylogarithm function appears as the closed form of integrals of the Fermi-Dirac distribution and the Bose-Einstein distribution, (also known as the Fermi-Dirac integral or the Bose-Einstein integral). In quantum electrodynamics, polylogarithms of positive integer order arise in the calculation of processes represented by higher order Feynman diagrams. The function corresponds to non-trivial algebraic cycles, which leads to interactions between the analytical properties of functions, arithmetics of special values, and algebraic geometry (space exploration).

The MASEC DLOG and PLOG validate that a single MASEC implements complex mathematical functions that currently require tens of thousands to billions of transistors using digital devices. The MASEC DLOG/PLOG function in constant time O(1) and at up to 3000 Gigahertz frequency.

Currently available Digital to Analog and Analog to Digital converters (i.e., DAC and ADC) are limited in resolution (24 bits) and frequency response (5 Gsps). The challenge is that higher resolution and frequency performing DAC and ADC devices are required to take full advantage of the MASEC DLOG or PLOG devices. There is no inherent theoretical limitation to development of higher resolution DAC and ADC devices. In signal processing, the Nyquist rate, specifies the design requirements for higher resolution and performance DAC and ADC devices. Current market needs constrain current DAC/ADC offerings. ACE intends to develop high resolution (80 bits) and high performance (up to 3000 Gigahertz) MASEC device integral DAC and ADC circuitry. This decouples the ACE mathematical computing MASEC offerings from rate limiting commercially available DAC and ADC limitations. The MASEC DLOG and PLOG products are the first of ACE MASEC mathematical computing offerings, which are productized as discrete co-processors for broad applications in mathematical computing.

### MASEC DLOG and PLOG Applications and Competition

MASEC devices, computers, and/or circuits implementing DLOG and PLOG obsolete all current digital calculations implementing discrete logarithms and polylogarithm functions for applications in mathematical computing. The MASEC DLOG/PLOG offerings are the first of many new mathematical computing co-processors with wide ranging applications to all industries. ACE plans a family of MASEC co-processors implementing complex mathematical functions, which obsolete current digital implementations.

### MASEC DLOG and PLOG Prototype Demonstration and Scalability

The MASEC DLOG/PLOG prototypes validate functionality using current DAC and ADC devices. Scalability is related to resolution and performance requirements that are constrained by DAC and ADC devices currently commercially available. Notwithstanding, the DLOG/PLOG prototypes using DAC/ADC limited resolution and performance devices surpass all current digital technology. Growth in the DLOG/PLOG and generally ACE MASEC co-processor product offerings is in offering mathematical co-processor solutions at much higher DAC/ADC resolution/frequency response.

### MASEC HACM (Affective Neuron)

MASEC HACM Affective Neuron (AN) is an unbiased AI technology that learns using machine intuition. Like neurons in the visual cortex, MASEC ANs learn entire memories without training. Unlike current machine learning (ML) technologies, MASEC ANs learn highly complex memories in real-time without training. MASEC ANs reproduce the biological emotions and stress responses, mimicking the host. Unlike artificial neural networks (ANNs) where the intelligence resides in the network connection weights, MASEC AN intelligence resides within the individual MASEC AN self-organizing neuron. MASEC ANs feature integral transfer learning where the AN is initialized using data from other MASEC ANs or imprinted using biological EEG and/or MRI data. MASEC ANs continuously evolve and self-organize in real-time with other MASEC AN or conventional deep neural network technologies. MASEC AN feature wireless on chip networks whose connections evolve continually based upon their environmental inputs and interactions.

### MASEC HACM (Affective Neuron) Applications and Competition

MASEC ANs eliminate mathematical operations so may fully obsolete current neural networks.

### MASEC Real Memory (MASEM)

MASEC devices, computers, and/or circuits of the invention implement computer memories, which may obsolete transistor memory. Current silicon transistor-based memory is ubiquitous and highly optimized. Transistor-based memory comes in generally of the two forms of Static Random-Access Memory (SRAM), or Dynamic Random-Access Memory (DRAM). Fast and expensive SRAM memory is typically used for computer cache or fast temporary storage. Slower and inexpensive DRAM memory is used for bulk computer memory storage where binary computer software programs reside prior to and during program execution. SRAM requires, e.g., 6 transistors per unit cell to represent a single “bit” of computer storage. Since there are eight bits in a byte of storage, one Gigabyte (GB) of SRAM memory has 48 billion transistors, i.e., (6*8). The slower DRAM memory is implemented using a single transistor and a capacitor for a single bit of storage. The capacitor is charged or discharged to represent a 1 or a 0. Consequently, 1 GB of DRAM requires two devices, i.e., 8 billion transistors and 8 billion associated capacitors. Unlike the directly addressable SRAM, DRAM require a memory controller unit to manage access to DRAM computer memory storage. Both SRAM and DRAM typically store single bits of information. Flash memory stores information in an array of memory cells made from floating gate transistors. The resistance of the transistor is sensed to interpret the data stored. In traditional single-level-cell (SLC) devices, each cell stores only one bit whereas multilevel cell (MLC) Flash memory devices, can store more than one bit per cell by choosing between multiple levels of electrical charge to apply to the floating gates of its cells, and so are slower.

In comparison, MASEC memories (MASEM), which can be provided in MASEC devices, computers, and/or circuits of the invention, are much more efficient than transistor memory. MASEC memories always store real number values including single bits of data, so are far denser than any form of transistor memory. MASEC memories are fabricated using two terminal diode like structures with a cathode and anode. MASEC memories are arranged in rectangular arrays. MASEC memories arranged as arrays are much simpler than transistor-based memory and have storage cycle times up to 3000 Gigahertz frequency. There is no MASEM feature size as with transistor-based memory since the spherical MASEC memory structure extends into the Z depth plane. Reducing MASEM physical size is through reducing the MASEC memory cathode/anode diameter. This leads to superior MASEM scaling than with quantum limited transistor memories.

### MASEC Real Memory (MASEM) Applications and Competition

A MASEM central application, that can be used in MASEC devices, computers, and/or circuits of the invention, is in the design and development of the MASEC real machine computational processors, which require real number storage, retrieval, and extremely high performance. MASEMs have secondary application competing with digital single and multi-value logic memory. MASEMs are superior to transistor memory via a much higher frequency response.

### MASEC Real Memory (MASEM) Prototype Demonstration and Scalability

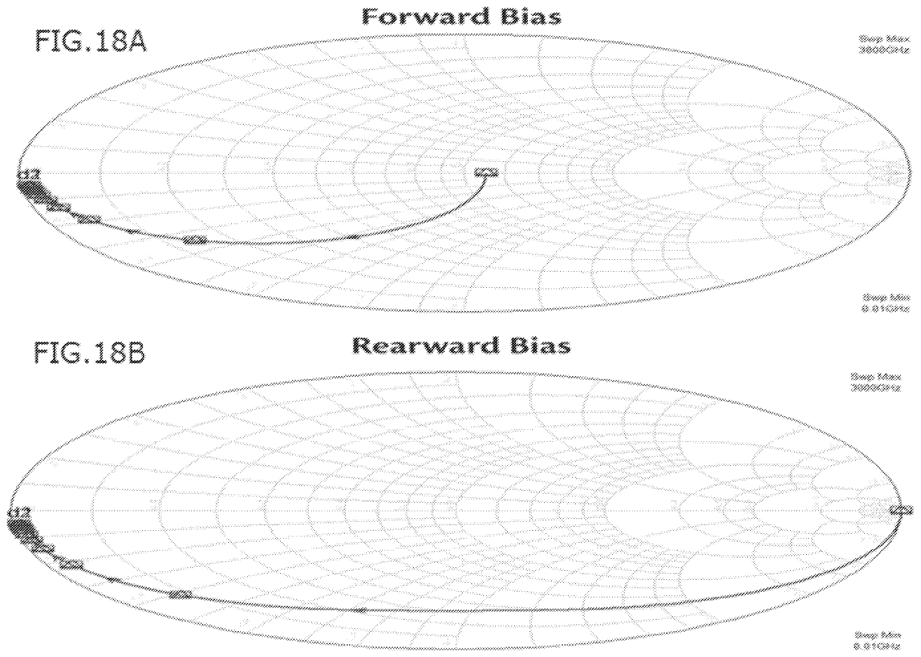

MASEC devices, computers, and/or circuits of the invention can include one or more aspects of a fully scalable MASEM prototype that demonstrates storing and retrieving real number values. The MASEM technology of the invention can be used within one or more same or different MASEC processor prototypes to manipulate real machine values both for short- and long-term storage of results. MASEM memory elements can be integral to MASEC HACM neuron centric machine learning device disclosed herein. Specifically, the HACM neuron implemented using one MASEM per neuron provides extremely high operational frequencies extending up and beyond 3000 Gigahertz (e.g., but not limited to, 100-500, 500-1000, 740-1250, 1500-2500, 1000-3000, 1500-4000, 3000-5000, 4000-6000, 5000-7000, 6000-8000, 7000-9000, 8000-10,000 Gigahertz, or any range, combination, or value therein) using InGaAs process MASEM devices. The Smith charts as FIG. 18A-18B validate the HACM neuron characterized frequencies. This ultraperformance and the total lack of arithmetic operations show the HACM AN is a synthetic neuron.

### Example: MASEC SAT Analytical Solver—Digital Circuit Verification and Bitcoin Mining

A Bitcoin mining program that can be used with or in MASEC devices, computers, and/or circuits of the invention essentially performs the following (in pseudo-code):
While (nonce<MAX): if sha (sha(block+nonce))<target:retum nonce nonce+=1

The task is to find a nonce which, as part of the bitcoin block header, hashes below a certain value. This is a brute force approach to something-like-a preimage attack on SHA256. The process of mining consists of finding an input to a cryptographic hash function which hashes below or equal to a fixed target value. It is brute force because at every iteration the content to be hashed is slightly changed in the hope to find a valid hash; there's no smart choice in the nonce. The choice using any known methods or algorithms is essentially a random guess as this is the best possible approach with such hash functions using known methods. Using MASEC real machine 3SAT technology of the invention a new and non-obvious Bitcoin miner can be provided that deterministically solves for the nonce and thereby eliminating power expensive, current, brute force, Bitcoin mining. In the past this approach was explored by several researchers, however using previously known digital technology to implement the SAT Bitcoin miner is impractical. However, using MASEC devices, computers, and/or circuits of the invention, this can be provided.

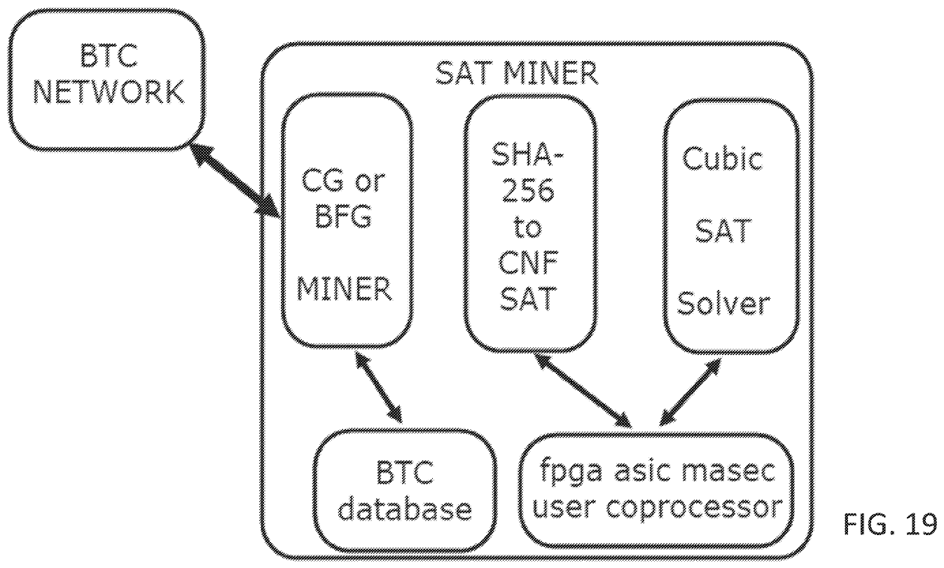

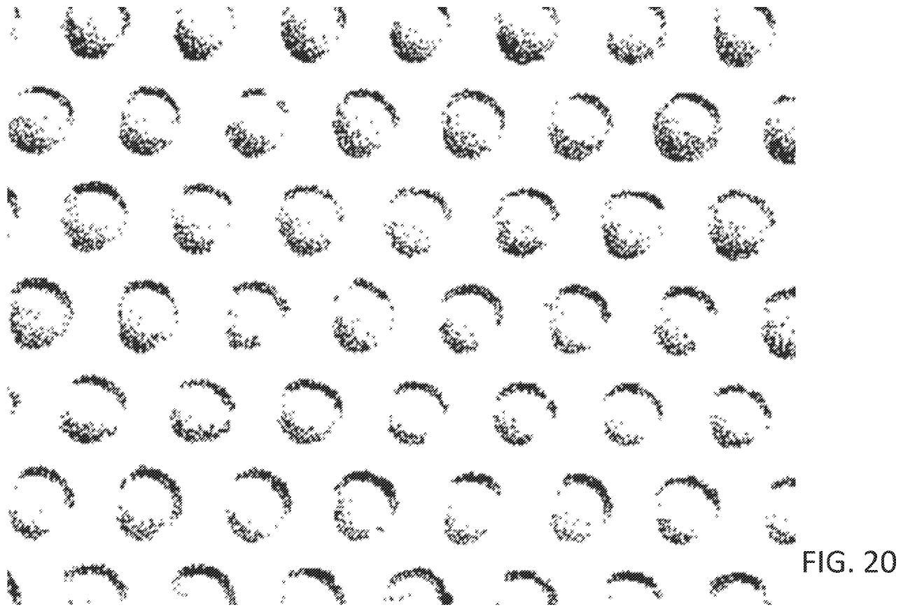

The miner block diagram illustrating the dataflow is shown in FIG. 19 (SAT MINER). In the MASEC SAT Bitcoin miner approach of the invention, solving for the nonce is through a Boolean SAT equation, which has a solution. This is in stark contrast to the current brute force approach, which is energy wasteful guessing. The resulting MASEC SAT miner would solve for the nonce more rapidly and require a fraction of the electrical power of current Bitcoin miners. Referring to the block diagram FIG. 19, in the MASEC SAT approach, SHA256 is converted to Conjunctive Normal Form (CNF) before presentation to the MASEC SAT solver. In Boolean logic, a formula is in CNF (or clausal normal form) if it is a conjunction of one or more clauses, where a clause is a disjunction of literals; otherwise put, it is a product of sums or an AND of ORs suitable for input for the MASEC 3SAT algorithm described in the main section of this document. More generally, as a canonical normal form, this is useful in automated theorem proving and specifically digital circuit verification.

Once SHA256 is converted to CNF the MASEC SAT solver in the miner block diagram FIG. 19 makes a guess for a particular input bit of the SHA256 input value. The remaining bits can be shuffled by making use of the multidimensional integration outlined in the main section of this disclosure. Since the bit guessed can be 0 and 1, then by comparing ONLY THE LINEAR components of the functions H0(ε) and H1(ε) the miner can select the value of the bits based on this comparison: the one that corresponds to the higher slope offers the miner a faster option to solve the cryptographic puzzle, therefore, leading to a high probability of winning the Bitcoin mining race.

Here we provide a simplified version of the Boolean functions that must be evaluated for a successful solution of the SHA256 cryptographic puzzle. SHA256 is a modified version of the MD5 hash algorithm proposed by Rivest in 1995. Since we plan to convert the problem into a Boolean satisfiability problem and apply the 3SAT technology outlined in the above sections, we will provide information about the number of variables and the number of clauses in both problems:

| Algorithm | | Mironov-Zhang | Legendre et al. |
|---|---|---|---|
| MD4 | variables | 53228 | 19363 |
| | clauses | 221440 | 184689 |
| MD5 | variables | 89748 | 35477 |
| | clauses | 375176 | 304728 |

The table above illustrates the number of variables and the number of clauses necessary to encode two hash functions (closest to SHA256) as a SAT problem. Corresponding to the SAT miner block diagram, the main computational blocks in the case of the MD5/SHA256 algorithms that we must implement with MASEC devices, computers, and/or circuits are:

| | |
|---|---|
| F(B, C, D) | (B and C) or (¬B and D) |
| G(B, C, D) | (B and D) or (C and ¬D) |
| H(B, C, D) | B xor C xor D |
| I(B, C, D) | C xor (B and ¬D) |

In the real SHA256 implementations, the variables B, C and D are 32-bit variables, and the Boolean operations are implemented on bit-wise manner. In our first simulations, we provide implementations based on shorter (1-8-bit variables), and we will determine the bits of these variables that satisfy the conditions of the “crypto-puzzle.” In the case of bitcoin mining, we require a specific number (based on the complexity level of the puzzle) of the most significant bits of the output to be zeros. The CNF representation of SHA256 corresponds to the following:

### SHA256 Implementation for Bitcoin Mining

1: All variables are 32-bit unsigned integers and addition is calculated modulo 232;
2: For each round, there is one round constant k[i] and one entry in the message schedule array w[i], 0≤i≤63;
3: The compression function uses 8 working variables, a through h;
4: Big-endian convention is used when expressing the constants in this pseudocode, and when parsing message block data from bytes to words, for example, the first word of the input message “abc” after padding is 0x61626380

Initialize hash values: (First 32 bits of the fractional parts of the square roots of the first 8 primes 2 . . . 19):

$$h 0 := 0 x 6 a 09 e 667$$

$$h 1 := 0 x bb 67 ae 85$$

$$h 2 := 0 x 3 c 6 ef 372$$

$$h 3 := 0 xa 54 ff 53 a$$

$$h 4 := 0 x 510 e 527 f$$

$$h 5 := 0 x 9 b 05688 c$$

$$h 6 := 0 x 1 f 83 d 9 ab$$

$$h 7 := 0 x 5 be 0 cd 19$$

Initialize array of round constants: (first 32 bits of the fractional parts of the cube roots of the first 64 primes 2 . . . 311):

$$k [ 0 … 63 ] := 0 x 428 a 2 f 98 , 0 x 71374491 , 0 x b 5 c 0 fbcf , 0 xe 9 b 5 dba 5 , 0 x 3956 c 25 b , 0 x 59 f 111 f 1 , 0 x 923 f 82 a 4 , 0 xab 1 c 5 ed 5 , 0 xd 807 aa 98 , 0 x 12835 b 01 , 0 x 243185 be , 0 x 550 c 7 d c 3 , 0 x 72 be 5 d 74 , 0 x 80 deb 1 fe , 0 x 9 bdc 06 a 7 , 0 xc19bf 174 , 0 xe 49 b 69 c 1 , 0 xefbe 4786 , 0 x 0 fc 19 dc 6 , 0 x 240 ca 1 cc , 0 x 2 de 92 c 6 f , 0 x 4 a 7484 aa , 0 x 5 cb 0 a 9 dc , 0 x 76 f 988 da , 0 x 983 e 5152 , 0 xa 831 c 66 d , 0 xb 00327 c 8 , 0 xbf 597 fc 7 , 0 xc 6 e 00 bf 3 , 0 xd 5 a 79147 , 0 x 06 ca 6351 , 0 x 14292967 , 0 x 27 b 70 a 85 , 0 x 2 e 1 b 2138 , 0 x 4 d 2 c 6 dfc , 0 x 53380 d 13 , 0 x 650 \; 1 \; 7354 , 0 x 766 a 0 abb , 0 x 81 c 2 c 92 e , 0 x 92722 c 85 , 0 xa 2 bfe 8 a 1 , 0 xa 81 \; 1 \; 664 b , 0 xc 24 b 8 b 70 , 0 xc76 c 51 a 3 , 0 xd 192 e 819 , 0 xd 6990624 , 0 xf 40 e 3585 , 0 x 106 aa 070 , 0 x 19 a 4 c 116 , 0 x 1 e 376 c 08 , 0 x 2748774 c , 0 x 34 b 0 bcb 5 , 0 x 391 c 0 cb 3 , 0 x 4 ed 8 aa 4 a , 0 x 5 b 9 cca 4 f , 0 x 682 e 6 ff 3 , 0 x 748 f 82 ee , 0 x 78 a 5636 f , 0 x 84 c 87814 , 0 x 8 cc 70208 , 0 x 90 befffa , 0 xa 4506 ceb , 0 xbef 9 a 3 f7 , 0 xc 67178 f 2$$

Pre-processing (Padding):
begin with the original message of length L bits;
append a single ‘1’ bit;
append K ‘0’ bits, where K is the minimum number >=0 such that L+1+K+64 is a multiple of 512; and
append L as a 64-bit big-endian integer, making the total postprocessed length a multiple of 512 bits.

Process the message in successive 512-bit chunks:
break message into 512-bit chunks for each chunk create a 64-entry message schedule array w[0 . . . 63] of 32-bit words (The initial values in w[0 . . . 63] don't matter, so many implementations zero them here);
copy chunk into first 16 words w[0 . . . 15] of the message schedule array

Extend the first 16 words into the remaining 48 words w[16 . . . 63] of the message schedule array:
for i from 16 to 63

$$s 0 := ( w [ i - 15 ] rightrotate 7 ) xor ( w [ i - 15 ] rightrotate 18 ) xor ( w [ i - 15 ] rightshift 3 )$$

$$s 1 := ( w [ i - 2 ] rightrotate 17 ) xor ( w [ i - 2 ] rightrotate 19 ) xor ( w [ i - 2 ] rightshift 10 )$$

$$w [ i ] := w [ i - 16 ] + s 0 + w [ i - 7 ] + s 1$$

### Initialize Working Variables to Current Hash Value:

$$a := h 0$$

$$b := h 1$$

$$c := h 2$$

$$d := h 3$$

$$e := h 4$$

$$f := h 5$$

$$g := h 6$$

$$h := h 7$$

Compression function main loop:

$$for i from 0 to 63$$

$$S 1 := ( e rightrotate 6 ) xor ( e rightrotate 11 ) xor ( e rightrotate 25 )$$

$$ch := ( e and f ) xor ( ( not e ) and g )$$

$$temp 1 := h + S 1 + ch + k [ i ] + w [ i ]$$

$$S 0 := ( a rightrotate 2 ) xor ( a rightrotate 13 ) xor ( a rightrotate 22 )$$

$$maj := ( a and b ) xor ( a and c ) xor ( b and c ) temp 2 := S 0 + maj$$

$$h := g$$

$$g := f$$

$$f := e$$

$$e := d + temp 1$$

$$d := c$$

$$c := b$$

$$b := a$$

$$a := temp 1 + temp 2$$

### Add the Compressed Chunk to the Current Hash Value:

$$h 0 : = h 0 + a$$

$$h 1 : = h 1 + b$$

$$h 2 := h 2 + c$$

$$h 3 : = h 3 + d$$

$$h 4 : = h 4 + e$$

$$h 5 : = h 5 + f$$

$$h 6 := h 6 + g$$

$$h 7 : = h 7 + h$$

### Produce the Final Hash Value (Big-Endian):

$$digest := hash := h 0 append$$

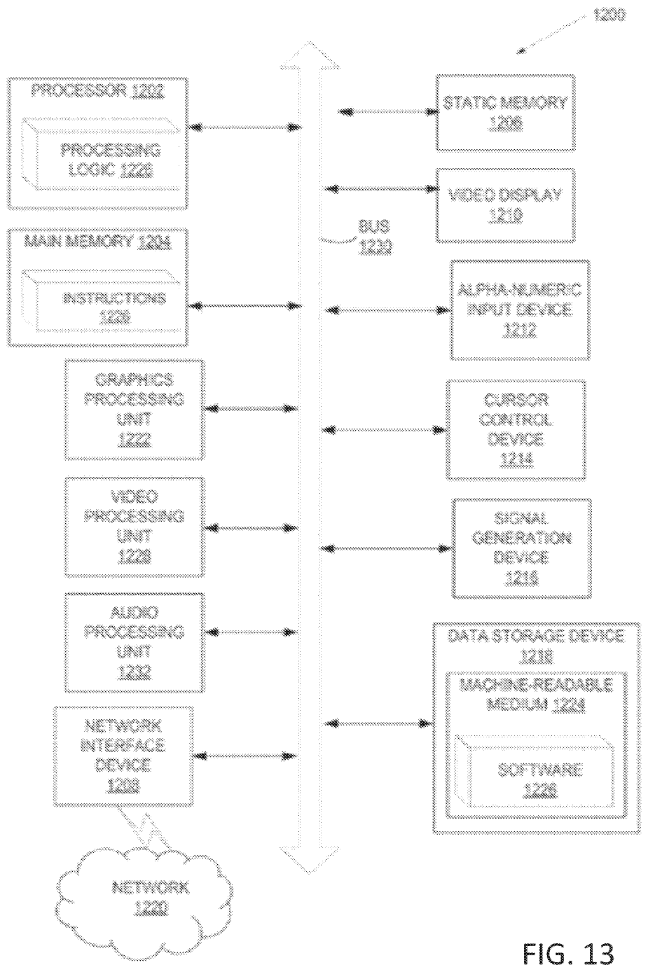

FIG. 13 illustrates a diagrammatic representation of a machine in the example form of a computer system 1200 within which a set of instructions, for causing the machine to perform any one or more of the methodologies discussed herein, may be executed. In alternative embodiments, the machine may be connected (e.g., networked) to other machines in a LAN, an intranet, an extranet, or the Internet. The machine may operate in the capacity of a server or a client device in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The computer system 1200 includes a processing device 1202, a main memory 1204 (e.g., read-only memory (ROM), flash memory, dynamic random access memory (DRAM) (such as synchronous DRAM (SDRAM) or DRAM (RDRAM), etc.), a static memory 1206 (e.g., flash memory, static random access memory (SRAM), etc.), and a data storage device 1218, which communicate with each other via a bus 1230.

Processing device 1202 represents one or more general-purpose processing devices such as a microprocessor, central processing unit, or the like. More particularly, the processing device may be complex instruction set computing (CISC) microprocessor, reduced instruction set computer (RISC) microprocessor, very long instruction word (VLIW) microprocessor, or processor implementing other instruction sets, or processors implementing a combination of instruction sets. Processing device 1202 may also be one or more special-purpose processing devices such as an application specific integrated circuit (ASIC), a field programmable gate array (FPGA), a digital signal processor (DSP), network processor, or the like. In one embodiment, processing device 1202 may include one or processing cores. The processing device 1202 is configured to execute the processing logic 1226 for performing the operations and steps discussed herein. In one embodiment, processing device 1202 is the same as processor architecture 100 described with respect to FIG. 1 as described herein with embodiments of the disclosure.

The computer system 1200 may further include a network interface device 1208 communicably coupled to a network 1220. The computer system 1200 also may include a video display unit 1210 (e.g., a liquid crystal display (LCD) or a cathode ray tube (CRT)), an alphanumeric input device 1212 (e.g., a keyboard), a cursor control device 1214 (e.g., a mouse), and a signal generation device 1216 (e.g., a speaker). Furthermore, computer system 1200 may include a graphics processing unit 1222, a video processing unit 1228, and an audio processing unit 1232.

The data storage device 1218 may include a machine-accessible storage medium 1224 on which is stored software 1226 implementing any one or more of the methodologies of functions described herein, such as implementing store address prediction for memory disambiguation as described above. The software 1226 may also reside, completely or at least partially, within the main memory 1204 as instructions 1226 and/or within the processing device 1202 as processing logic 1226 during execution thereof by the computer system 1200; the main memory 1204 and the processing device 1202 also constituting machine-accessible storage media.

The machine-readable storage medium 1224 may also be used to store instructions 1226 implementing store address prediction for hybrid cores such as described according to embodiments of the disclosure. While the machine-accessible storage medium 1128 is shown in an example embodiment to be a single medium, the term “machine-accessible storage medium” should be taken to include a single medium or multiple media (e.g., a centralized or distributed database, and/or associated caches and servers) that store the one or more sets of instructions. The term “machine-accessible storage medium” shall also be taken to include any medium that is capable of storing, encoding or carrying a set of instruction for execution by the machine and that cause the machine to perform any one or more of the methodologies of the present disclosure. The term “machine-accessible storage medium” shall accordingly be taken to include, but not be limited to, solid-state memories, and optical and magnetic media.

While the disclosure has been described with respect to a limited number of embodiments, those skilled in the art will appreciate numerous modifications and variations there from. It is intended that the appended claims cover all such modifications and variations as fall within the true spirit and scope of this disclosure.

A design may go through various stages, from creation to simulation to fabrication. Data representing a design may represent the design in a number of manners. First, as is useful in simulations, the hardware may be represented using a hardware description language or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable medium, at least temporarily, an article, such as information encoded into a carrier wave, embodying techniques of embodiments of the present disclosure.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Use of the phrase ‘configured to,’ in one embodiment, refers to arranging, putting together, manufacturing, offering to sell, importing and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘to,’ ‘capable of/to,’ and or ‘operable to,’ in one embodiment, refers to some apparatus, logic, hardware, and/or element designed in such a way to enable use of the apparatus, logic, hardware, and/or element in a specified manner. Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example the decimal number ten may also be represented as a binary value of 910 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, i.e. reset, while an updated value potentially includes a low logical value, i.e. set. Note that any combination of values may be utilized to represent any number of states.

The embodiments of methods, hardware, software, firmware or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash memory devices; electrical storage devices; optical storage devices; acoustical storage devices; other form of storage devices for holding information received from transitory (propagated) signals (e.g., carrier waves, infrared signals, digital signals); etc., which are to be distinguished from the non-transitory mediums that may receive information there from.

Instructions used to program logic to perform embodiments of the disclosure may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the computer-readable medium includes any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment and other exemplarily language does not necessarily refer to the same embodiment or the same example, but may refer to different and distinct embodiments, as well as potentially the same embodiment.

What is claimed is:

1. An electronic computer processing system comprising:
at least one semiconductor device configured for real number or complex number computations and comprising at least one III-V Monolithic Microwave Integrated Circuit (MMIC) that is configured to perform matter amplification by stimulated emission computations (MASEC) configured to provide real number and complex number computations;
wherein the at least one MMIC comprises direct/zero band-gap semiconductor materials and two or more diode types selected from a semi-conductor diode configured for MASEC; and a semiconductor HBT-diode configured for MASEC;
wherein one or more diode MASEC diode memories are configured to store real number values including single bits of data and include at least two terminal diode structures with a cathode and anode that are arranged in arrays having storage cycle times up to 3000 Gigahertz with a spherical structure extending into a Z depth plane having reduced size as compared to transistor size by having reduced MASEC diode memory cathode/anode diameter;
wherein the MMIC is configured to:
provide real number or complex number computations;
operate in at least one frequency between 50 gigahertz and 1000 gigahertz;
emit real and complex number computations using calculations incorporating stimulated emission of electromagnetic radiation;
provide complex logarithm computations O(1) applied to translating 3SAT into the continuous domain converting a multi-dimensional integration for at least 100-1000 continuous variables;
perform an NP-complete deterministic polynomial time algorithm according to the following Formula (I) using the steps of four of more of: (1) convert an original Boolcan formula to polynomial; (2) select bit to be determined; (3) evaluate the integrals as provided above; (4) repeat steps (1) to (3) for all remaining bits of the original Boolean formula; and (5) based on the outcome of the previous calculation(s), choose/select/incorporate an i-th bit:
$${\sum }_{{i}_{1} = 0}^{1} {\sum }_{{i}_{2} = 0}^{1} {\sum }_{{i}_{3} = 0}^{1} … {\sum }_{{i}_{\text{?}} = 0}^{1} H ( {p}_{0} , … , {q}_{k - 1} ) {\to }_{transform ( discrete to continuous )} {\int }_{- ε}^{1 + ε} … {\int }_{- ε}^{1 + ε} HP ( {p}_{0} , … , {p}_{i - 2} , 1 , {p}_{i + 1} , … , {p}_{k - 1} , {q}_{0} , … , {q}_{k - 1} ) {dp}_{0} … {dq}_{k - 1} - {\int }_{ε}^{1 - ε} … {\int }_{ε}^{1 - ε} HP ( {p}_{0} , … , {p}_{i - 1} , 1 , {p}_{i + 1} , … , {p}_{k - 1} , {q}_{0} , … , {q}_{k - 1} ) {dp}_{0} … {dq}_{k - 1} \qquad Formula ( I )$$
$${\sum }_{{i}_{1} = 0}^{1} {\sum }_{{i}_{2} = 0}^{1} {\sum }_{{i}_{3} = 0}^{1} … {\sum }_{{i}_{\text{?}} = 0}^{1} H ( {p}_{0} , … , {q}_{k - 1} ) {\to }_{transform ( discrete to continuous )} {\int }_{ε}^{1 + ε} … {\int }_{- ε}^{1 + ε} HP ( {p}_{0} , … , {p}_{i - 1} , 0 , {p}_{i + 1} , … , {p}_{k - 1} , {q}_{0} , … , {q}_{k - 1} ) {dp}_{0} … {dq}_{k - 1} - {\int }_{ε}^{1 - ε} … {\int }_{ε}^{1 - ε} HP ( {p}_{0} , … , {p}_{i - 1} , 0 , {p}_{i + 1} , … , {p}_{k - 1} , {q}_{0} , … , {q}_{k - 1} ) {dp}_{0} … {dq}_{k - 1}$$
$$\text{?} \text{indicates text missing or illegible when filed}$$
wherein the calculation of the integrals on the right-hand side of Formula I is calculated in succession for each variable by transforming the summation into two integral evaluations where one of the two integral evaluations results is a larger (as a function of e) value demonstrated by at least one or two variables including using pᵢ and at least two possible conjectures for pᵢ and with the following four integrals according to Formula (II):
$${I}_{1}^{( + )} = {\int }_{- ε}^{1 + ε} {\int }_{- ε}^{1 + ε} {\int }_{- ε}^{1 + ε} … {\int }_{- ε}^{1 + ε} HP ( {p}_{0} , {p}_{1} , … , {p}_{i - 1} , 1 , {p}_{i + 1} , … , {p}_{k - 1} , {q}_{0} , {q}_{1} , … , {q}_{k - 1} ) {dp}_{0} … {dq}_{k - 1} \qquad Formula ( II )$$
$${I}_{1}^{( - )} = {\int }_{ε}^{1 - ε} {\int }_{ε}^{1 - ε} {\int }_{ε}^{1 - ε} … {\int }_{ε}^{1 - ε} HP ( {p}_{0} , {p}_{1} , … , {p}_{i - 1} , 1 , {p}_{i + 1} , … , {p}_{k - 1} , {q}_{0} , {q}_{1} , … , {q}_{k - 1} ) {dp}_{0} … {dq}_{k - 1}$$
$${I}_{0}^{( + )} = {\int }_{- ε}^{1 + ε} {\int }_{- ε}^{1 + ε} {\int }_{- ε}^{1 + ε} … {\int }_{- ε}^{1 + ε} HP ( {p}_{0} , {p}_{1} , … , {p}_{i - 1} , 0 , {p}_{i + 1} , … , {p}_{k - 1} , {q}_{0} , {q}_{1} , … , {q}_{k - 1} ) {dp}_{0} … {dq}_{k - 1}$$
$${I}_{0}^{( - )} = {\int }_{ε}^{1 - ε} {\int }_{ε}^{1 - ε} {\int }_{ε}^{1 - ε} … {\int }_{ε}^{1 - ε} HP ( {p}_{0} , {p}_{1} , … , {p}_{i - 1} , 0 , {p}_{i + 1} , … , {p}_{k - 1} , {q}_{0} , {q}_{1} , … , {q}_{k - 1} ) {dp}_{0} … {dq}_{k - 1}$$
wherein the two limits are compared such that:
$${Y}_{1} = {lim}_{ε \to 0} {I}_{1}^{( + )} - {I}_{1}^{( - )}$$
$${Y}_{0} = {lim}_{ε \to 0} {I}_{0}^{( + )} - {I}_{0}^{( - )}$$
if Y₁>Y₀, then the i-th bit of p is provided as ONE, otherwise it is provided as ZERO, where Y₁=0, whereas Y₀=2(½+ε)ε; and where since Y₀ is larger establishes that the correct value for pᵢ is expected to be 0; wherein as a function of ε, the formulae for Y₁ and Y₀ are polynomial expressions; both polynomials have a constant term 0; the entire polynomial expansions are not calculated; the first terms in the polynomial expansions of ε that differ will determine which one of the two essential values (that is, Y₁ or Y₀) is larger; the integration only includes the first (low degree) components of the polynomial expansions from Formulas I and II.

2. An electronic computer processing system according to claim 1, wherein the at least one semiconductor device comprises at least one direct band gap semiconductor comprising at least one III-V periodic table element.

3. An electronic computer processing system according to claim 2, wherein the at least one III-V periodic table element comprises at least one element selected from silicon (Si); scandium (Sc), titanium (Ti), vanadium (V), chromium (Cr), manganese (Mn), gallium (Ga), germanium (Gc), selenium (Sc), bromine (Br), and krypton (Kr), and Indium (In), or combinations thereof.

4. An electronic computer processing system according to claim 3, wherein the at least one III-V periodic table element comprises indium (In) and gallium (Ga).

5. An electronic computer processing system according to claim 1, wherein the two or more diode types selected from a semi-conductor diode MASEC; or a semiconductor HBT-diode MASEC comprise at least one indium gallium phosphide (InGaP) diode.

6. A method of making a computer processing system, comprising providing a at least one semiconductor device according to claim 1.

7. A method for real number and complex number computer calculations, comprising:
(a) providing a at least one semiconductor device according to claim 1; and
(b) inputting data for real and complex number calculations using the at least one semiconductor device or computer processing unit (CPU); and
(c) processing the inputted data to provide real number or complex number computations using said at least one semiconductor device or computer processing unit (CPU) according to claim 1.
